(19) United States
(12) Patent Application Publication
(10) Pub. No.: US 2025/0366236 A1
(43) Pub. Date: Nov. 27, 2025

(54) PIXEL SENSOR ARRAY AND METHODS OF FORMATION

(71) Applicant: Taiwan Semiconductor Manufacturing Company, Ltd., Hsinchu (TW)

(72) Inventors: Feng-Chien HSIEH, Pingtung City (TW); Keng-Yin LIAO, Tainan City (TW); Chien Nan TU, Kaohsiung City (TW)

(21) Appl. No.: 18/672,551

(22) Filed: May 23, 2024

(51) Int. Cl. H01L 27/146; H04N 25/77

(52) U.S. Cl. CPC H10F 39/806; H04N 25/77; H10F 39/018; H10F 39/024; H10F 39/182; H10F 39/8053; H10F 39/8063; H10F 39/807; H10F 39/809; H10F 39/811

(57) ABSTRACT

A plurality of vertically arranged layers of diffusion structures are included above a photodiode of a pixel sensor. Each layer of diffusion structures distributes incident light by refraction to provide a greater amount of distribution of the incident light than a single layer of diffusion structures. For example, a top layer of diffusion structures may distribute incident light by refraction, and a bottom layer of diffusion structures may further distribute the distributed incident light from the top layer of diffusion structures before the incident light enters the photodiode of the pixel sensor. This increases the length of the path of travel of photons of the incident light, thereby increasing the likelihood that the photons will be absorbed in the photodiode. Thus, the plurality of vertically arranged layers of diffusion structures may further increase the quantum efficiency (QE) of the pixel sensor.

### BACKGROUND

Complementary metal oxide semiconductor (CMOS) image sensors utilize light-sensitive CMOS circuitry to convert light energy (e.g., photons) into electrical energy. The light-sensitive CMOS circuitry may include a photodiode formed in a silicon substrate. As the photodiode is exposed to light, an electrical charge is induced in the photodiode (referred to as a photocurrent). The photodiode may be coupled to a switching transistor, which is used to sample the charge of the photodiode. Colors may be determined by placing filters over the light-sensitive CMOS circuitry.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example of a pixel sensor described herein.

FIGS. 2A-2C are diagrams of examples of an image sensor device described herein.

FIGS. 3A-3G are diagrams of examples of pixel sensors that may be included in a pixel sensor array of an image sensor device described herein.

FIGS. 4A-4I are diagrams of examples of pixel sensors that may be included in a pixel sensor array of an image sensor device described herein.

FIGS. 5A-5G are diagrams of examples of pixel sensors that may be included in a pixel sensor array of an image sensor device described herein.

FIGS. 6A-6E are diagrams of an example implementation of forming a circuitry die (or a portion thereof) described herein.

FIGS. 7A-7F are diagrams of an example implementation of forming a sensor die (or a portion thereof) described herein.

FIGS. 8A and 8B are diagrams of an example implementation of forming an image sensor device (or a portion thereof) described herein.

FIGS. 9A-9I are diagrams of an example implementation of forming a pixel sensor array of a sensor die (or a portion thereof) described herein.

FIGS. 10A-10E are diagrams of an example implementation of forming a pixel sensor array of a sensor die (or a portion thereof) described herein.

FIGS. 11A-11E are diagrams of an example implementation of forming a pixel sensor array of a sensor die (or a portion thereof) described herein.

FIGS. 12A-12C are diagrams of an example implementation of forming a pixel sensor array of a sensor die (or a portion thereof) described herein.

FIG. 13 is a flowchart of an example process associated with forming a pixel sensor array described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, diffusion structures (also referred to as high absorption (HA) structures) may be included between a photodiode and a micro-lens of a pixel sensor. The diffusion structures may include portions of a dielectric layer that extend into recesses in a substrate of the pixel sensor. Incident light propagating toward the photodiode from the micro-lens is refracted at an interface between the dielectric layer and the substrate, causing the incident light to travel a less direct path toward the photodiode. Thus, the diffusion structures distribute incident light across the photodiode and increases the length of the path of travel of photons of the incident light, thereby increasing the likelihood that the photons will be absorbed in the photodiode. Accordingly, the plurality of vertically arranged layers of diffusion structures may increase the QE of the pixel sensor.

However, the diffusion structures may not be optimally sized and/or shaped for multiple wavelengths of the incident light, resulting in less than optimal performance across a broad range of wavelengths. Thus, while the diffusion structures may increase the QE of the pixel sensor for some wavelengths of the incident light, the pixel sensor may suffer from low QE performance for other wavelengths.

In some implementations described herein, a plurality of vertically arranged layers of diffusion structures are included above a photodiode of a pixel sensor. Each layer of diffusion structures distributes incident light by refraction to provide a greater amount of distribution of the incident light than a single layer of diffusion structures. For example, a top layer of diffusion structures may distribute incident light by refraction, and a bottom layer of diffusion structures may further distribute the distributed incident light from the top layer of diffusion structures before the incident light enters the photodiode of the pixel sensor. This ensures that the incident light is spread out across the photodiode and increase the length of the path of travel of photons of the incident light, thereby increasing the likelihood that the photons will be absorbed in the photodiode. Thus, the plurality of vertically arranged layers of diffusion structures may further increase the QE of the pixel sensor. Moreover, each layer of diffusion structures may be sized and/or shaped to distribute particular wavelengths of the incident light, thereby enabling a broader range of wavelengths of the incident light to be distributed for further QE enhancement.

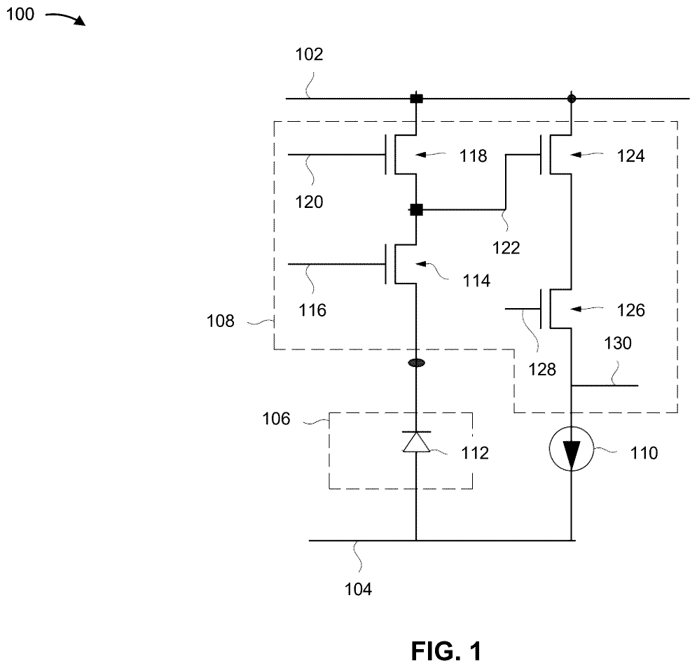

FIG. 1 is a diagram of an example of a pixel sensor 100 described herein. The pixel sensor 100 may include a front side pixel sensor (e.g., a pixel sensor that is configured to receive photons of light from a front side of a sensor die), a back side pixel sensor (e.g., a pixel sensor that is configured to receive photons of light from a back side of a sensor die), and/or another type of pixel sensor. The pixel sensor 100 may be electrically connected to a supply voltage (V_{dd}) 102 and an electrical ground 104.

The pixel sensor 100 includes a sensing region 106 that may be configured to sense and/or accumulate incident light (e.g., light directed toward the pixel sensor 100). The pixel sensor 100 also includes a control circuitry region 108. The control circuitry region 108 is electrically connected with the sensing region 106 and is configured to receive a photocurrent 110 that is generated by the sensing region 106. Moreover, the control circuitry region 108 is configured to transfer the photocurrent 110 from the sensing region 106 to downstream circuits such as amplifiers or analog-to-digital (AD) converters, among other examples.

The sensing region 106 includes a photodiode 112. The photodiode 112 may absorb and accumulate photons of the incident light, and may generate the photocurrent 110 based on absorbed photons. The magnitude of the photocurrent 110 is based on the amount of light collected in the photodiode 112. Thus, the accumulation of photons in the photodiode 112 generates a build-up of electrical charge that represents the intensity or brightness of the incident light (e.g., a greater amount of charge may correspond to a greater intensity or brightness, and a lower amount of charge may correspond to a lower intensity or brightness).

The photodiode 112 is electrically connected with a source of a transfer gate 114 in the control circuitry region 108. The transfer gate 114 is configured to control the transfer of the photocurrent 110 from the photodiode 112. The photocurrent 110 is provided from the source of the transfer gate 114 to a drain of the transfer gate 114 based on selectively switching a gate of the transfer gate 114. The gate of the transfer gate 114 may be selectively switched by applying a transfer voltage (Vₜₓ) 116 to the transfer gate 114. In some implementations, the transfer voltage 116 being applied to the transfer gate 114 causes a conductive channel to form between the source and the drain of the transfer gate 114, which enables the photocurrent 110 to traverse along the conductive channel from the source to the drain. In some implementations, the transfer voltage 116 being removed from the transfer gate 114 (or the absence of the transfer voltage 116) causes the conductive channel to be removed such that the photocurrent 110 cannot pass from the source to the drain.

The control circuitry region 108 further includes a reset gate 118. The reset gate 118 is electrically connected to the supply voltage 102. The reset gate 118 may be controlled by a reset voltage (Vᵣₛₜ) 120. The transfer gate 114 and the reset gate 118 may be electrically coupled with a floating diffusion node 122. The reset voltage 120 may be applied to the reset gate 118 to pull the drain of the transfer gate 114 to a high voltage (e.g., to the supply voltage 102) to “reset” the floating diffusion node 122 (e.g., by draining any residual charge in the floating diffusion node 122) prior to activation of the transfer gate 114 to transfer the photocurrent 110 from the photodiode 112 to the floating diffusion node 122.

The photocurrent 110 may be used to apply a floating diffusion voltage (V_{fd}) to a source follower gate 124 of the control circuitry region 108. This permits the photocurrent 110 to be observed without removing or discharging the photocurrent 110 from the floating diffusion node 122. The reset gate 118 may instead be used to remove or discharge the photocurrent 110 from the floating diffusion node 122.

The source follower gate 124 functions as a high impedance amplifier for the pixel sensor 100. The source follower gate 124 provides a voltage to current conversion of the floating diffusion voltage. The output of the source follower gate 124 is electrically connected with a row select gate 126, which is configured to control the flow of the photocurrent 110 to external circuitry. The row select gate 126 is controlled by selectively applying a select voltage (V_{di}) 128 to the gate of the row select gate 126. This permits the photocurrent 110 to flow to an output 130 of the pixel sensor 100.

As indicated above, FIG. 1 is provided as an example. Other examples may differ from what is described with regard to FIG. 1.

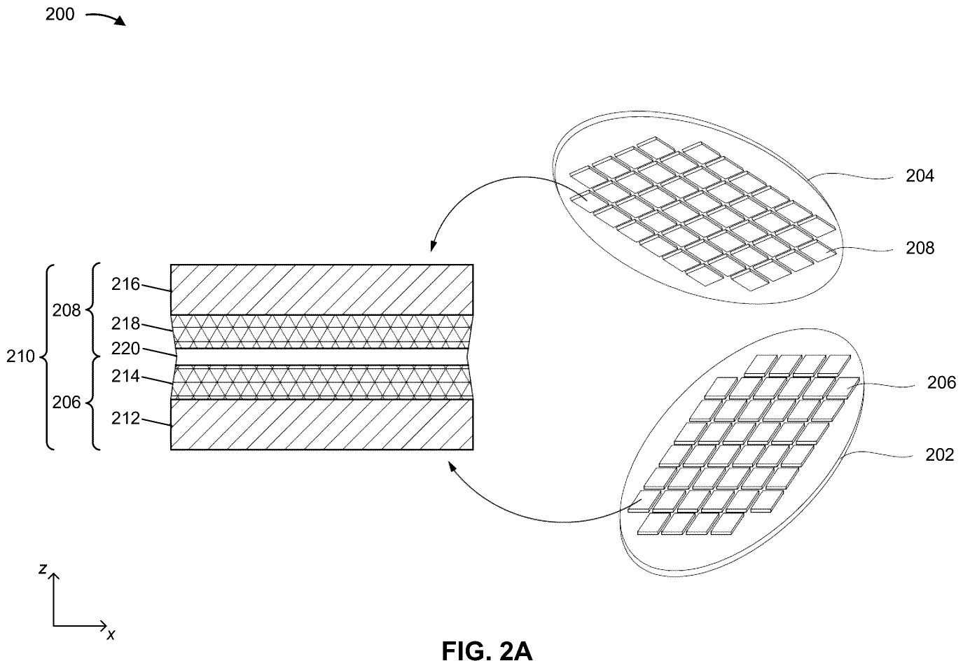

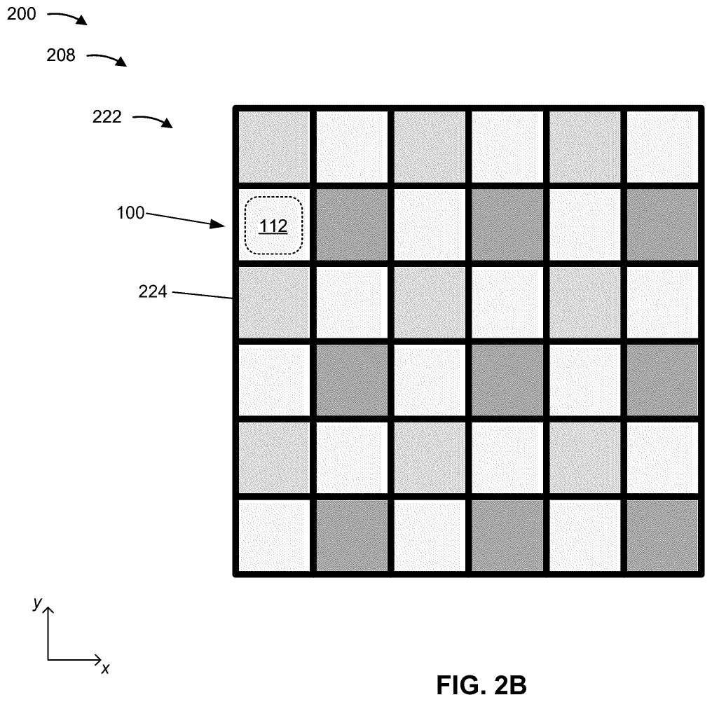

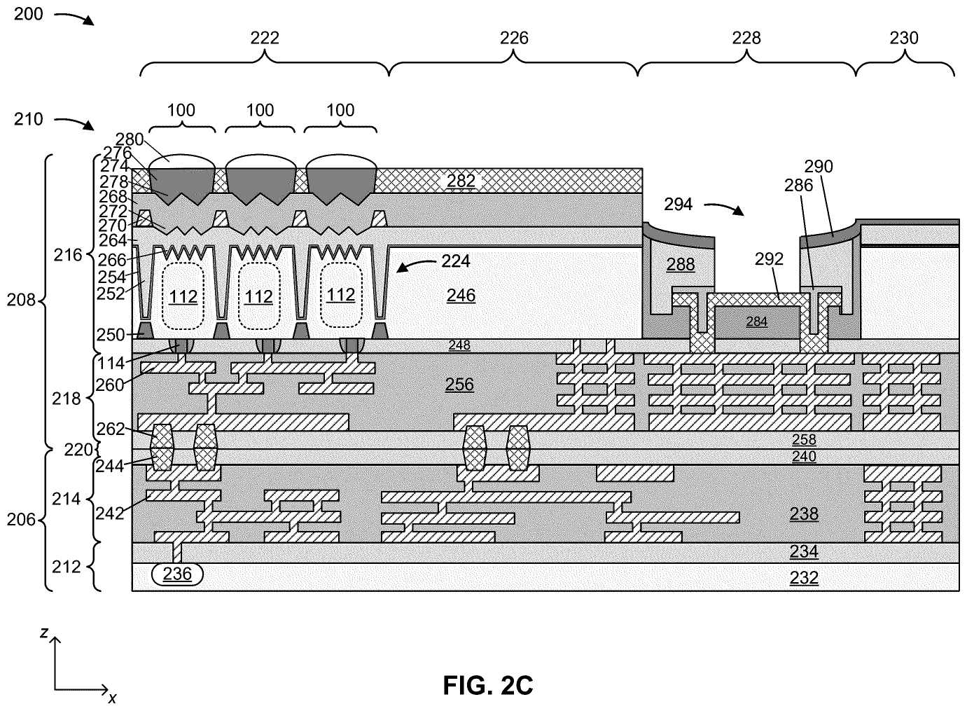

FIGS. 2A-2C are diagrams of examples 200 of an image sensor device described herein. As shown in FIG. 2A, an image sensor device may be formed by bonding a circuitry wafer 202 and a sensor wafer 204. For example, a bonding tool may be used to perform a bonding operation to bond the circuitry wafer 202 and the sensor wafer 204 using a metal-to-metal bonding technique, a dielectric-to-dielectric bonding technique, and/or another bonding technique. In the bonding operation, circuitry dies 206 on the circuitry wafer 202 are bonded with associated sensor dies 208 on the sensor wafer 204 to image sensor devices 210. The image sensor devices 210 are then diced and packaged. Other processing steps may be performed to form the image sensor devices 210.

Each image sensor device 210 includes a circuitry die 206 and a sensor die 208. The circuitry die 206 and the sensor die 208 may be stacked or vertically arranged in the image sensor device 210. The sensor die 208 includes a pixel sensor array that includes a plurality of pixel sensors 100, or portions of a plurality of pixel sensors 100. In particular, the pixel sensor array includes at least the sensing regions 106 (and thus, the photodiodes 112) of the pixel sensors 100. Accordingly, the sensor die 208 primarily is configured to sense photons of incident light and convert the photons to a photocurrent 110.

The circuitry die 206 includes circuitry that is configured to measure, manipulate, and/or otherwise use the photocurrent 110. Moreover, the circuitry die 206 includes at least a subset of the transistors of the control circuitry regions 108 of the pixel sensors 100. For example, the circuitry die 206 may include the row select gates 126 of the pixel sensors 100, the source follower gates 124 of the pixel sensor, and/or a combination thereof. This provides increased area on the sensor die 208 for the photodiodes 112, which enables the size of the photodiodes 112 to be increased to increase the sensitivity and/or overall performance of the light sensing performance of the pixel sensor, and/or enables the size of the pixel sensors 100 to be decreased while maintaining the same size for the photodiodes 112.

As further shown in FIG. 2A, the circuitry die 206 may include a device layer 212 and an interconnect layer 214. The device layer 212 may include the devices (e.g., transistors) of the circuitry die 206, and the interconnect layer 214 may include interconnects that enable signals and/or power to be provided to and/or from the devices in the device layer 212. The sensor die 208 may also include a device layer 216 and an interconnect layer 218. The device layer 216 may include portions of the pixel sensors 100, including the photodiodes 112, the transfer gates 114, and the floating diffusion nodes 122, among other examples. The interconnect layer 218 may include interconnects that enable signals and/or power to be provided to and/or from the device layer 216.

The circuitry die 206 and the sensor die 208 may be bonded at a bonding interface 220, which may be included between the interconnect layers 214 and 218, and/or may be included in a portion of the interconnect layers 214 and/or 218. The bonding interface 220 may include bonding pads, bonding vias, bonding dielectric layers, and/or other bonding structures.

FIG. 2B is a top-down view of an example pixel sensor array 222 included on a sensor die 208. The pixel sensor array 222 may be included on a sensor die 208 of an image sensor device 210. As shown in FIG. 2B, the pixel sensor array 222 may include a plurality of pixel sensors 100 (or portions of the plurality of plurality of pixel sensors 100). For example, the pixel sensor array 222 may include the photodiodes 112 of the pixel sensors 100. As further shown in FIG. 2B, the pixel sensors 100 may be arranged in a grid. In some implementations, the pixel sensors 100 are square-shaped (as shown in the example in FIG. 2B). In some implementations, the pixel sensors 100 include other shapes such as rectangle shapes, circle shapes, octagon shapes, diamond shapes, and/or other shapes.

In some implementations, the size of the pixel sensors 100 (e.g., the width or the diameter) of the pixel sensors 100 is approximately 1 micron. In some implementations, the size of the pixel sensors 100 (e.g., the width or the diameter) of the pixel sensors 100 is less than approximately 1 micron. For example, a width of one or more of the pixel sensors 100 may be included in a range of approximately 0.6 microns to approximately 0.7 microns. In these examples, the pixel sensors 100 may be referred to as sub-micron pixel sensors. Sub-micron pixel sensors may decrease the pixel sensor pitch (e.g., the distance between adjacent pixel sensors) in the pixel sensor array 222, which may enable increased pixel sensor density in the pixel sensor array 222 (which can increase the performance of the pixel sensor array 222). However, other values for the range of the size of the pixel sensors 100 are within the scope of the present disclosure.

Each pixel sensor 100 may be configured to sense a particular wavelength range of incident light associated with a particular color component of the incident light. For example, a pixel sensor 100 may be configured to sense a wavelength range associated with a red component of incident light, and may therefore be referred to as a red pixel sensor. As another example, a pixel sensor 100 may be configured to sense a wavelength range associated with a blue component of incident light, and may therefore be referred to as a blue pixel sensor. As another example, a pixel sensor 100 may be configured to sense a wavelength range associated with a green component of incident light, and may therefore be referred to as a green pixel sensor. In some implementations, a plurality of pixel sensors 100 are configured to sense a wavelength range associated with a near infrared (NIR) component of incident light, and may therefore be referred to as NIR pixel sensors. The NIR pixel sensors may be included in the pixel sensor array 222 to improve low-light performance of the image sensor device 210 and/or to enable night-vision functionality to be realized for the image sensor device 210.

As further shown in FIG. 2B, the pixel sensors 100 may be electrically and optically isolated by a deep trench isolation (DTI) structure 224 included in the pixel sensor array 222. The DTI structure 224 may include a plurality of interconnected and intersecting trenches in a substrate that are filled with one or more types of materials, such as a dielectric material, a metal material, and/or another type of material. The trenches of the DTI structure 224 may be included around the perimeters of the pixel sensors 100 such that the DTI structure 224 forms an isolation grid that surrounds the photodiodes 112 of the pixel sensors 100, as shown in FIG. 2B.

FIG. 2C illustrates a cross-section view of an image sensor device 210. As shown in FIG. 2C, a circuitry die 206 and a sensor die 208 may be bonded at a bonding interface 220 such that the circuitry die 206 and the sensor die 208 are stacked or vertically arranged in a z-direction in the image sensor device 210. As further shown in FIG. 2C, the image sensor device 210 includes the pixel sensor array 222 (e.g., including the pixel sensors 100), a black level correction (BLC) region 226 adjacent to (e.g., horizontally adjacent to) the pixel sensor array 222, a bonding pad region 228 adjacent to (e.g., horizontally adjacent to) the BLC region 226, and a seal ring region 230 adjacent to (e.g., horizontally adjacent to) the bonding pad region 228, among other examples.

As further shown in FIG. 2C, the image sensor device 210 includes a plurality of layers, such as the device layer 212 and the interconnect layer 214 of the circuitry die 206, and the device layer 216 and the interconnect layer 218 of the sensor die 208. The device layer 212 of the circuitry die 206 includes a substrate 232 and a dielectric layer 234 above the substrate 232. The substrate 232 may include silicon (Si) (e.g., a silicon substrate), a material including silicon, a III-V compound semiconductor material such as gallium arsenide (GaAs), a silicon on insulator (SOI), or another type of semiconductor material. The substrate 232 may include a semiconductor layer such as a silicon layer. The dielectric layer 234 may include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

Integrated circuit devices 236 may be included in and/or on the substrate 232 of the device layer 212. The integrated circuit devices 236 may include one or more application-specific integrated circuit (ASIC) devices, one or more system-on-chip (SOC) devices, one or more transistors, and/or one or more other components configured to measure the magnitude of a photocurrent 110 generated by the pixel sensors 100 to determine light intensity of incident light and/or to generate images and/or video (e.g., digital images, digital video).

The interconnect layer 214 of the circuitry die 206 may include a dielectric layer 238, a bonding layer 240, a plurality of interconnect structures 242 in the dielectric layer 238, and a plurality of bonding structures 244 in the bonding layer 240. The dielectric layer 238 may include one or more interlayer dielectric (ILD) layers, one or more intermetal dielectric (IMD) layers, and/or one or more etch stop layers (ESLs), among other examples. The dielectric layer 238 and the bonding layer 240 may each include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

The interconnect structures 242 may each include conductive lines, trenches, vias, interconnects, metallization layers, and/or other types of electrically conductive structures that electrically connect the integrated circuit devices 236 to one or more other regions of the circuitry die 206 and/or to one or more regions of the sensor die 208, among other examples. The bonding structures 244 may each include bonding pads, bonding vias, and/or other types of bonding structures. The interconnect structures 242 and the bonding structures 244 may each include one or more electrically conductive materials, such as, an electrically conductive metal, an electrically conductive metal alloy, an electrically conductive ceramic, tungsten (W), cobalt (Co), ruthenium (Ru), titanium (Ti), aluminum (Al), copper (Cu), and/or gold (Au), among other examples of electrically conductive materials.

The device layer 216 of the sensor die 208 includes a substrate 246 and a dielectric layer 248 below the substrate 246. The substrate 246 may include silicon (Si) (e.g., a silicon substrate), a silicon layer or another type of semiconductor layer, a material including silicon, a III-V compound semiconductor material such as gallium arsenide (GaAs), an SOI, or another type of semiconductor material. The dielectric layer 248 may include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

The photodiodes 112 of the pixel sensors 100 are included in the substrate 246 of the sensor die 208. The photodiodes 112 may each include one or more doped regions of substrate 246. The substrate 246 may be doped with a plurality of types of ions to form a p-n junction or a PIN junction (e.g., a junction between a p-type portion, an intrinsic (or undoped) type portion, and an n-type portion) corresponding to a photodiode 112. For example, the substrate 246 may be doped with an n-type dopant to form a first portion (e.g., an n-type portion) of a photodiode 112 and a p-type dopant to form a second portion (e.g., a p-type portion) of the photodiode 112. A photodiode 112 may be configured to absorb photons of incident light. The absorption of photons causes the photodiode 112 to accumulate a charge (a photocurrent 110) due to the photoelectric effect. Here, photons bombard the photodiode 112, which causes emission of electrons of the photodiode 112. The emission of electrons causes the formation of electron-hole pairs, where the electrons migrate toward the cathode of the photodiode 112 and the holes migrate toward the anode, which produces the photocurrent 110.

The photodiodes 112 may be electrically isolated and/or optically isolated from one another by one or more isolation structures in the substrate 246. Shallow trench isolation (STI) structures 250 extend into the substrate 246 from a bottom side of the substrate 246 (referred to as the front side of the substrate 246), and the DTI structure 224 extends into the substrate 246 from a top side of the substrate 246 (referred to as the back side of the substrate 246) over the STI structures 250). The combination of the STI structures 250) and the DTI structure 224 in the substrate 246 laterally surround the pixel sensors 100 in the substrate 246 and provide the electrically isolation and/or optically isolation for the pixel sensors 100 in the substrate 246.

The DTI structure 224 may include elongated structures that include a dielectric layer 252 and a dielectric liner 254 between the dielectric layer 252 and the substrate 246. The dielectric liner 254 may be a conformal liner that included on, and conforms to the profile of, sidewalls and a bottom surface of the DTI structure 224. The dielectric liner may be included as an antireflective coating (ARC), to passivate the substrate 246 near the DTI structure 224, and/or to further facilitate electrical and/or optical isolation of the pixel sensors 100. The STI structures 250 may include one or more dielectric materials, such as a silicon oxide (SiOₓ), a silicon nitride (SiₓN_{y}), and/or a silicon oxynitride (SiON), among other examples. The dielectric layer 252 of the DTI structure 224 may include a silicon oxide (SiOₓ such as SiO₂), phosphosilicate glass (PSG), borophosphosilicate glass (BPSG), fluorinated silica glass (FSG), another low dielectric constant (low-k) dielectric material having a dielectric constant of approximately 3.9 or less, and/or another dielectric material. In some implementations, the dielectric liner 254 may include a high dielectric constant (high-k) dielectric material such as a silicon nitride (SiₓN_{y} such as Si₃N₄), a hafnium oxide (HfOₓ such as HfO₂), an aluminum oxide (AlₓO_{y}such as Al₃O₄), and/or another high-k dielectric material having a dielectric constant greater than approximately 3.9.

The DTI structure 224 are included in the backside of the substrate 246. On the front side of the substrate 246, transfer gates 114 of the pixel sensors 100 are included, and the dielectric layer 248 is included over the transfer gates 114. The transfer gates 114 are electrically connected to the interconnect layer 218, which enables inputs (e.g., gate voltages) to be provided to the transfer gates 114 to control the flow of photocurrents 110 from the photodiodes 112 to floating diffusion nodes 122 (not shown) of pixel sensors 100.

The interconnect layer 218 may include a dielectric layer 256, a bonding layer 258, a plurality of interconnect structures 260 in the dielectric layer 256, and a plurality of bonding structures 262 in the bonding layer 258. The dielectric layer 256 may include one or more ILD layers, one or more IMD layers, and/or one or more ESLs, among other examples. The dielectric layer 256 and the bonding layer 258 may each include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

The interconnect structures 260 may each include conductive lines, trenches, vias, interconnects, metallization layers, and/or other types of electrically conductive structures that electrically connect the transfer gates 114 to one or more other regions of the sensor die 208 and/or to one or more regions of the circuitry die 206, among other examples. The bonding structures 262 may each include bonding pads, bonding vias, and/or other types of bonding structures. The interconnect structures 260 and the bonding structures 262 may each include one or more electrically conductive materials, such as, an electrically conductive metal, an electrically conductive metal alloy, an electrically conductive ceramic, tungsten (W), cobalt (Co), ruthenium (Ru), titanium (Ti), aluminum (Al), copper (Cu), and/or gold (Au), among other examples of electrically conductive materials.

At the bonding interface 220, the bonding layers 240 and 258 may be bonded together (e.g., in a dielectric-to-dielectric bond), and the bonding structures 244 and 262 may be bonded together (e.g., in a metal-to-metal bond). Signals and/or power may be provided between the circuitry die 206 and the sensor die 208 through the bonding structures 244 and 262.

Above the top side (e.g., the back side) of the substrate 246, a buffer layer 264 may be included above the DTI structure 224 and above the photodiodes 112. The buffer layer 264 may include an oxide material such as a silicon oxide (SiOₓ). Additionally and/or alternatively, a silicon nitride (SiNₓ), a silicon carbide (SiCₓ), or a mixture thereof, such as a silicon carbon nitride (SiCN), a silicon oxynitride (SiON), or another dielectric material is used for the buffer layer 264. In some implementations, the buffer layer 264 is merged with the dielectric layer 252 of the DTI structure 224. In some implementations, the buffer layer 264 is separate from the dielectric layer 252 of the DTI structure 224. In some implementations, a thickness of the buffer layer 264 is included in a range of approximately 1,000 to approximately 2,000 angstroms. However, other values for the range are within the scope of the present disclosure.

As further shown in FIG. 2C, a layer of diffusion structures 266 may be included above the photodiodes 112 of the pixel sensors 100. The diffusion structures 266 are included to diffuse or scatter photons of incident light into the substrate 246 (e.g., by refraction), causing the photons to traverse a longer path to the photodiodes 112. The longer path of travel of the photons provides more opportunities for the photons to be absorbed in the photodiodes 112, thereby increasing the likelihood that the photons will be absorbed. This increases the QE of the pixel sensors 100.

The diffusion structures 266 may be located within the perimeter of the DTI structure 224 in a top view of the pixel sensor array 222 and between opposing sections of the DTI structure 224 on opposing sides of a photodiode 112 in cross-section view of the pixel sensor array 222. The diffusion structures 266 each include a portion or a region of dielectric material of the buffer layer 264 that is included in recesses in back side of the substrate 246 above the photodiodes 112. Thus, the diffusion structures 266 extend into the back side of the substrate 246, similar to the DTI structure 224. However, the diffusion structures 266 are shallower in depth in the substrate 246 than the DTI structure 224. In some implementations, the dielectric liner 254 of the DTI structure 224 is also included in the recesses in which the diffusion structures 266 are included, such that the dielectric liner 254 is between the substrate 246 and the portions or regions of the dielectric material of the diffusion structures 266.

The bottom surfaces of the diffusion structures 266 may have an approximately V-shaped cross-sectional profile because of the recesses in the substrate 246 having angled sidewalls. Alternatively, the bottom surfaces of the diffusion structures 266 may have rounded or approximately U-shaped sidewalls. The angle of the sidewalls of the recesses in which the diffusion structures 266 are formed, in combination with the different refractive indexes of the material of the substrate 246 and the material of the dielectric material of the diffusion structures 266, cause the path traveled by photons into the substrate 246 to be modified through refraction at the interface between the diffusion structures 266 and the substrate 246.

A passivation layer 268 may be included over and/or on the buffer layer 264. The passivation layer 268 may include one or more dielectric materials, and may have a same or similar material composition as the material composition of the buffer layer 264, or the passivation layer 268 and the buffer layer 264 may include different dielectric materials and/or different material compositions. In some implementations, the passivation layer 268 has a thickness that is greater than a thickness of the buffer layer 264. For example, the thickness of the passivation layer 268 may be approximately 3 times to approximately 6 times the thickness of the buffer layer 264. However, other values for the range are within the scope of the present disclosure. In some implementations, the thickness of the passivation layer is included in a range of approximately 5,000 angstroms to approximately 7,000 angstroms. However, other values for the range are within the scope of the present disclosure.

A metal grid structure 270 may be included on the buffer layer 264 and embedded in the passivation layer 268. Sections of the metal grid structure 270 may be located over the DTI structure 224 and may be formed around the perimeter of the photodiodes 112 of the pixel sensors 100. Openings in the metal grid structure 270 are included above the photodiodes 112 to enable incident light to pass through the metal grid structure 270 and to the photodiodes 112. The metal grid structure 270 may be formed of a metal material, such as gold (Au), copper (Cu), silver (Ag), cobalt (Co), tungsten (W), titanium (Ti), ruthenium (Ru), a metal alloy (e.g., aluminum copper (AlCu)), and/or a combination thereof, among other examples.

Another layer of diffusion structures 272 may be included above the photodiodes 112 of the pixel sensors 100. The diffusion structures 272 are included to further diffuse or scatter photons of incident light into the substrate 246, causing (in combination with the diffusion structures 266) the photons to traverse a longer path to the photodiodes 112 to further increase the QE of the pixel sensors 100. The diffusion structures 272 may be located within the perimeter of the metal grid structure 270 in a top view of the pixel sensor array 222 and between opposing sections of the metal grid structure 270 on opposing sides of a photodiode 112 in cross-section view of the pixel sensor array 222. The diffusion structures 272 are included above the diffusion structures 266 such that the diffusion structures 266 and the diffusion structures 272 are vertically arranged (e.g., in the z-direction) above the photodiodes 112. The diffusion structures 272 each include a portion or a region of dielectric material of the passivation layer 268 that is included in recesses in the top surface of the buffer layer 264.

The bottom surfaces of the diffusion structures 272 may have an approximately V-shaped cross-sectional profile because of the recesses in the buffer layer 264 having angled sidewalls. Alternatively, the bottom surfaces of the diffusion structures 272 may have rounded or approximately U-shaped sidewalls. The angle of the sidewalls of the recesses in which the diffusion structures 272 are formed, in combination with the different refractive indexes of the material of the buffer layer 264 and the material of the dielectric material of the diffusion structures 272, cause the path traveled by photons into the substrate 246 to be modified through refraction at the interface between the diffusion structures 272 and the buffer layer 264.

Another metal grid structure 274 may be included on the passivation layer 268. Sections of the metal grid structure 270 may be located over the metal grid structure 270 and may be formed around the perimeter of the photodiodes 112 of the pixel sensors 100. Openings in the metal grid structure 274 are included above the photodiodes 112 to enable incident light to pass through the metal grid structure 274 and to the photodiodes 112. The metal grid structure 274 may be formed of a metal material, such as gold (Au), copper (Cu), silver (Ag), cobalt (Co), tungsten (W), titanium (Ti), ruthenium (Ru), a metal alloy (e.g., aluminum copper (AlCu)), and/or a combination thereof, among other examples.

In some implementations, the metal grid structure 274 is omitted, and only the metal grid structure 270 is included in the pixel sensor array 222. In some implementations, the metal grid structure 270 is omitted, and only the metal grid structure 274 is included in the pixel sensor array 222. In some implementations, both the metal grid structure 270 and the metal grid structure 274 are omitted from the pixel sensor array 222.

Color filter regions 276 of the pixel sensors 100 be included in the openings in the metal grid structure 274. The color filter regions 276 may be included above the photodiodes 112 of the pixel sensors 100. The color filter regions 276 may be included above the photodiodes 112. Each color filter region 276 may be configured to filter incident light to allow a particular wavelength of the incident light to pass to a photodiode 112. For example, a color filter region 276 may filter incident light to allow red light to pass through the color filter region 276 to an associated photodiode 112. As another example, a color filter region 276 may filter incident light to allow green light to pass through the color filter region 276 to an associated photodiode 112. As another example, a color filter region 276 may filter incident light to allow blue light to pass through the color filter region 276 to an associated photodiode 112. In some implementations, a color filter region 276 may be non-discriminating or non-filtering, which may define a white pixel sensor. A non-discriminating or non-filtering color filter region 276 may include a material that permits all wavelengths of light to pass into the associated photodiode 112 (e.g., for purposes of determining overall brightness to increase light sensitivity for the image sensor). In some implementations, a color filter region 276 may be an NIR bandpass color filter region 276, which may define an NIR pixel sensor. An NIR bandpass color filter region 276 may include a material that permits the portion of incident light in an NIR wavelength range to pass to an associated photodiode 112 while blocking visible light from passing.

Another layer of diffusion structures 278 may be included above the photodiodes 112 of the pixel sensors 100. The diffusion structures 278 are included to further diffuse or scatter photons of incident light into the substrate 246, causing (in combination with the diffusion structures 266 and/or 272) the photons to traverse a longer path to the photodiodes 112 to further increase the QE of the pixel sensors 100. The diffusion structures 278 may be located within the perimeter of the metal grid structure 274 in a top view of the pixel sensor array 222 and between opposing sections of the metal grid structure 274 on opposing sides of a photodiode 112 in cross-section view of the pixel sensor array 222. The diffusion structures 278 are included above the diffusion structures 266 and/or above the diffusion structures 272 such that the diffusion structures 266, the diffusion structures 272, and/or the diffusion structures 278 are vertically arranged (e.g., in the z-direction) above the photodiodes 112. The diffusion structures 278 each include a portion or a region of dielectric material of a color filter region 276 that is included in recesses in the top surface of the passivation layer 268.

The bottom surfaces of the diffusion structures 278 may have an approximately V-shaped cross-sectional profile because of the recesses in the passivation layer 268 having angled sidewalls. Alternatively, the bottom surfaces of the diffusion structures 278 may have rounded or approximately U-shaped sidewalls. The angle of the sidewalls of the recesses in which the diffusion structures 278 are formed, in combination with the different refractive indexes of the material of the passivation layer 268 and the material of the dielectric material of the diffusion structures 278, cause the path traveled by photons into the substrate 246 to be modified through refraction at the interface between the diffusion structures 278 and the passivation layer 268.

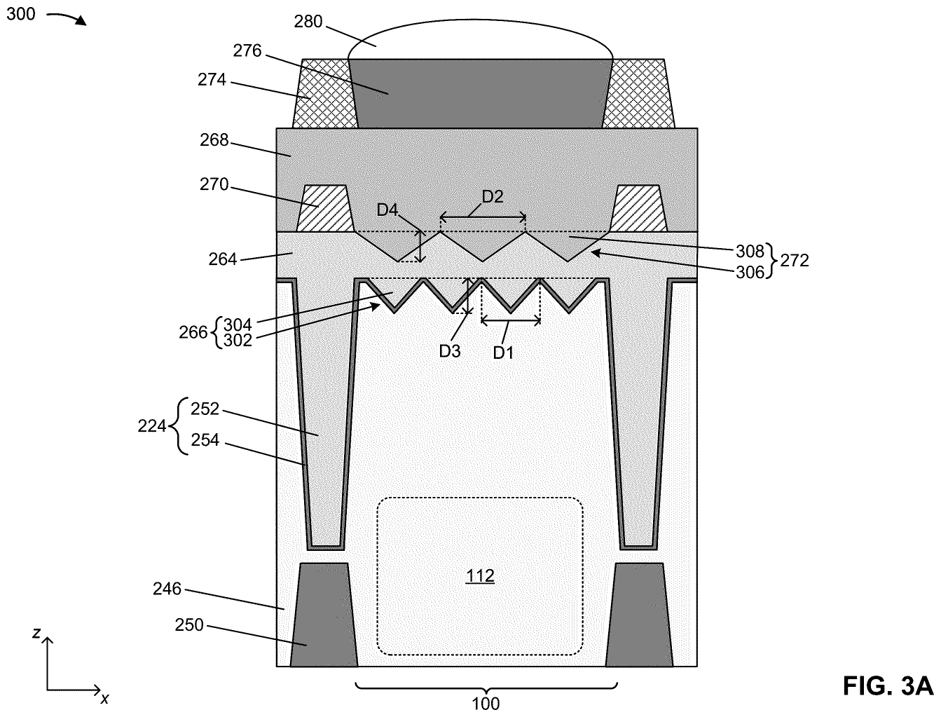

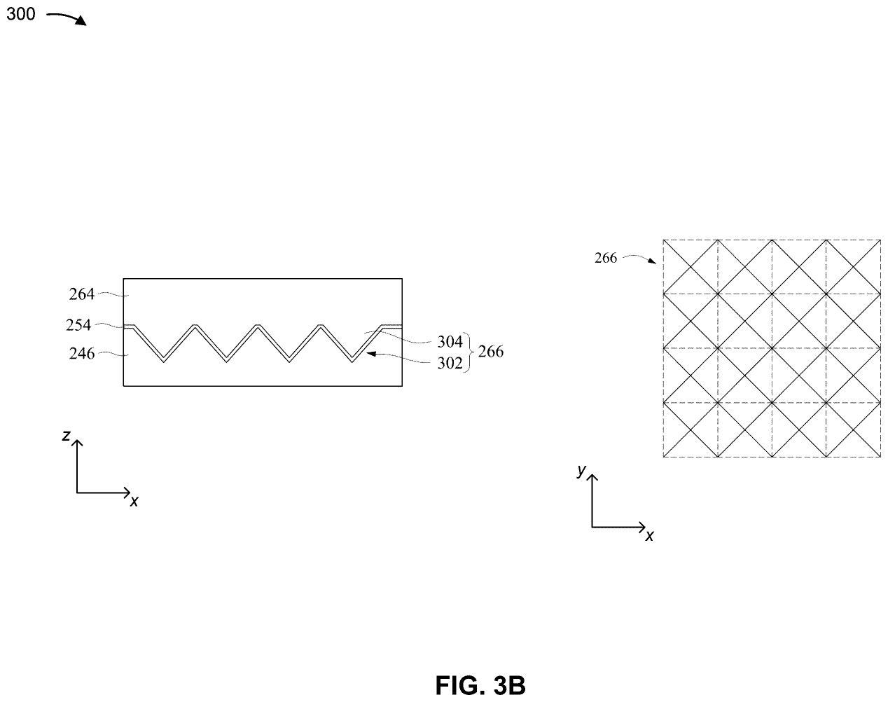

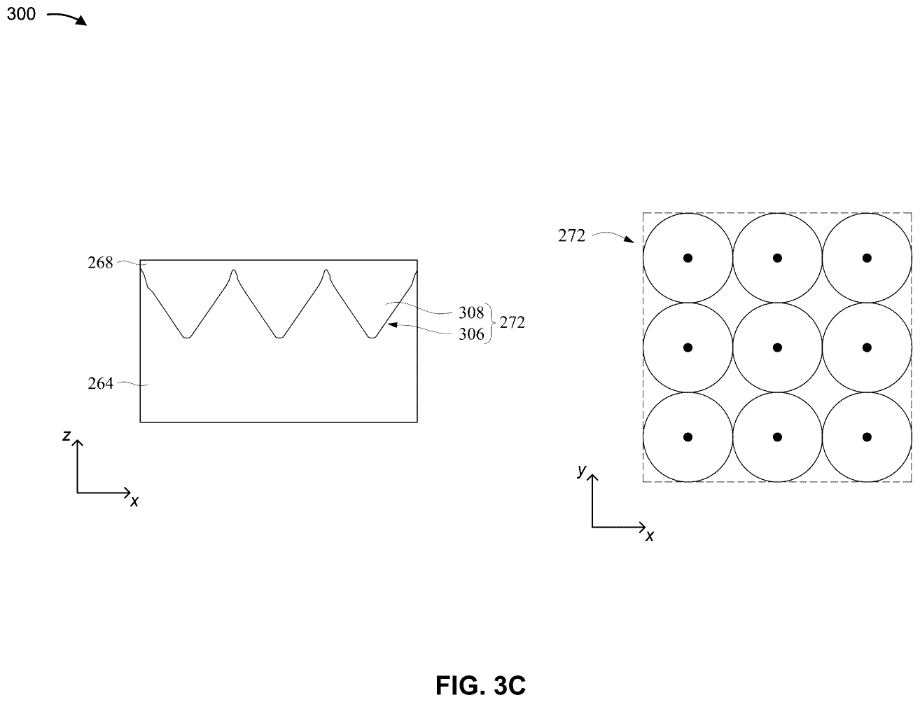

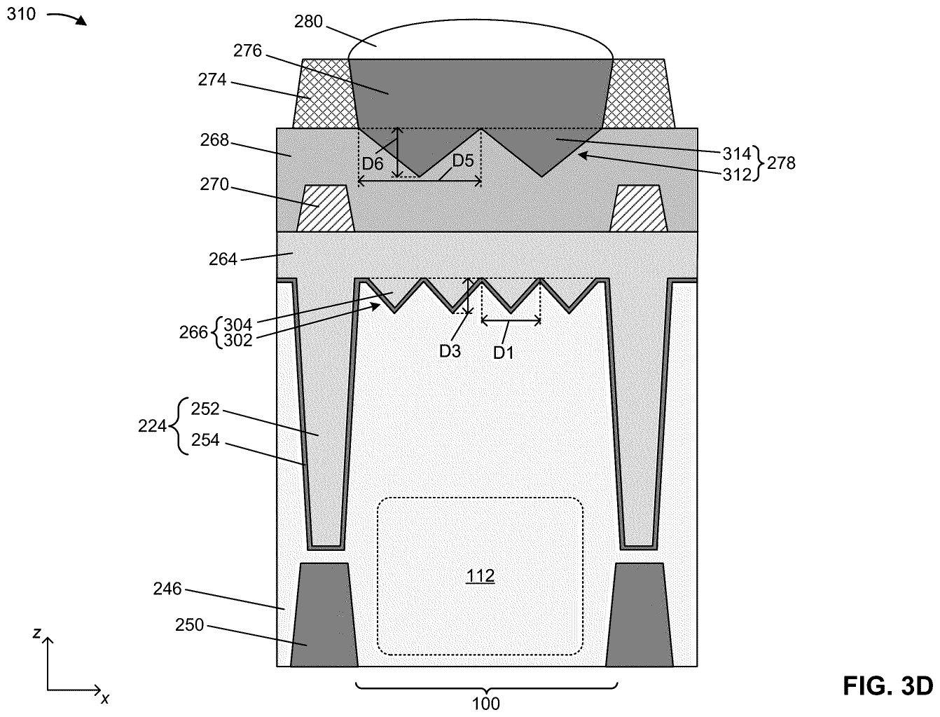

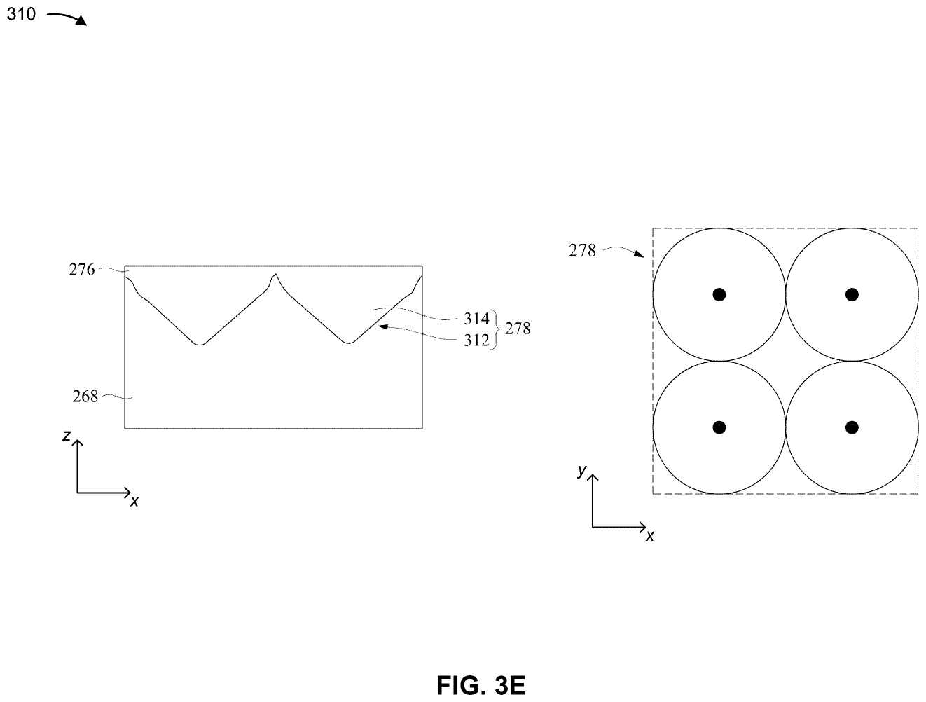

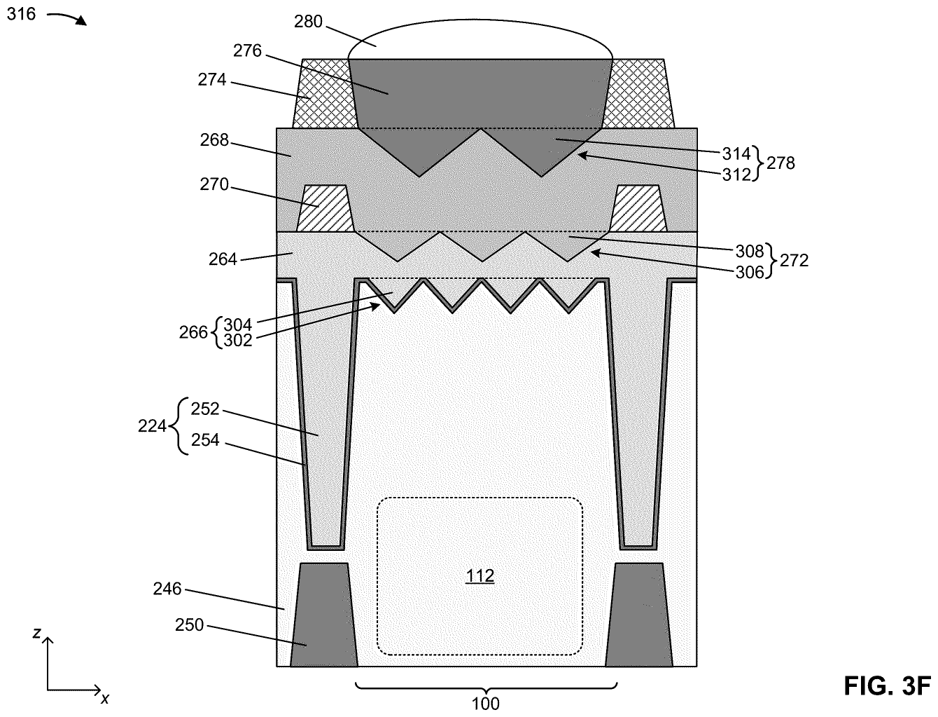

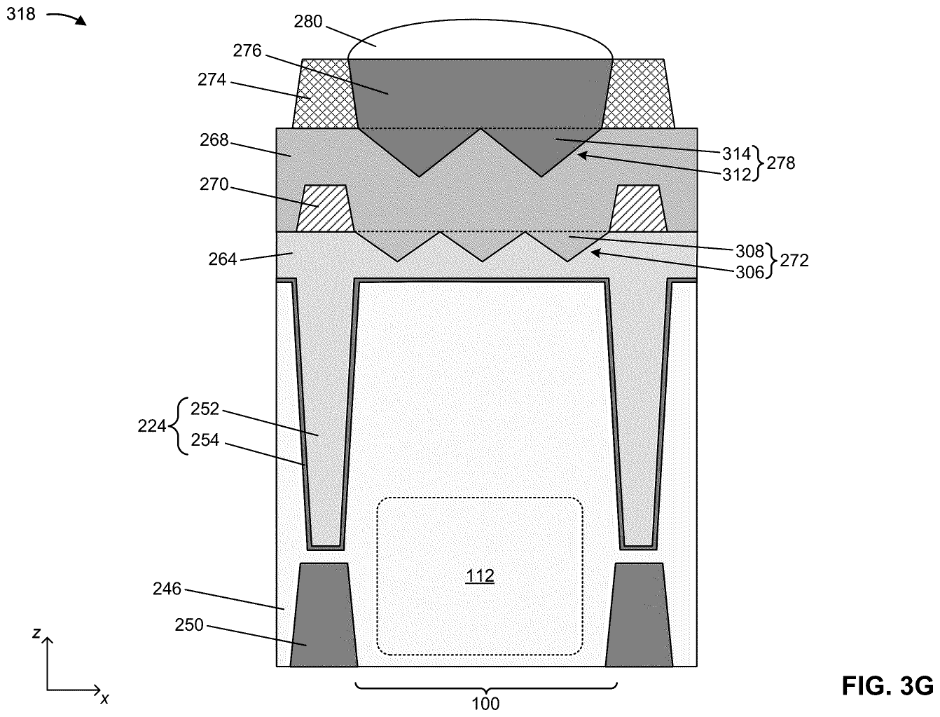

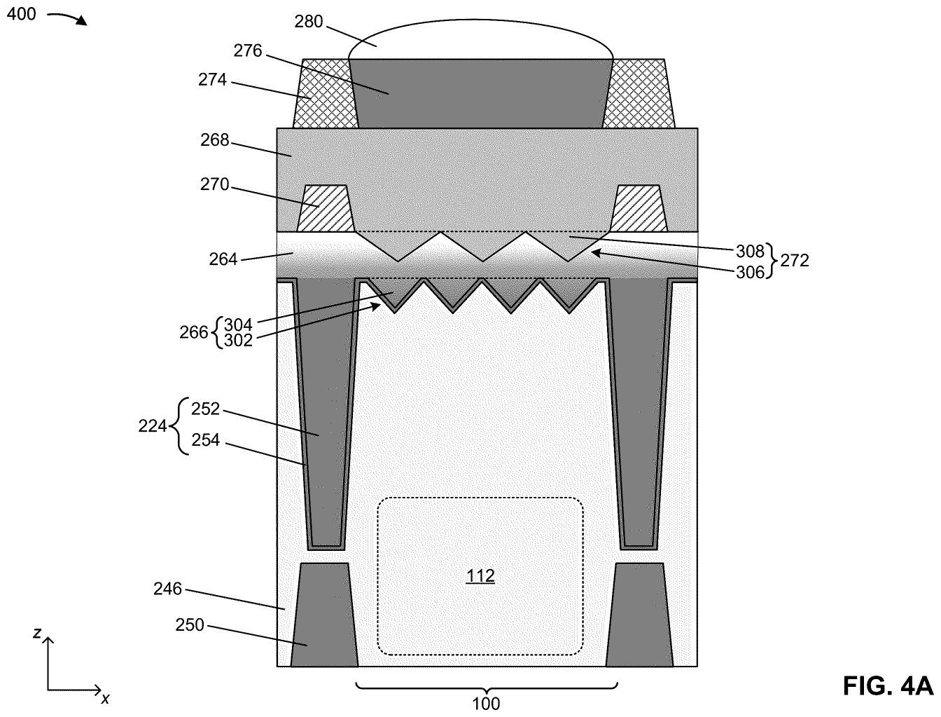

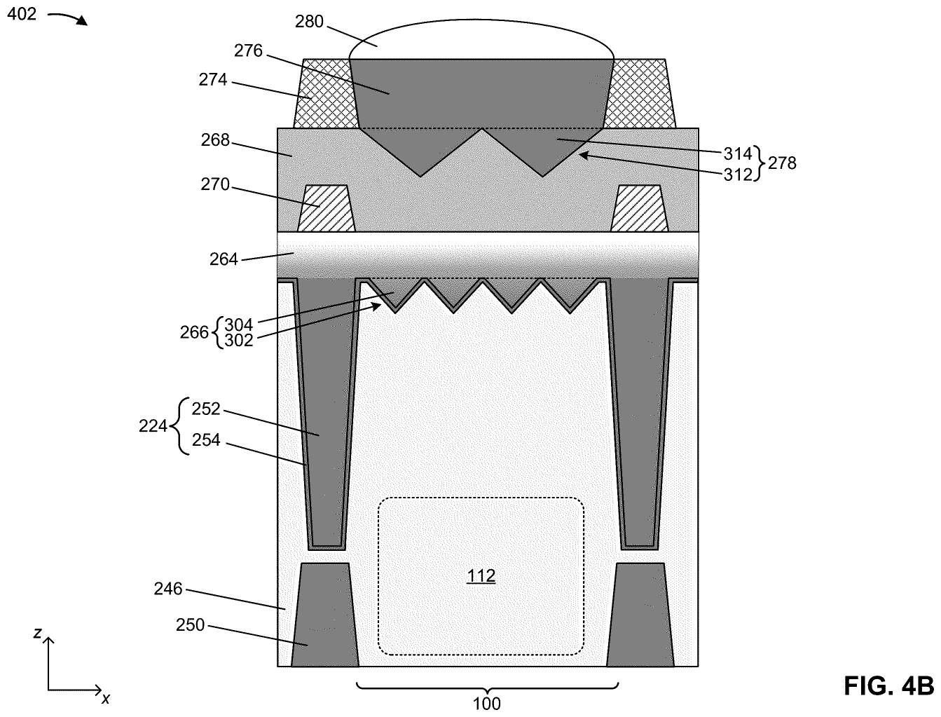

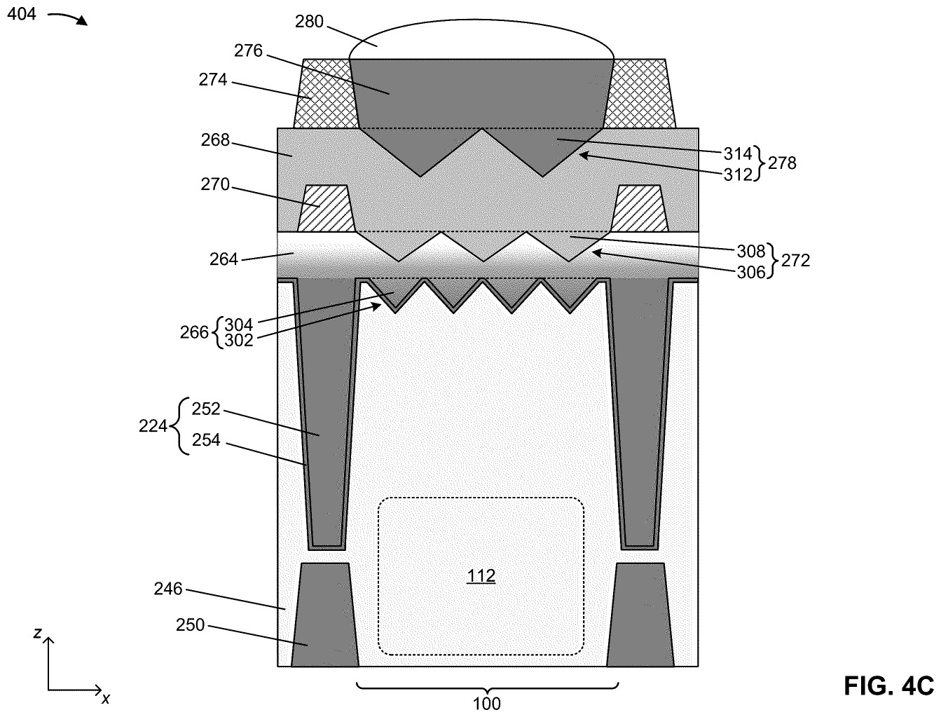

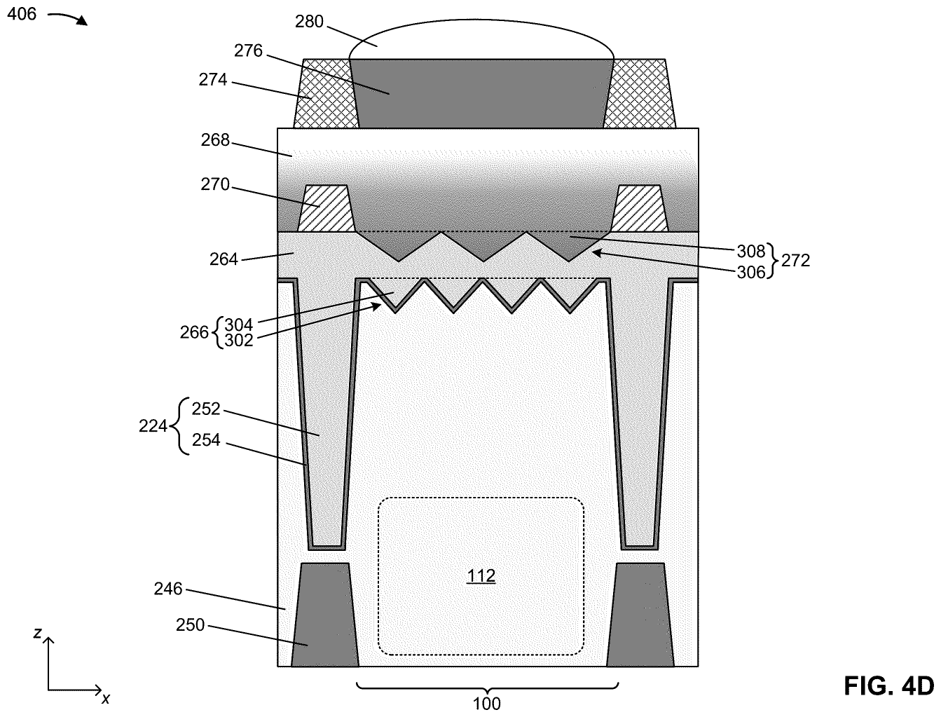

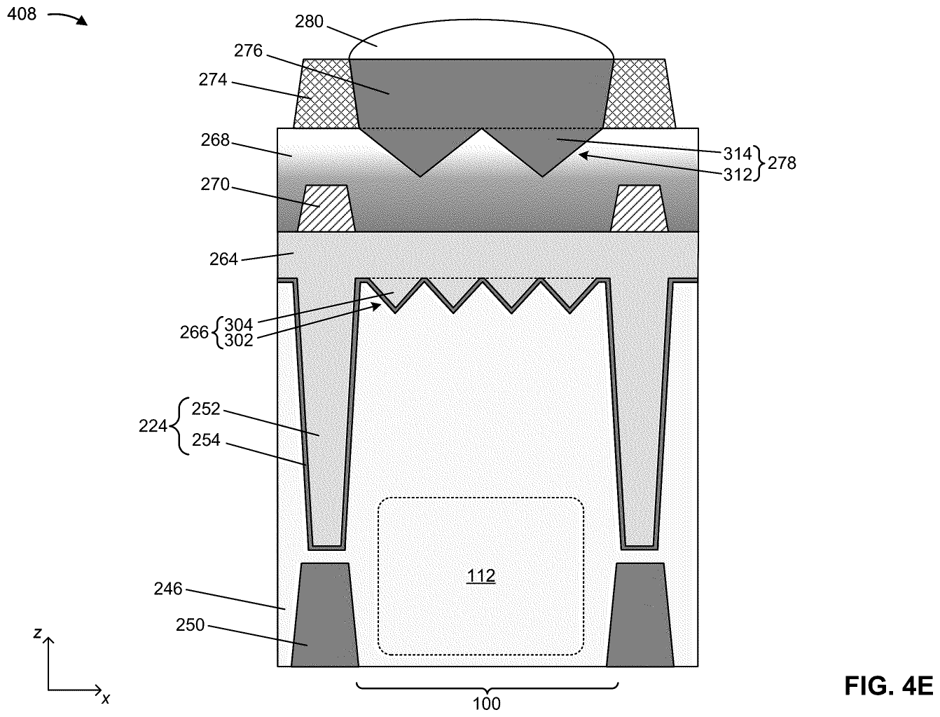

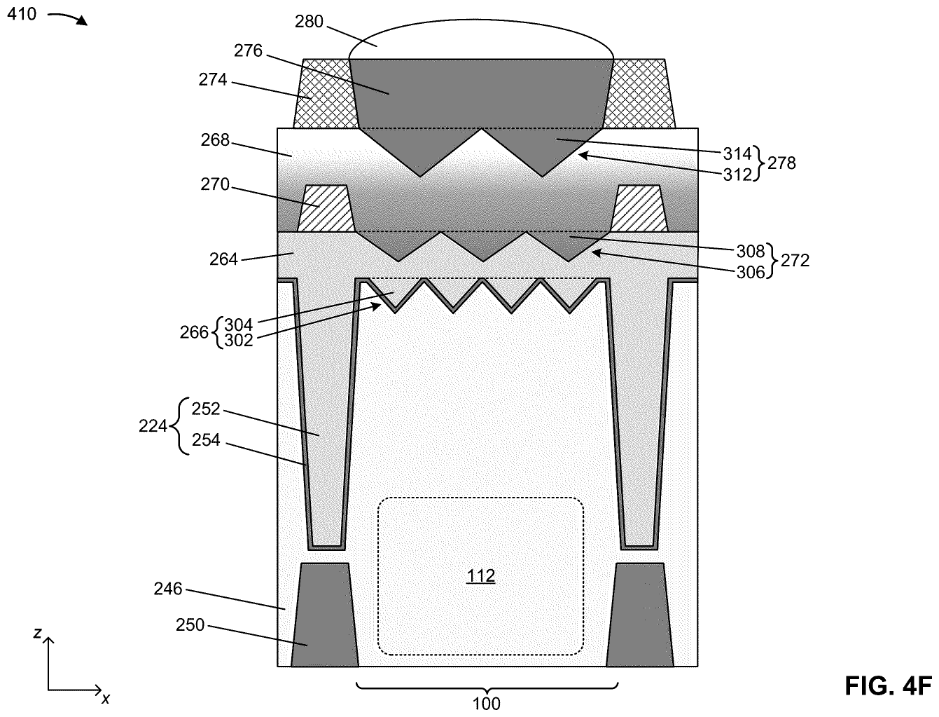

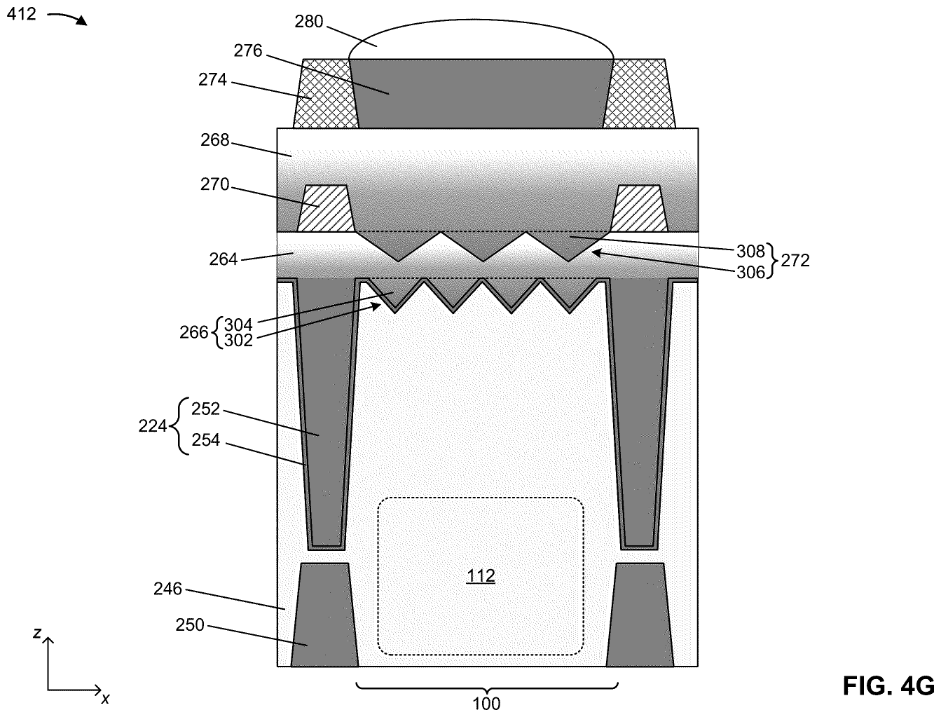

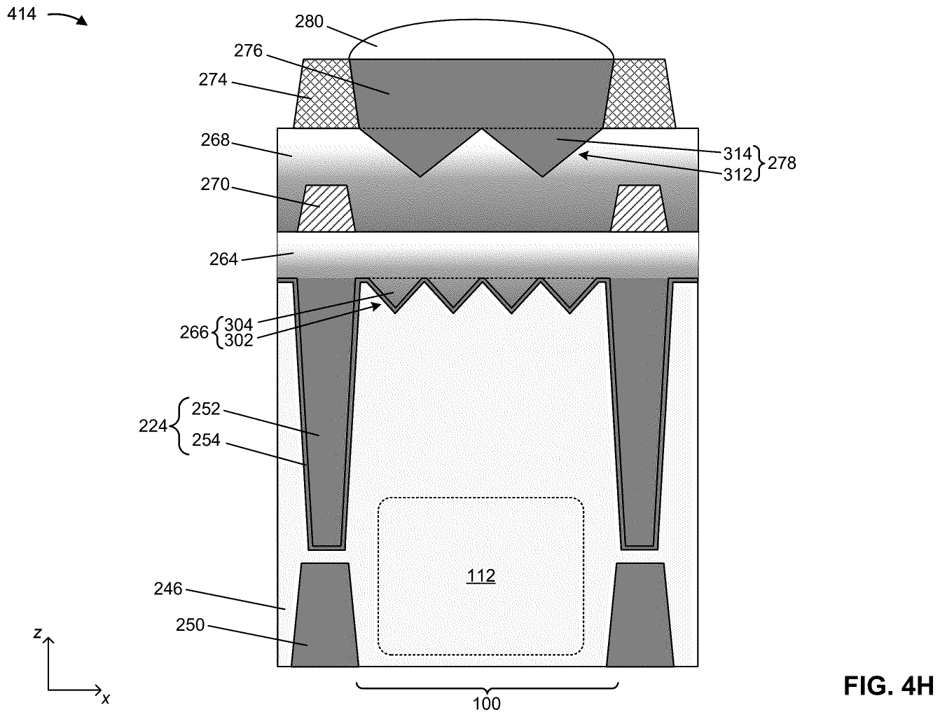

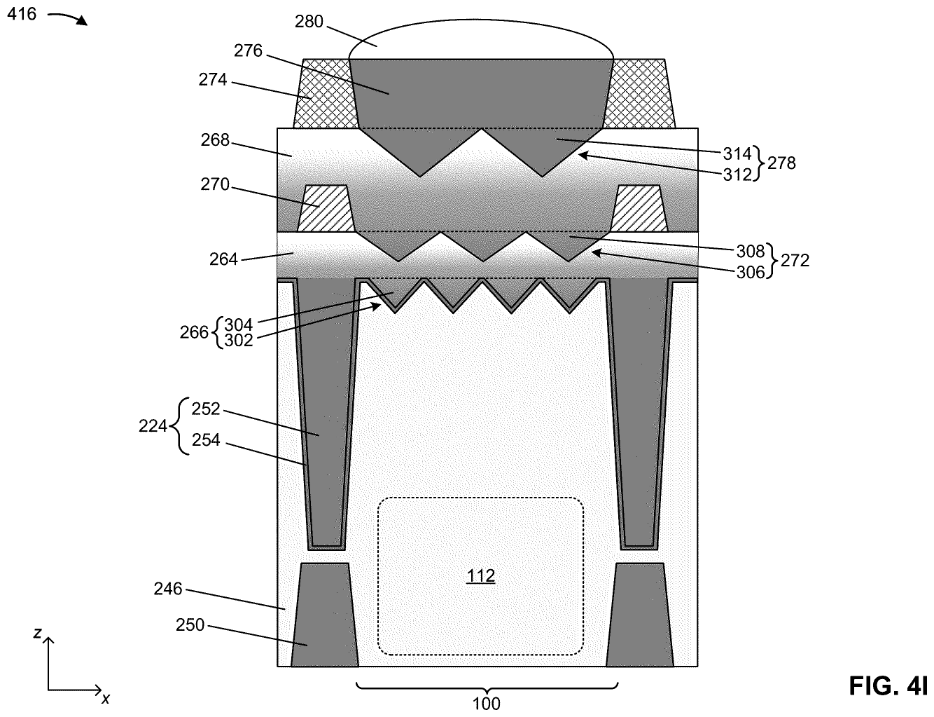

As illustrated and described in connection with various examples herein, such as in connection with FIGS. 3A-3G, 4A-4F, and/or 5A-5G, among other examples, a pixel sensor 100 may include two or more layers of diffusion structures to enable increased QE to be achieved for the pixel sensor 100. For example, a pixel sensor 100 may include a layer of diffusion structures 266 and a layer of diffusion structures 272, and the layer of diffusion structures 278 may be omitted. As another example, a pixel sensor 100 may include a layer of diffusion structures 266 and a layer of diffusion structures 278, and the layer of diffusion structures 272 may be omitted. As another example, a pixel sensor 100 may include a layer of diffusion structures 272 and a layer of diffusion structures 278, and the layer of diffusion structures 266 may be omitted. As another example, a pixel sensor 100 may include a layer of diffusion structures 266, a layer of diffusion structures 272, and a layer of diffusion structures 278. The various arrangements of the layers of diffusion structures described herein enable flexible placement of multiple layers of diffusion structures for achieving a high QE for particular combinations of wavelengths of incident light, for particular sizes of pixel sensors 100, and/or for flexibility in manufacturing of pixel sensors 100, among other examples.

Micro-lenses 280 may be included over and/or on the color filter regions 276. The micro-lenses 280 may include a respective micro-lens for each of the pixel sensors 100. A micro-lens may be formed to focus incident light toward a photodiode 112 of an associated pixel sensor 100.

As further shown in FIG. 2C, a metal layer 282 may be included above the substrate 246 in the BLC region 226 of the substrate 246. The metal layer 282 may be included as a light-blocking layer to prevent incident light from entering the portion of substrate 246 in the BLC region 226. The portion of substrate 246 in the BLC region 226 is thus a sensing region that is kept “dark” so that dark current measurements may be performed in the BLC region 226. A dark current measurement may be performed to measure the amount of charge (dark current) in the substrate 246 that is generated from sources other than incident light (e.g., from thermal energy in the substrate 246) so that the dark current measurement may be used for black level correction (or black level calibration) for the pixel sensor array 222.

As further shown in FIG. 2C, the bonding pad region 228 may include a plurality of dielectric layers 284, 286, 288, and/or 290 that electrically isolate a bonding pad structure 292. The bonding pad structure 292 is electrically coupled and/or physically coupled with one or more of the interconnect structures 260 in the interconnect layer 218 of the sensor die 208. A bonding pad opening 294 is included above the bonding pad structure 292 to enable an external electrical connection to be formed to the bonding pad structure 292.

The plurality of dielectric layers 284, 286, 288, and/or 290 may each include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples. The bonding pad structure 292 may include a metal material, such as gold (Au), copper (Cu), silver (Ag), cobalt (Co), tungsten (W), titanium (Ti), ruthenium (Ru), a metal alloy (e.g., aluminum copper (AlCu)), and/or a combination thereof, among other examples.

The seal ring region 230 includes a plurality of stacked interconnect structures 242 in the interconnect layer 214 and a plurality of stacked interconnect structures 260 in the interconnect layer 218 to seal the structures and layers of the image sensor device 210 to prevent ingress of humidity and other contaminants, as well as to provide structural rigidity to the image sensor device 210.

As indicated above, FIGS. 2A-2C are provided as examples. Other examples may differ from what is described with regard to FIGS. 2A-2C.

FIGS. 3A-3G are diagrams of examples of pixel sensors 100 that may be included in a pixel sensor array 222 of an image sensor device 210 described herein. As shown in FIG. 3A, an example 300 of a pixel sensor 100 includes a photodiode 112 in the substrate 246 of the sensor die 208. A color filter region 276 and a micro-lens 280 of the pixel sensor 100 are included above the photodiode 112. A DTI structure 224 is included in the substrate 246 and laterally surrounds the photodiode 112 in the substrate 246.

As further shown in FIG. 3A, a plurality of layers of diffusion structures are included above the photodiode 112. A layer of diffusion structures 266 is included between the substrate 246 and the buffer layer 264. The diffusion structures 266 are included between sections of the DTI structure 224. In a top view of the pixel sensor 100, the diffusion structures 266 are included within an inner perimeter of the portion of the DTI structure 224 around the photodiode 112. Each diffusion structure 266 is included in a recess 302 that extends into in the substrate 246. The recesses 302 are filed with portions 304 of dielectric material of the buffer layer 264 to form the diffusion structures 266. The diffusion structures 266, therefore, extend into the backside surface of the substrate 246.

The dielectric material (or material composition) of the diffusion structures 266 may have a refractive index that is less than a refractive index of the material of the substrate 246. The lesser refractive index of the dielectric material of the diffusion structures 266 reduces the likelihood of incident light being reflected off of an interface between the diffusion structures 266 and the substrate 246, and increases the likelihood of the incident light being refracted into the substrate 246. In some implementations, the material of the substrate 246 has a refractive index of approximately 4, and the dielectric material of the diffusion structures 266 has a refractive index of less than 4. In some implementations, the dielectric material of the diffusion structures 266 has a refractive index that is included in a range of approximately 1.5 to approximately 2.7. However, other values and ranges for the refractive index of the dielectric material of the diffusion structures 266 are within the scope of the present disclosure. Additionally and/or alternatively, the refractive index of the dielectric material of the diffusion structures 266 may be greater than the refractive index of the material of the substrate 246.

In some implementations, the dielectric material of the diffusion structures 266 includes a silicon nitride material (SiₓN_{y} such as Si₃N₄), a silicon-rich silicon nitride material (which increases the refractive index of the silicon nitride material), a silicon oxynitride material (SiON), a silicon oxide material (SiOₓ such as SiO or SiO₂), a nitrogen-rich silicon oxide material (which increases the refractive index of the silicon oxide material), a silicon-rich silicon oxide material (which increases the refractive index of the silicon oxide material), an oxygen-rich polysilicon material (which decreases the refractive index of the polysilicon material), a magnesium oxide material (MgOₓ such as MgO), an aluminum oxide material (AlₓO_{y} such as Al₂O₃), a ytterbium oxide material (YbₓO_{y} such as Yb₂O₃), a zinc oxide material (ZnOₓ such as ZnO), a tantalum oxide material (TaₓO_{y} such as Ta₂O₅), a zirconium oxide material (ZrOₓ such as ZrO₂), a hafnium oxide material (HfOₓ such as HfO₂), a tellurium oxide material (TeOₓ such as TeO₂), and/or a titanium oxide material (TiOₓ such as TiO₂), among other examples. In some implementations, the dielectric material of the diffusion structures 266 include a silicon oxide material doped with one or more types of dopants. Examples of such dopants include boron (B), phosphorous (P), barium (Ba), lanthanum (La), and/or lead (Pb), among other examples.

As further shown in FIG. 3A, another layer of diffusion structures 272 is included between the buffer layer 264 and the passivation layer 268. The diffusion structures 272 are included between sections of the metal grid structure 270. In a top view of the pixel sensor 100, the diffusion structures 272 are included within an inner perimeter of the portion of the metal grid structure 270 around the photodiode 112. Each diffusion structure 272 is included in a recess 306 that extends into in the substrate 246. The recesses 306 are filed with portions 308 of dielectric material of the passivation layer 268 to form the diffusion structures 272.

The dielectric material (or material composition) of the diffusion structures 272 may have a refractive index that is less than a refractive index of the material of the buffer layer 264. The lesser refractive index of the dielectric material of the diffusion structures 272 reduces the likelihood of incident light being reflected off of an interface between the diffusion structures 272 and the buffer layer 264, and increases the likelihood of the incident light being refracted into the substrate 246. In some implementations, the dielectric material of the diffusion structures 272 has a refractive index that is included in a range of approximately 1.4 to approximately 2. However, other values and ranges for the refractive index of the dielectric material of the diffusion structures 272 are within the scope of the present disclosure. Additionally and/or alternatively, the refractive index of the dielectric material of the diffusion structures 272 may be greater than the refractive index of the material of the buffer layer 264.

In some implementations, the dielectric material of the diffusion structures 272 includes an oxygen-rich silicon nitride material (which decreases the refractive index of the silicon nitride material), a silicon oxynitride material (SiON), a silicon oxide material (SiOₓ such as SiO or SiO₂), a nitrogen-rich silicon oxide material (which increases the refractive index of the silicon oxide material), a silicon-rich silicon oxide material (which increases the refractive index of the silicon oxide material), an oxygen-rich silicon oxide material (which decreases the refractive index of the silicon oxide material), a magnesium oxide material (MgOₓ such as MgO), an aluminum oxide material (AlₓO_{y} such as Al₂O₃), and/or a ytterbium oxide material (YbₓO_{y} such as Yb₂O₃), among other examples. In some implementations, the dielectric material of the diffusion structures 272 include a silicon oxide material doped with one or more types of dopants. Examples of such dopants include boron (B), phosphorous (P), barium (Ba), lanthanum (La), and/or lead (Pb), among other examples.

As further shown in FIG. 3A, the pixel sensor 100 may include a quantity of diffusion structures 266 than is greater than the quantity of diffusion structures 272. The greater quantity of the diffusion structures 266 may result from a cross-sectional width of the diffusion structures 266 (indicated in FIG. 3A as a dimension D1) being lesser than a cross-sectional width of the diffusion structures 272 (indicated in FIG. 3A as a dimension D2). This may result in the sidewalls of the diffusion structures 272 being more horizontal (e.g., having a greater angle between the sidewalls of a diffusion structure 272) than the sidewalls of the of the diffusion structures 266. The greater horizontality of the sidewalls of the diffusion structures 272 results in less lateral scattering of incident light at the level of the diffusion structures 272 than at the level of the diffusion structures 266 in the pixel sensor 100. Thus, the incident light becomes increasingly laterally diffused as the incident light approaches the photodiode 112. The less horizontal scattering of incident light at the level of the diffusion structures 272 in the pixel sensor 100 reduces the amount of incident light that is lost from being directed away from the photodiode 112. However, the dimension DI may alternatively be greater than the dimension D2, and the quantity of diffusion structures 272 may alternatively be greater than the quantity of the diffusion structures 266.

The depth or vertical (z-direction) thickness of the diffusion structures 266 (indicated in FIG. 3A as dimension D3) and the depth or vertical (z-direction) thickness of the diffusion structures 272 (indicated in FIG. 3A as dimension D4) may be approximately a same value. For example, the vertical thickness of the diffusion structures 266 and the vertical thickness of the diffusion structures 272 may each be included in a range of approximately 0.3 microns to approximately 0.4 microns. However, other values for the range are within the scope of the present disclosure. In some implementations, the vertical thickness of the diffusion structures 266 is greater than the vertical thickness of the diffusion structures 272. In some implementations, the vertical thickness of the diffusion structures 272 is greater than the vertical thickness of the diffusion structures 266.

FIG. 3B illustrates a cross-section view and a top view of the diffusion structures 266 in the example 300 of the pixel sensor 100. As shown in FIG. 3B, the diffusion structures 266 may each have a V-shaped cross-sectional profile. The diffusion structures 266 may each have an approximate inverted pyramidal three-dimensional shape. In the top view, the diffusion structures 266 are arranged in a grid (e.g., a 4×4 grid). In some implementations, the grid of the diffusion structures 266 is aligned with the DTI structure 224 such that the sections of the DTI structure 224 extend along the 4 sides of the grid of the diffusion structures 266, such as in implementations where the material of the substrate 246 has a <100> grain orientation. In other implementations, such as those in which the material of the substrate 246 has a <110> grain orientation, the grid of the diffusion structures 266 may be rotated relative to the DTI structure 224 such that the sections of the DTI structure 224 extend along the corners of the grid of the diffusion structures 266 is aligned with the DTI structure 224.

FIG. 3C illustrates a cross-section view and a top view of the diffusion structures 272 in the example 300 of the pixel sensor 100. As shown in FIG. 3C, the diffusion structures 272 may each have a V-shaped cross-sectional profile. Unlike the diffusion structures 266, the diffusion structures 272 may each have an approximate inverted conical three-dimensional shape. The cone shape of the diffusion structures 272 may result from the recesses 306 being formed in a dielectric layer (e.g., the buffer layer 264), whereas the pyramid shape of the diffusion structures 266 may result from the recesses 302 being formed in a silicon layer (e.g., the substrate 246). In the top view, the diffusion structures 272 are arranged in a grid (e.g., a 3×3 grid).

FIG. 3D illustrates an example 310 of a pixel sensor 100, which is similar to the example 300 of the pixel sensor 100 in FIG. 3A except that the example 310 of a pixel sensor 100 includes a layer of diffusion structures 278 instead of the layer of diffusion structures 272.

The diffusion structures 278 are included above the diffusion structures 266 and extend into the passivation layer 268. The diffusion structures 278 are included between sections of the metal grid structure 274. In a top view of the pixel sensor 100, the diffusion structures 278 are included within an inner perimeter of the portion of the metal grid structure 274 around the color filter region 276 of the pixel sensor 100. Each diffusion structure 278 is included in a recess 312 that extends into in the passivation layer 268. The recesses 312 are filed with portions 314 of dielectric material of the color filter region 276 to form the diffusion structures 278.

The dielectric material (or material composition) of the diffusion structures 278 may have a refractive index that is less than a refractive index of the material of the passivation layer 268. The lesser refractive index of the dielectric material of the diffusion structures 278 reduces the likelihood of incident light being reflected off of an interface between the diffusion structures 278 and the passivation layer 268, and increases the likelihood of the incident light being refracted into the substrate 246.

As further shown in FIG. 3D, the pixel sensor 100 may include a quantity of diffusion structures 266 than is greater than the quantity of diffusion structures 278. The greater quantity of the diffusion structures 266 may result from a cross-sectional width of the diffusion structures 266 (dimension D1) being lesser than a cross-sectional width of the diffusion structures 278 (indicated in FIG. 3D as a dimension D5). This may result in the sidewalls of the diffusion structures 278 being more horizontal (e.g., having a greater angle between the sidewalls of a diffusion structure 278) than the sidewalls of the of the diffusion structures 266. The greater horizontality of the sidewalls of the diffusion structures 278 results in less lateral scattering of incident light at the level of the diffusion structures 278 than at the level of the diffusion structures 266 in the pixel sensor 100. Thus, the incident light becomes increasingly laterally diffused as the incident light approaches the photodiode 112. The less horizontal scattering of incident light at the level of the diffusion structures 278 in the pixel sensor 100 reduces the amount of incident light that is lost from being directed away from the photodiode 112. However, the dimension DI may alternatively be greater than the dimension D5, and the quantity of diffusion structures 278 may alternatively be greater than the quantity of the diffusion structures 266.

The depth or vertical (z-direction) thickness of the diffusion structures 266 (dimension D3) and the depth or vertical (z-direction) thickness of the diffusion structures 278 (indicated in FIG. 3D as dimension D6) may be approximately a same value. For example, the vertical thickness of the diffusion structures 266 and the vertical thickness of the diffusion structures 278 may each be included in a range of approximately 0.3 microns to approximately 0.4 microns. However, other values for the range are within the scope of the present disclosure. In some implementations, the vertical thickness of the diffusion structures 266 is greater than the vertical thickness of the diffusion structures 278. In some implementations, the vertical thickness of the diffusion structures 278 is greater than the vertical thickness of the diffusion structures 266.

FIG. 3E illustrates a cross-section view and a top view of the diffusion structures 278 in the example 310 of the pixel sensor 100. As shown in FIG. 3E, the diffusion structures 278 may each have a V-shaped cross-sectional profile. Unlike the diffusion structures 266, the diffusion structures 278 may each have an approximate inverted conical three-dimensional shape. The cone shape of the diffusion structures 278 may result from the recesses 312 being formed in a dielectric layer (e.g., the passivation layer 268), whereas the pyramid shape of the diffusion structures 266 may result from the recesses 302 being formed in a silicon layer (e.g., the substrate 246). In the top view, the diffusion structures 278 are arranged in a grid (e.g., a 2×2 grid).

FIG. 3F illustrates an example 316 of a pixel sensor 100, which is similar to the example 300 of the pixel sensor 100 in FIG. 3A except that the example 316 of a pixel sensor 100 includes the layer of diffusion structures 266, the layer of diffusion structures 272, and the layer of diffusion structures 278. The diffusion structures 272 are included above the diffusion structures 266, and the diffusion structures 278 are included above the diffusion structures 272. Thus, the diffusion structures 266, 272, and 278 are vertically arranged in the z-direction in the pixel sensor 100. This provides three levels of diffusion or scattering of incident light. The cross-sectional width of the diffusion structures 278 (dimension D5) may be greater than the cross-sectional width of the diffusion structures 272 (dimension D2) such that the quantity of the diffusion structures 272 is greater than the quantity of the diffusion structures 278. Alternatively, the quantity of the diffusion structures 278 may be greater than the quantity of the diffusion structures 272, and/or the cross-sectional width of the diffusion structures 278 (dimension D5) may be less than the cross-sectional width of the diffusion structures 272 (dimension D2).

FIG. 3G illustrates an example 318 of a pixel sensor 100, which is similar to the example 316 of the pixel sensor 100 in FIG. 3F except that the layer of diffusion structures 266 is omitted from the pixel sensor 100 in the example 318. The diffusion structures 278 are included above the diffusion structures 272. Thus, the diffusion structures 272 and 278 are vertically arranged in the z-direction in the pixel sensor 100.

As indicated above, FIGS. 3A-3G are provided as examples. Other examples may differ from what is described with regard to FIGS. 3A-3G. For example, a pixel sensor 100 may include greater than three layers of diffusion structures that are vertically arranged.

FIGS. 4A-4I are diagrams of examples of pixel sensors 100 that may be included in a pixel sensor array 222 of an image sensor device 210 described herein. In the examples of pixel sensors 100 illustrated in FIGS. 4A-4I, the buffer layer 264 and/or the passivation layer 268 include a material composition gradient such that a refractive index gradient (e.g., a vertical gradient in the z-direction) occurs in buffer layer 264 and/or a refractive index gradient occurs in the passivation layer 268. The refractive index gradient in the buffer layer 264 and/or in the passivation layer 268 facilitate bending of incident light between the micro-lens 280 and the substrate 246. In this way, the incident light may be directed on a more vertically oriented path between layers of diffusion structures in the pixel sensors 100.

As shown in FIG. 4A, an example 400 of a pixel sensor 100 is similar to the example 300 of the pixel sensor 100 in FIG. 3A, except that a refractive index gradient is included in the buffer layer 264. In some implementations, the refractive index in the buffer layer 264 increases from the top of the buffer layer 264 to a bottom of the buffer layer 264. In some implementations, the refractive index in the buffer layer 264 decreases from the top of the buffer layer 264 to a bottom of the buffer layer 264. In some implementations, the refractive index in the buffer layer 264 increases from the top to a center of the buffer layer 264, and decreases from the center of the buffer layer 264 to a bottom of the buffer layer 264. In some implementations, the refractive index in the buffer layer 264 decreases from the top to a center of the buffer layer 264, and increases from the center of the buffer layer 264 to a bottom of the buffer layer 264.

In some implementations, the refractive index gradient in the buffer layer 264 may be achieved by doping the dielectric material with a particular doping profile. For example, the buffer layer 264 may be doped with one or more types of dopants such that the dopant concentration increases from the top to the bottom of the buffer layer 264. As another example, the buffer layer 264 may be doped with one or more types of dopants such that the dopant concentration decreases from the top to the bottom of the buffer layer 264. As another example, the buffer layer 264 may be doped with one or more types of dopants such that the dopant concentration of a first dopant increases from the top to the bottom of the buffer layer 264, and such that the dopant concentration of a second dopant decreases from the top to the bottom of the buffer layer 264.

In some implementations, the refractive index gradient in the buffer layer 264 may be achieved by forming an oxygen concentration gradient in the dielectric material. For example, the oxygen concentration may increase from the top to the bottom of the buffer layer 264. As another example, the oxygen concentration may decrease from the top to the bottom of the buffer layer 264.

In some implementations, the refractive index gradient in the buffer layer 264 may be achieved by forming a nitrogen concentration gradient in the dielectric material. For example, the nitrogen concentration may increase from the top to the bottom of the buffer layer 264. As another example, the nitrogen concentration may decrease from the top to the bottom of the buffer layer 264.

In some implementations, the refractive index gradient in the buffer layer 264 may be achieved by forming a silicon concentration gradient in the dielectric material. For example, the silicon concentration may increase from the top to the bottom of the buffer layer 264. As another example, the silicon concentration may decrease from the top to the bottom of the buffer layer 264.

FIG. 4B illustrates an example 402 of a pixel sensor 100. The example 402 of the pixel sensor 100 is similar to the example 310 of the pixel sensor 100 in FIG. 3B, except that the example 402 of a pixel sensor 100 includes the refractive index gradient in the buffer layer 264 included in the example 400 of the pixel sensor 100 of FIG. 4A.

FIG. 4C illustrates an example 404 of a pixel sensor 100. The example 404 of the pixel sensor 100 is similar to the example 316 of the pixel sensor 100 in FIG. 3F, except that the example 404 of a pixel sensor 100 includes the refractive index gradient in the buffer layer 264 included in the example 400 of the pixel sensor 100 of FIG. 4A.

FIG. 4D illustrates an example 406 of a pixel sensor 100, which is similar to the example 300 of the pixel sensor 100 in FIG. 3A except that a refractive index gradient is included in the passivation layer 268. In some implementations, the refractive index in the passivation layer 268 increases from the top of the passivation layer 268 to a bottom of the passivation layer 268. In some implementations, the refractive index in the passivation layer 268 decreases from the top of the passivation layer 268 to a bottom of the passivation layer 268. In some implementations, the refractive index in the passivation layer 268 increases from the top to a center of the passivation layer 268, and decreases from the center of the passivation layer 268 to a bottom of the passivation layer 268. In some implementations, the refractive index in the passivation layer 268 decreases from the top to a center of the passivation layer 268, and increases from the center of the passivation layer 268 to a bottom of the passivation layer 268.

In some implementations, the refractive index gradient in the passivation layer 268 may be achieved by doping the dielectric material with a particular doping profile. For example, the passivation layer 268 may be doped with one or more types of dopants such that the dopant concentration increases from the top to the bottom of the passivation layer 268. As another example, the passivation layer 268 may be doped with one or more types of dopants such that the dopant concentration decreases from the top to the bottom of the passivation layer 268. As another example, the passivation layer 268 may be doped with one or more types of dopants such that the dopant concentration of a first dopant increases from the top to the bottom of the passivation layer 268, and such that the dopant concentration of a second dopant decreases from the top to the bottom of the passivation layer 268.

In some implementations, the refractive index gradient in the passivation layer 268 may be achieved by forming an oxygen concentration gradient in the dielectric material. For example, the oxygen concentration may increase from the top to the bottom of the passivation layer 268. As another example, the oxygen concentration may decrease from the top to the bottom of the passivation layer 268.

In some implementations, the refractive index gradient in the passivation layer 268 may be achieved by forming a nitrogen concentration gradient in the dielectric material. For example, the nitrogen concentration may increase from the top to the bottom of the passivation layer 268. As another example, the nitrogen concentration may decrease from the top to the bottom of the passivation layer 268.

In some implementations, the refractive index gradient in the passivation layer 268 may be achieved by forming a silicon concentration gradient in the dielectric material. For example, the silicon concentration may increase from the top to the bottom of the passivation layer 268. As another example, the silicon concentration may decrease from the top to the bottom of the passivation layer 268.

FIG. 4E illustrates an example 408 of a pixel sensor 100. The example 408 of the pixel sensor 100 is similar to the example 310 of the pixel sensor 100 in FIG. 3B, except that the example 408 of a pixel sensor 100 includes the refractive index gradient in the passivation layer 268 included in the example 406 of the pixel sensor 100 of FIG. 4D.

FIG. 4F illustrates an example 410 of a pixel sensor 100. The example 410 of the pixel sensor 100 is similar to the example 316 of the pixel sensor 100 in FIG. 3F, except that the example 410 of a pixel sensor 100 includes the refractive index gradient in the passivation layer 268 included in the example 406 of the pixel sensor 100 of FIG. 4D.

FIG. 4G illustrates an example 412 of a pixel sensor 100. The example 412 of the pixel sensor 100 is similar to the example 300 of the pixel sensor 100 in FIG. 3A, except that the example 412 of a pixel sensor 100 includes a combination of the refractive index gradient in the buffer layer 264 included in the example 400 of the pixel sensor 100 of FIG. 4A and the refractive index gradient in the passivation layer 268 included in the example 406 of the pixel sensor 100 of FIG. 4D.

FIG. 4H illustrates an example 414 of a pixel sensor 100. The example 414 of the pixel sensor 100 is similar to the example 310 of the pixel sensor 100 in FIG. 3B, except that the example 414 of a pixel sensor 100 includes a combination of the refractive index gradient in the buffer layer 264 included in the example 400 of the pixel sensor 100 of FIG. 4A and the refractive index gradient in the passivation layer 268 included in the example 406 of the pixel sensor 100 of FIG. 4D.

FIG. 4I illustrates an example 416 of a pixel sensor 100. The example 416 of the pixel sensor 100 is similar to the example 316 of the pixel sensor 100 in FIG. 3F, except that the example 416 of a pixel sensor 100 includes a combination of the refractive index gradient in the buffer layer 264 included in the example 400 of the pixel sensor 100 of FIG. 4A and the refractive index gradient in the passivation layer 268 included in the example 406 of the pixel sensor 100 of FIG. 4D.

As indicated above, FIGS. 4A-4I are provided as examples. Other examples may differ from what is described with regard to FIGS. 4A-4I.

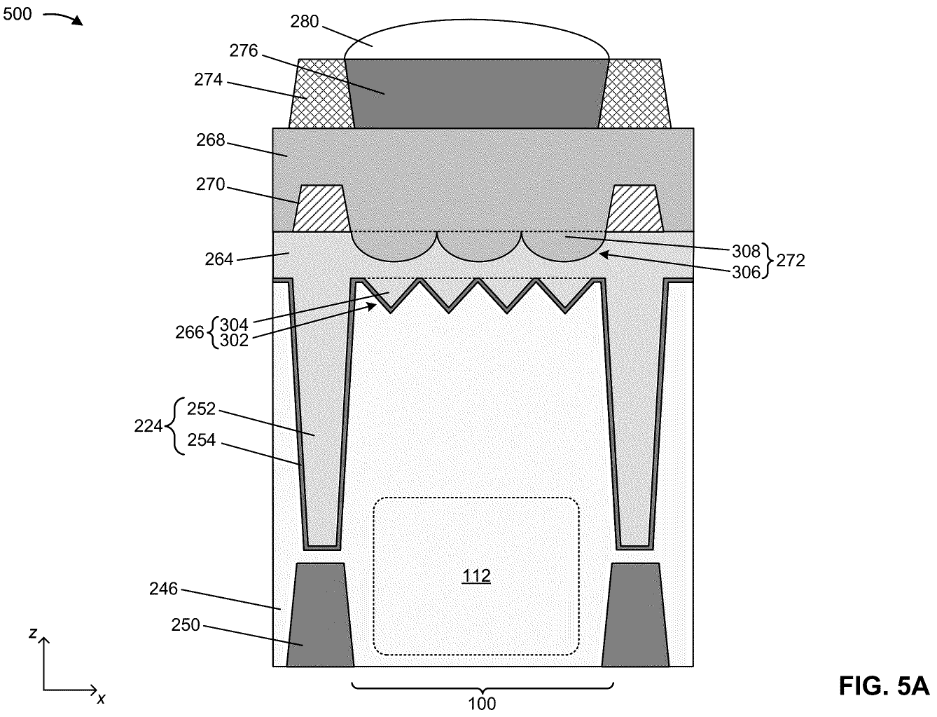

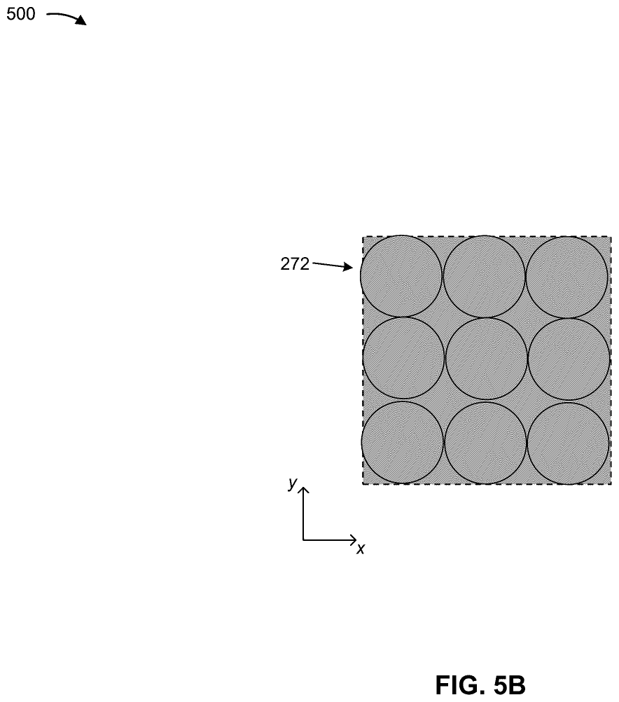

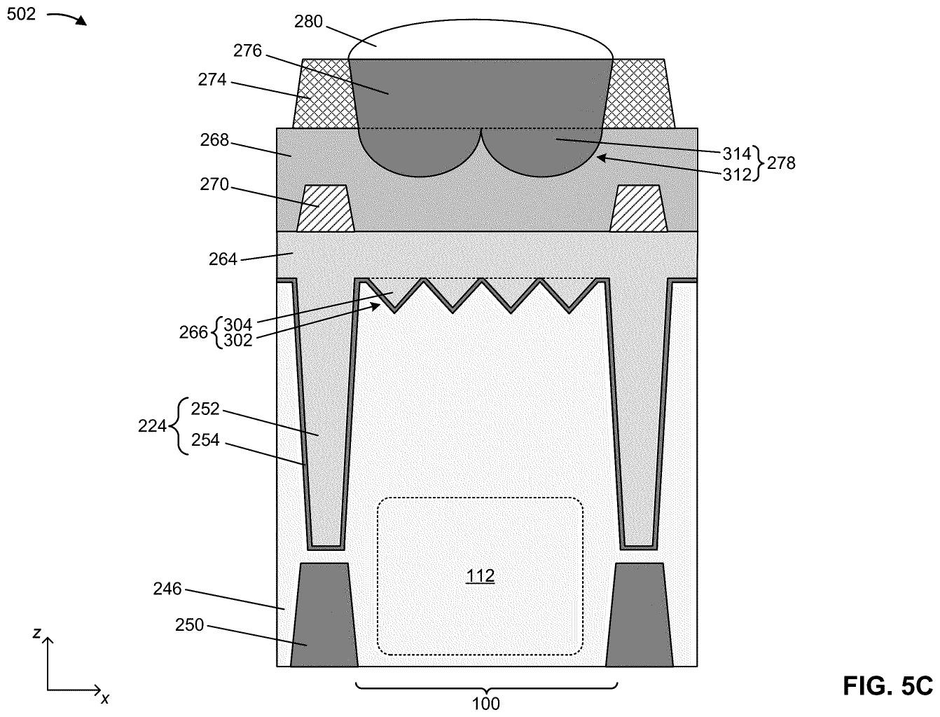

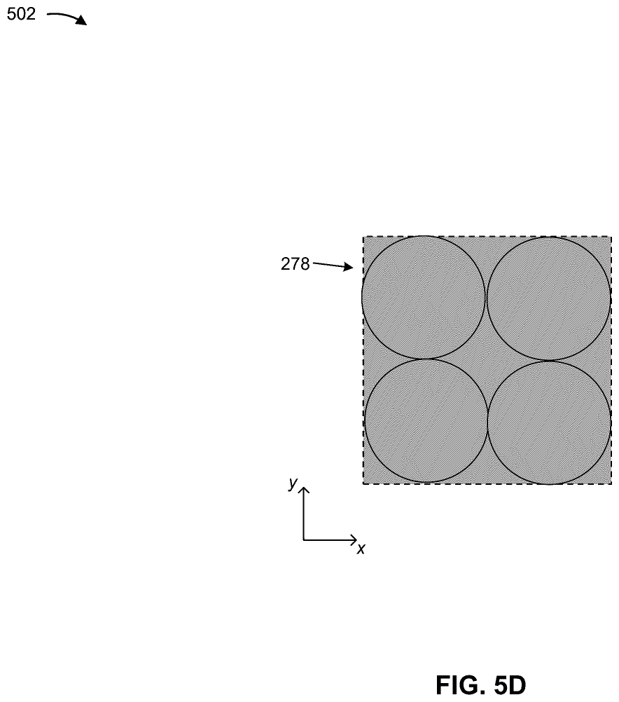

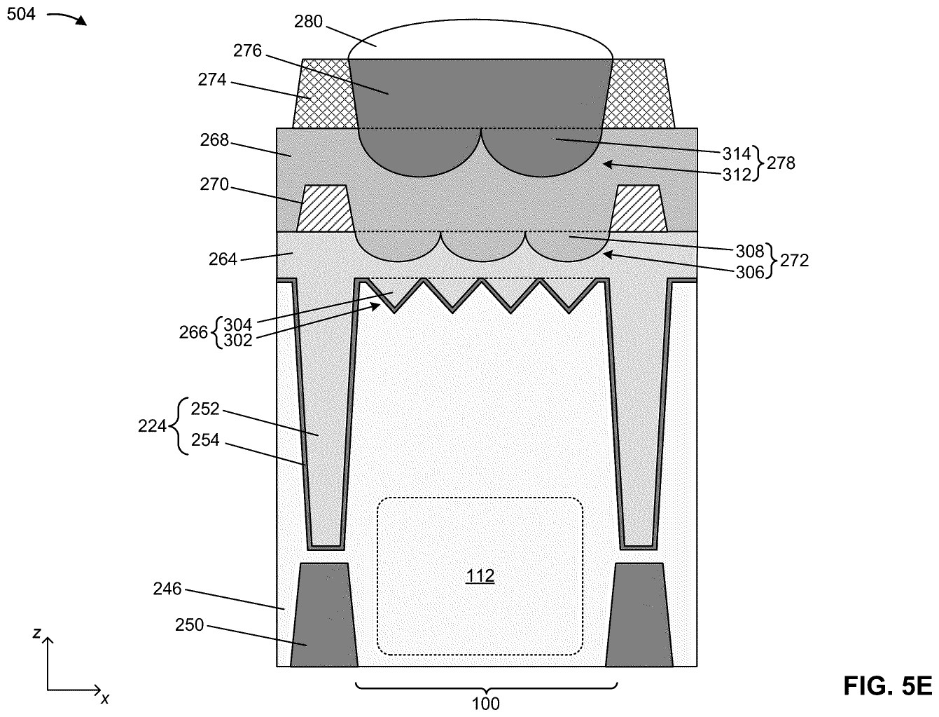

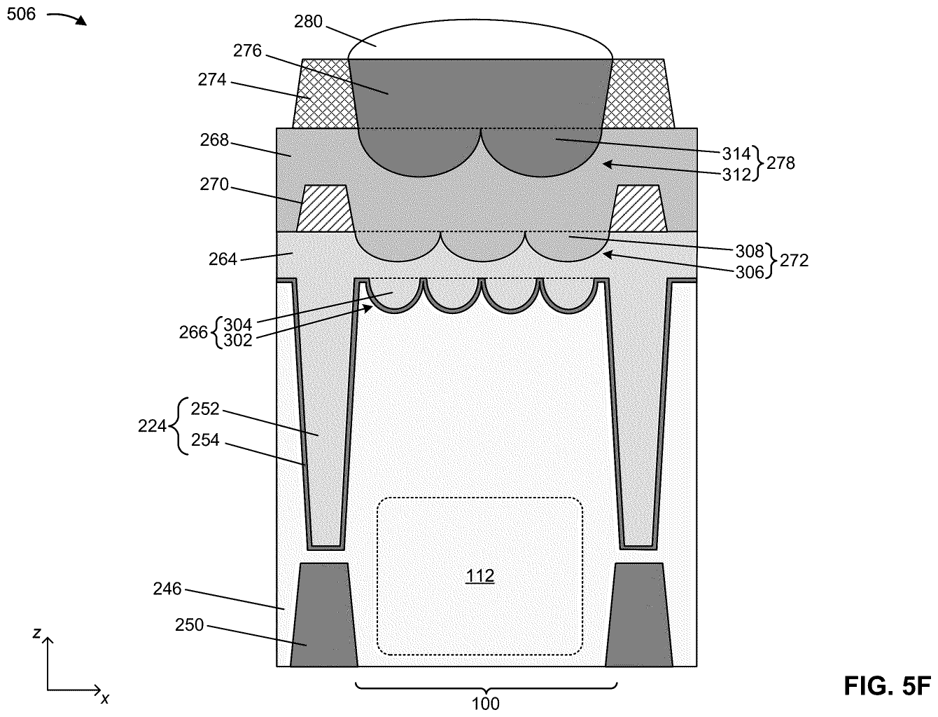

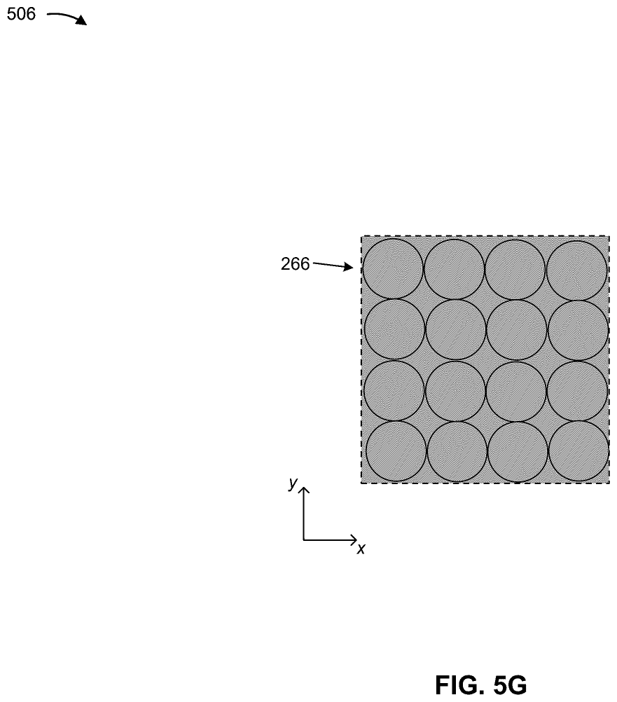

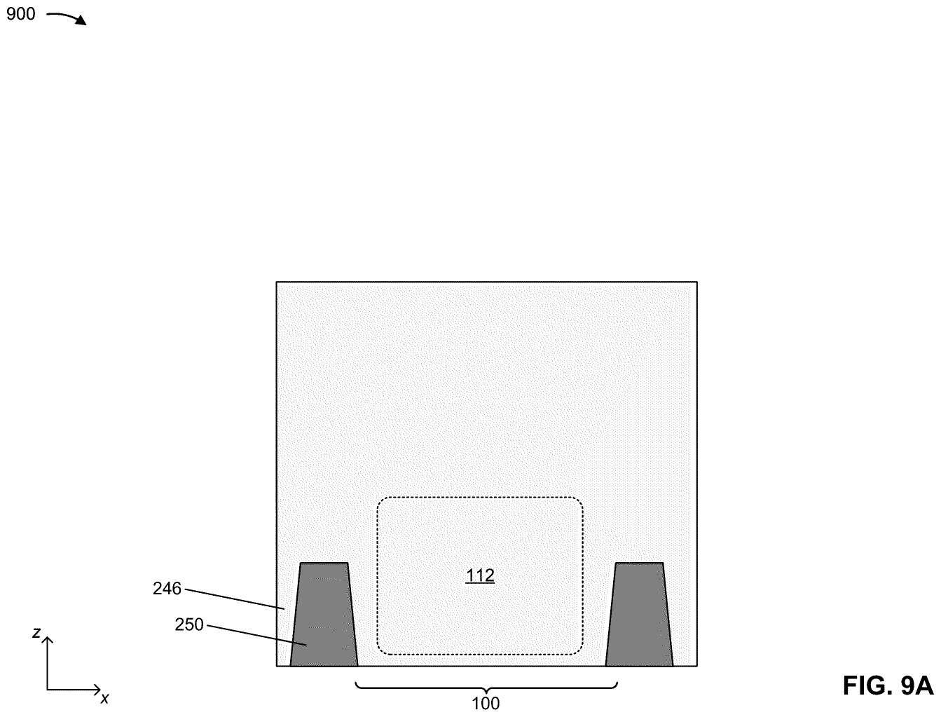

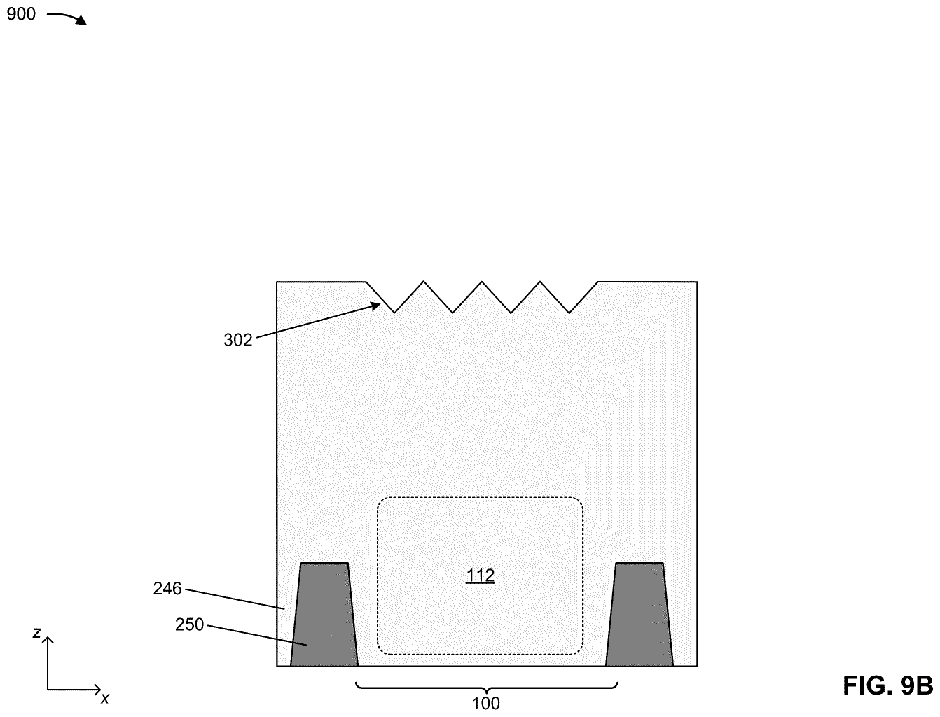

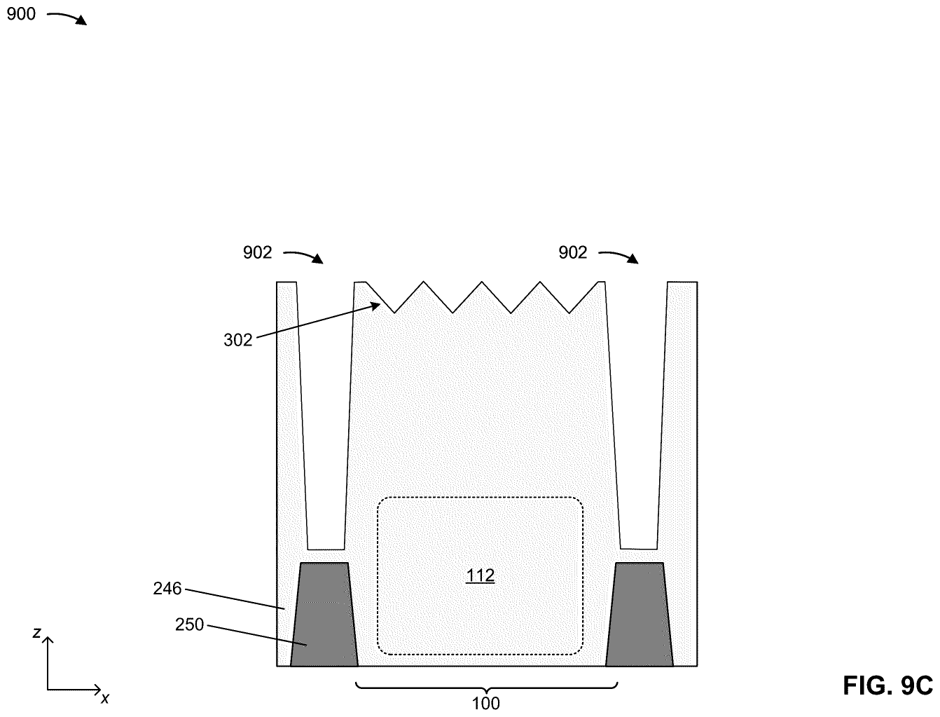

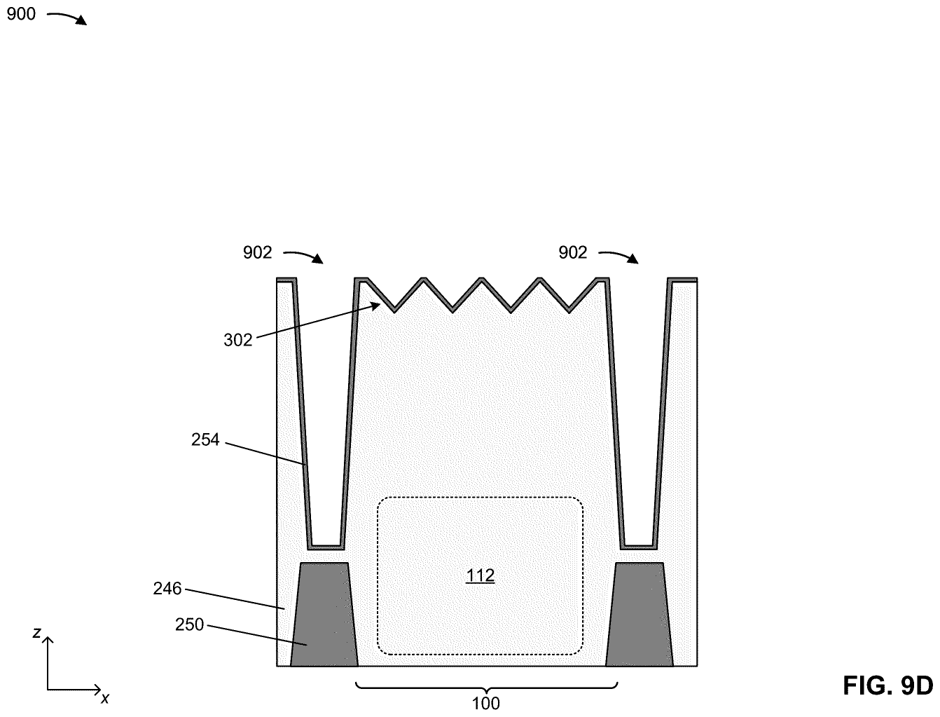

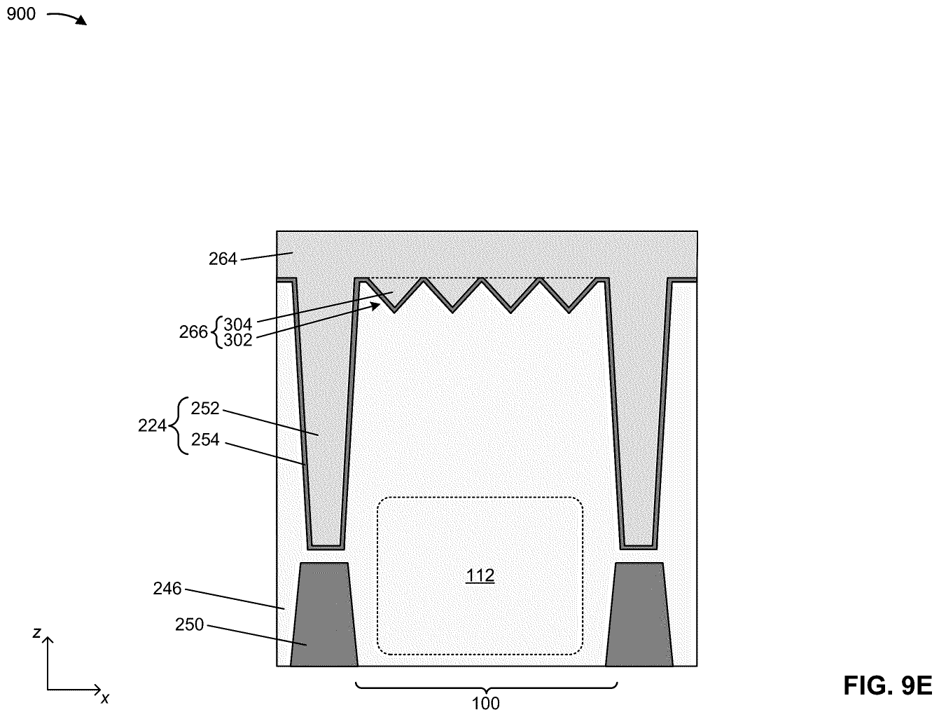

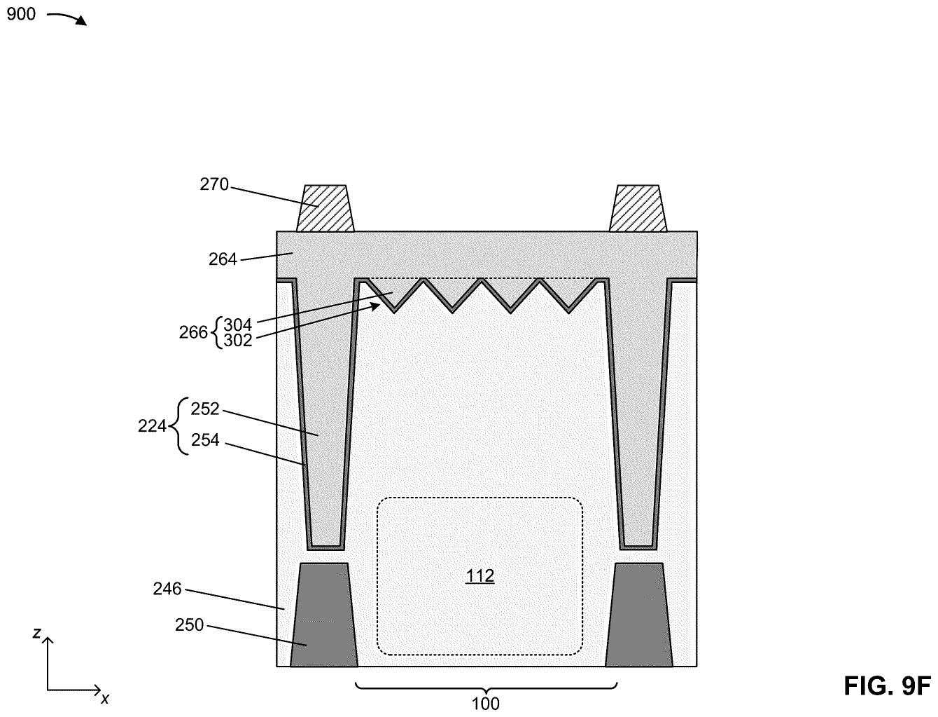

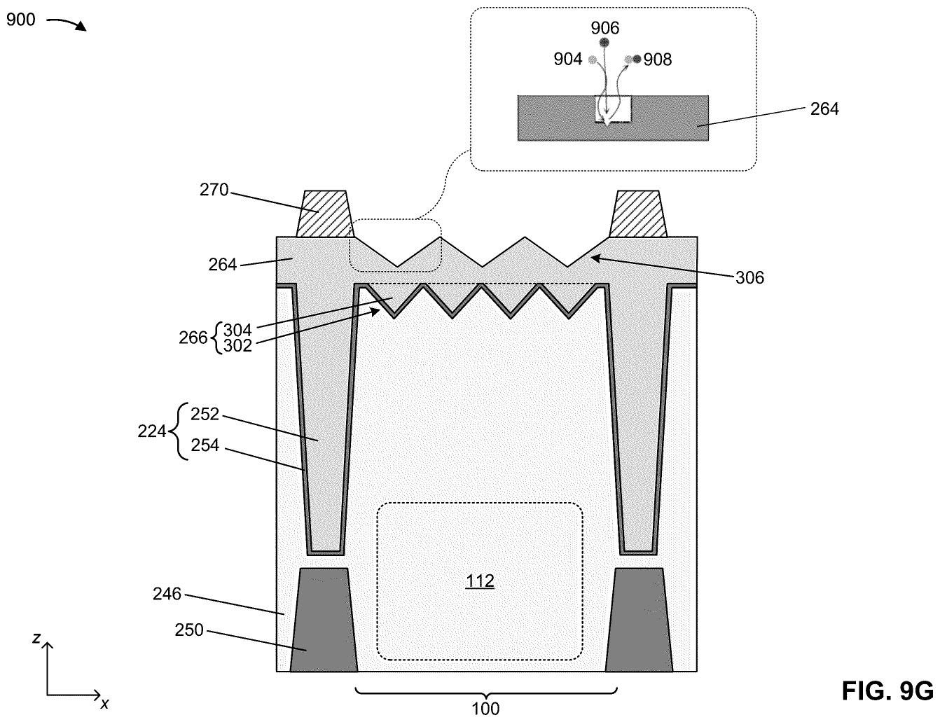

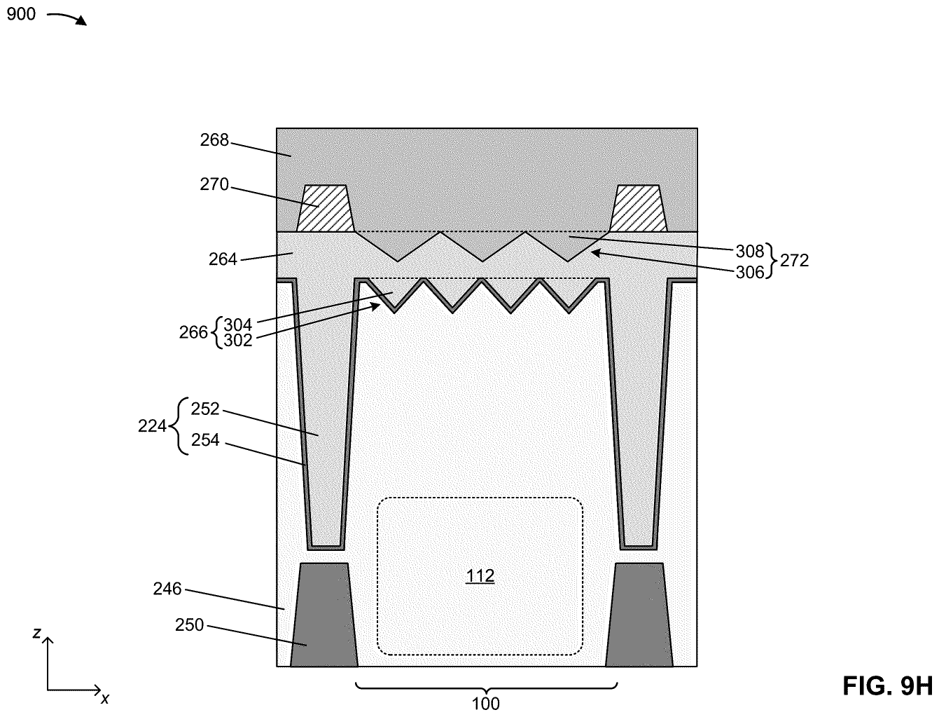

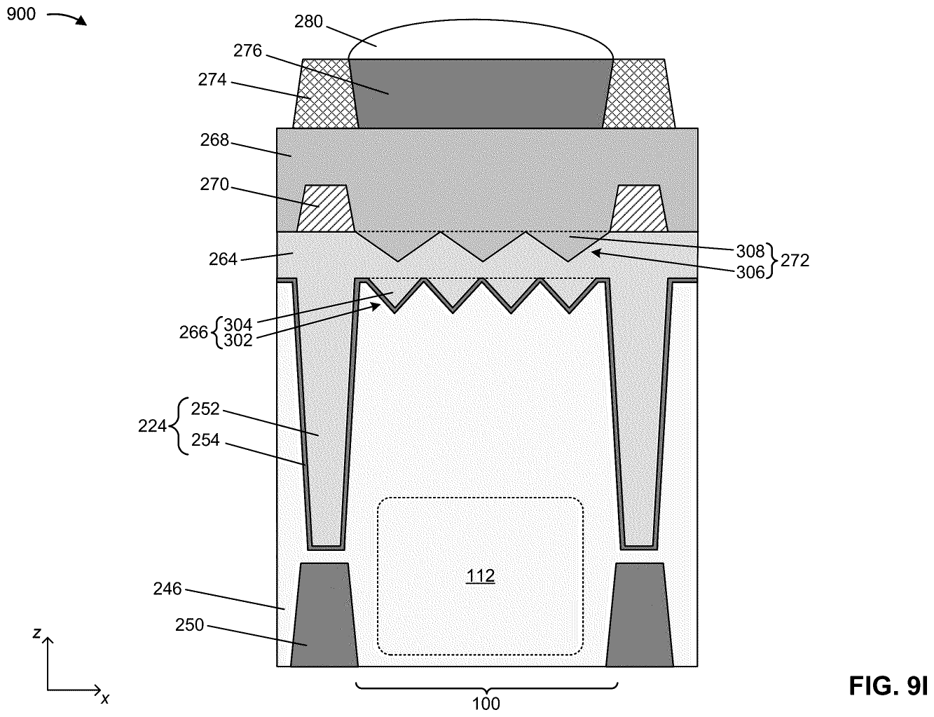

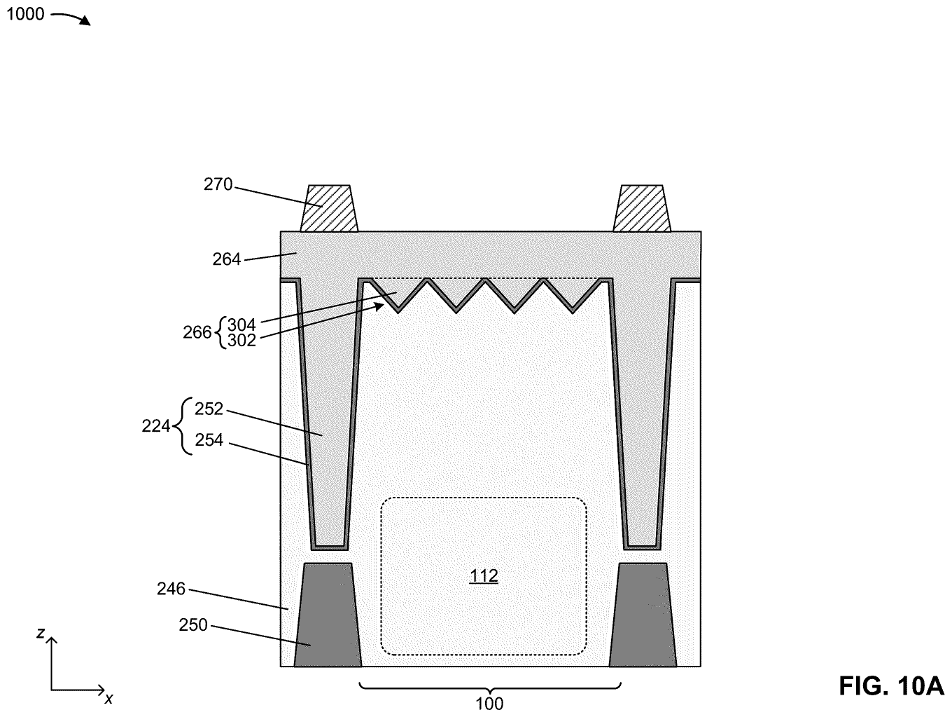

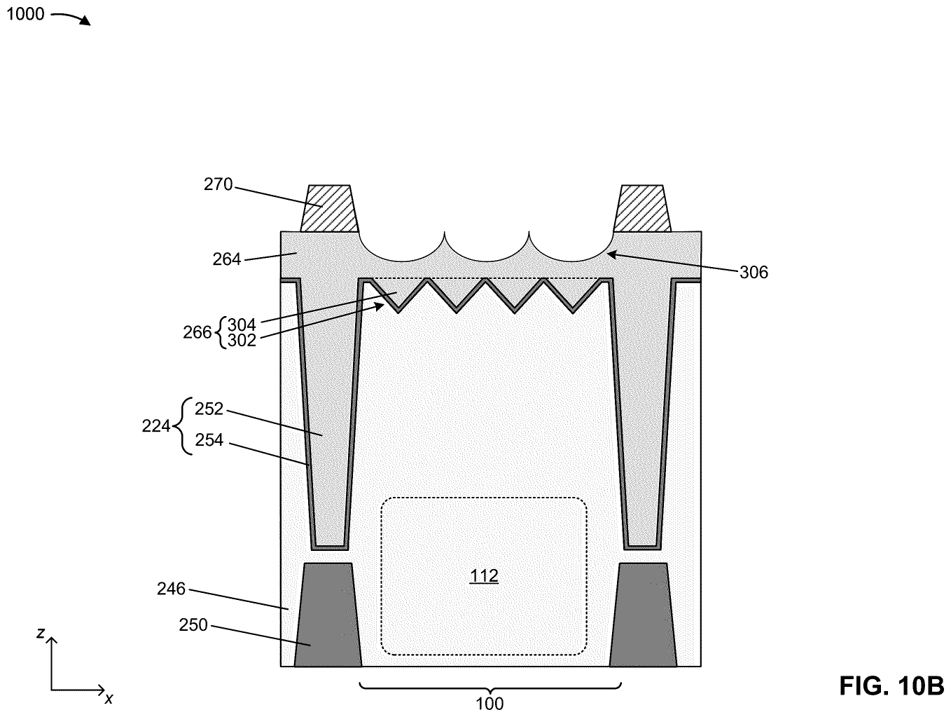

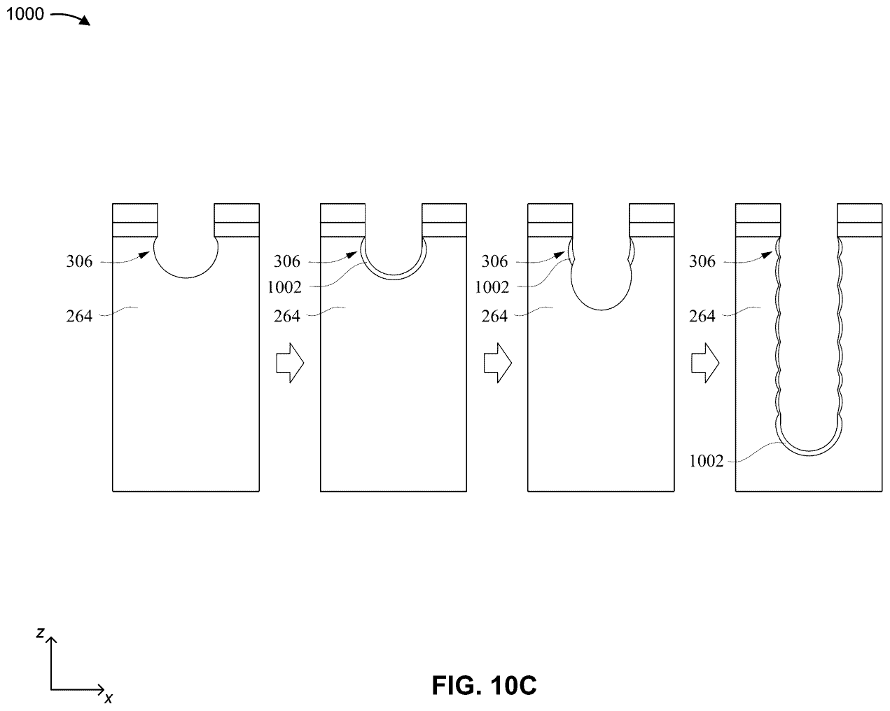

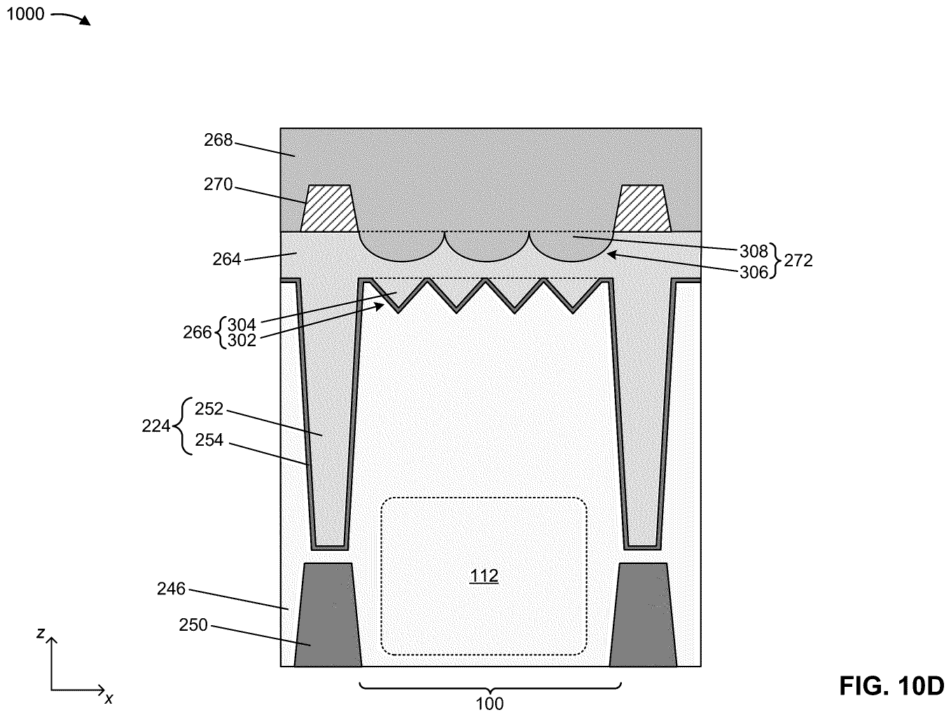

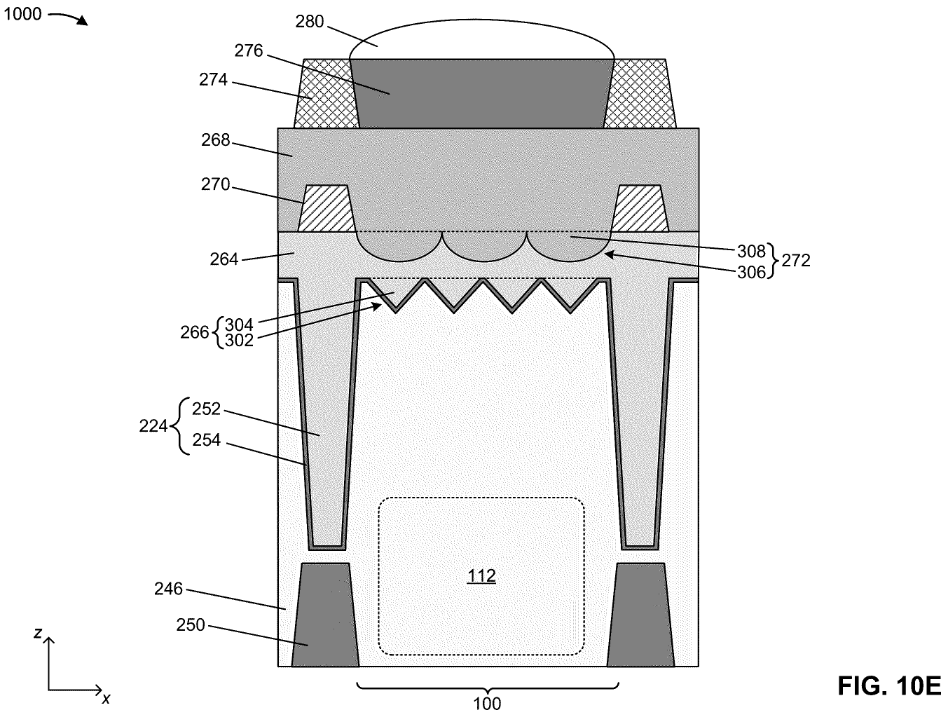

FIGS. 5A-5G are diagrams of examples of pixel sensors 100 that may be included in a pixel sensor array 222 of an image sensor device 210 described herein. In the examples of pixel sensors 100 illustrated in FIGS. 5A-5G, one or more layers of diffusion structures 266, 272, and/or 278 include diffusion structures having a rounded or approximate U-shaped cross-sectional profile and an approximate semi-spherical three-dimensional shape. The semi-spherical three-dimensional shape of the diffusion structures may result from using different semiconductor processing techniques to form the diffusion structures than those used to form diffusion structures having an approximate pyramidal three-dimensional shape or an approximate conical three-dimensional shape. Example technique(s) used to form diffusion structures having an approximate pyramidal three-dimensional shape or an approximate conical three-dimensional shape are described in connection with FIGS. 9A-9I. Example technique(s) used to form diffusion structures having an approximate semi-spherical three-dimensional shape are described in connection with FIGS. 10A-10E.

As shown in FIG. 5A, an example 500 of a pixel sensor 100 is similar to the example 300 of the pixel sensor 100 in FIG. 3A, except that the diffusion structures 272 have a rounded or approximate U-shaped cross-sectional profile (in which case the diffusion structures 272 may each have an approximate semi-spherical three-dimensional shape). As shown in a top view of the diffusion structures 272 in FIG. 5B, the diffusion structures 272 may have an approximate circular top view shape and are arranged in a grid (e.g., a 3×3 grid).

As shown in FIG. 5C, an example 502 of a pixel sensor 100 is similar to the example 310 of the pixel sensor 100 in FIG. 3D, except that the diffusion structures 278 have a rounded or approximate U-shaped cross-sectional profile (in which case the diffusion structures 278 may each have an approximate semi-spherical three-dimensional shape). As shown in a top view of the diffusion structures 278 in FIG. 5D, the diffusion structures 278 may have an approximate circular top view shape and are arranged in a grid (e.g., a 2×2 grid).

As shown in FIG. 5E, an example 504 of a pixel sensor 100 is similar to the example 316 of the pixel sensor 100 in FIG. 3F, except that the diffusion structures 272 and the diffusion structures 278 each have a rounded or approximate U-shaped cross-sectional profile (in which case the diffusion structures 272 and the diffusion structures 278 each may have an approximate semi-spherical three-dimensional shape).

As shown in FIG. 5F, an example 506 of a pixel sensor 100 is similar to the example 316 of the pixel sensor 100 in FIG. 3F, except that the diffusion structures 266, the diffusion structures 272, and the diffusion structures 278 each have a rounded or approximate U-shaped cross-sectional profile (in which case the diffusion structures 266, the diffusion structures 272, and the diffusion structures 278 each may have an approximate semi-spherical three-dimensional shape). As shown in a top view of the diffusion structures 278 in FIG. 5G, the diffusion structures 266 may have an approximate circular top view shape and are arranged in a grid (e.g., a 4×4 grid).

As indicated above, FIGS. 5A-5G are provided as examples. Other examples may differ from what is described with regard to FIGS. 5A-5G.

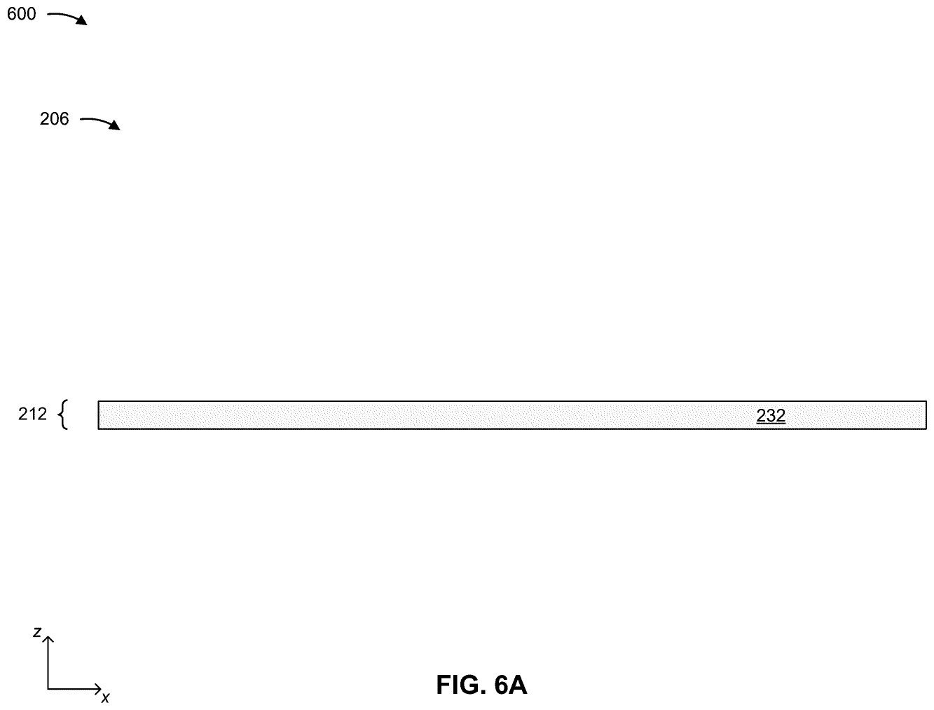

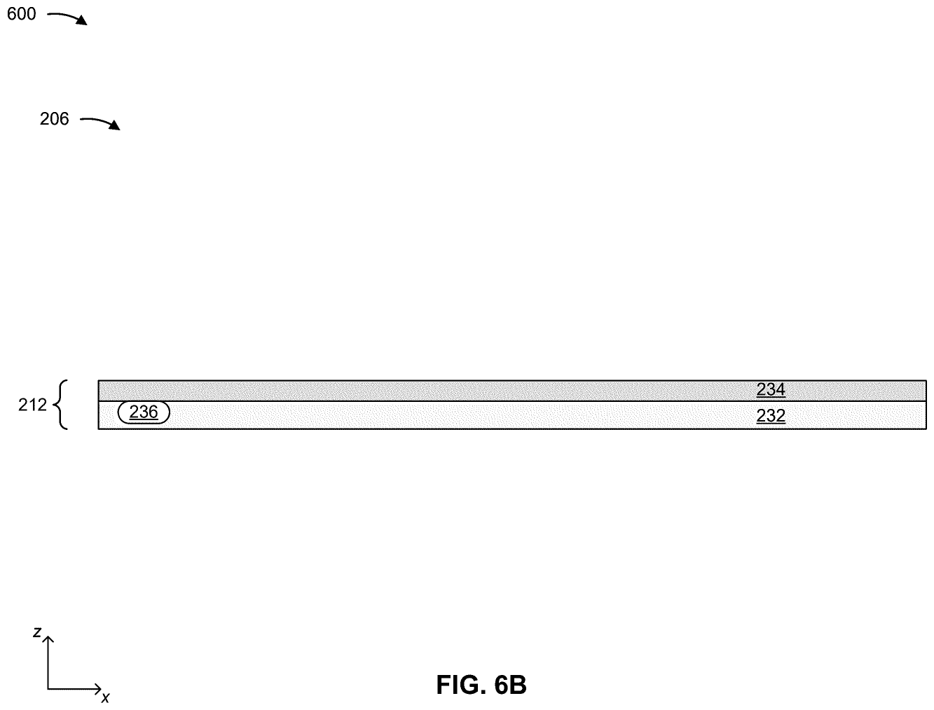

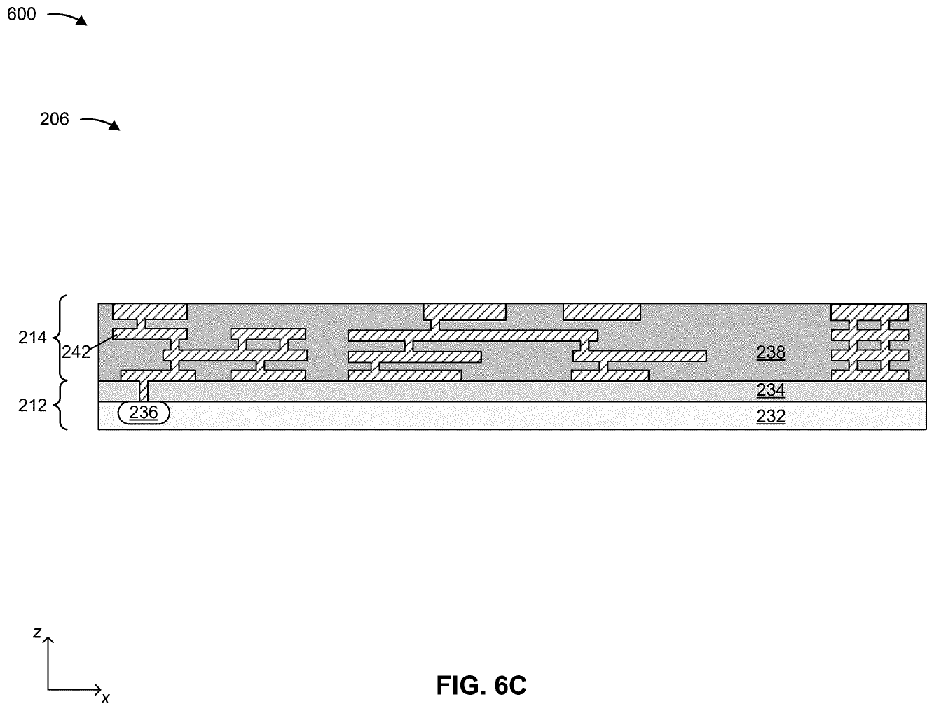

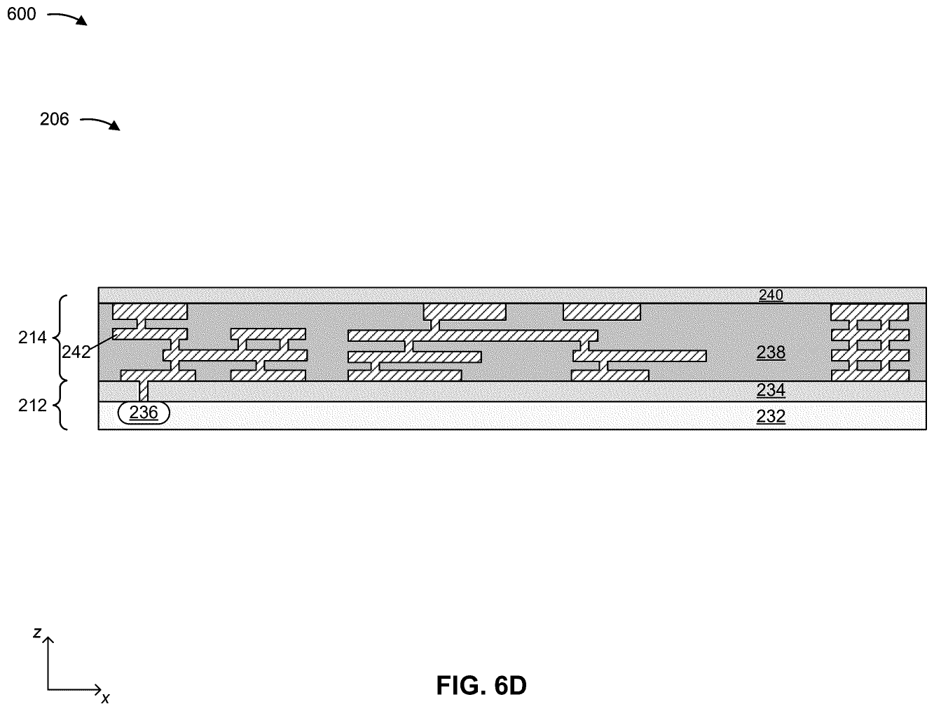

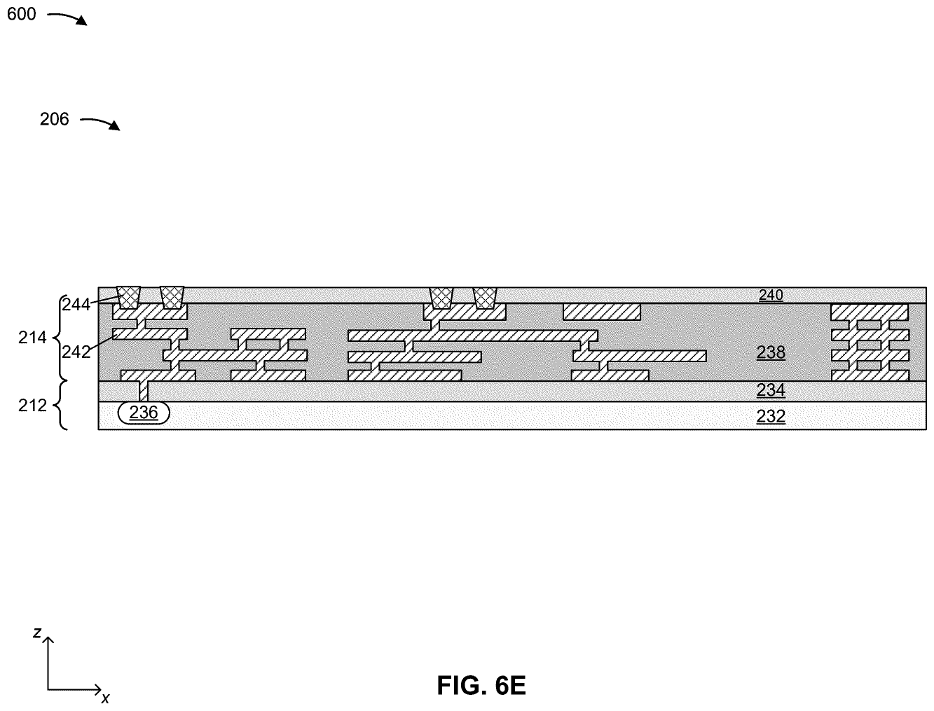

FIGS. 6A-6E are diagrams of an example implementation 600 of forming a circuitry die 206 (or a portion thereof) described herein. In some implementations, one or more of the semiconductor processing operations described in connection with FIGS. 6A-6E may be performed using one or more semiconductor processing tools, such as a deposition tool, an exposure tool, a developer tool, an etch tool, a planarization tool, a plating tool, an ion implantation tool, and/or a wafer/die transport tool, among other examples.

Turning to FIG. 6A, the substrate 232 of the device layer 212 of the circuitry die 206 is provided. The substrate 232 may be provided in the form of a semiconductor wafer such as a silicon (Si) wafer may be provided as an SOI wafer, and/or another type of semiconductor work piece.

As shown in FIG. 6B, one or more integrated circuit devices 236 may be formed in and/or on the substrate 232. One or more semiconductor processing tools may be used to form one or more portions of the integrated circuit devices 236. For example, a deposition tool may be used to perform various deposition operations to deposit layers of the integrated circuit devices 236, and/or to deposit photoresist layers for etching the substrate 232 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 232 and/or portions of the deposited layers to form the integrated circuit devices 236. As another example, a planarization tool may be used to planarize portions of the integrated circuit devices 236. As another example, a plating tool may be used to deposit metal structures and/or layers of the integrated circuit devices 236.

As further shown in FIG. 6B, a dielectric layer 234 may be deposited over and/or on the substrate 232 and over and/or on the integrated circuit devices 236. A deposition tool may be used to deposit the dielectric layer 234 using a physical vapor deposition (PVD) technique, an atomic layer deposition (ALD) technique, a chemical vapor deposition (CVD) technique, an oxidation technique, another type of deposition technique. In some implementations, a planarization tool may be used to planarize the dielectric layer 234 after the dielectric layer 234 is deposited.

As shown in FIG. 6C, a first portion of an interconnect layer 214 of the circuitry die 206 is formed above the device layer 212. To form the first portion of the interconnect layer 214, a deposition tool may be used to deposit a dielectric layer 238 (which may include one or more ILD layers, one or more IMD layers, one or more ESLs, and/or one or more of another type of dielectric layer) using a PVD technique, an ALD technique, a CVD technique, an oxidation technique, another deposition technique. In some implementations, a planarization tool may be used to planarize the dielectric layer 238 after the dielectric layer 238 is deposited.

A deposition tool, an exposure tool, a developer tool, an etch tool, a planarization tool, a plating tool, and/or another semiconductor processing tool may be used to perform various operations to form interconnect structures 242 in the first portion of the interconnect layer 214. A deposition tool and/or a plating tool may be used to deposit the interconnect structures 242 using a PVD technique, an ALD technique, a CVD technique, an electroplating technique, and/or another deposition technique. In some implementations, a planarization tool may be used to planarize the interconnect structures 242 after the interconnect structures 242 are deposited.

In some implementations, first portion of the interconnect layer 214 is built up in the z-direction in a plurality of via layers (V-layers) and metallization layers (M-layers). For example, a first portion of the dielectric layer 238 may be formed, recesses may be formed in the first portion of the dielectric layer 238, and first interconnect structures 242 (e.g., a V0 via layer, an M0 metallization layer) may be formed in the recesses. A second portion of the dielectric layer 238 may be formed, recesses may be formed in the second portion of the dielectric layer 238, and second interconnect structures 242 (e.g., a V1 via layer, an M1 metallization layer) may be formed in the recesses. The remaining via layers and/or metallization layers of the first portion of the interconnect layer 214 may be formed in a similar manner.

As shown in FIGS. 6D and 6E, a second portion of the interconnect layer 214 may be formed, and the second portion of the interconnect layer 214 may include a bonding layer 240 and bonding structures 244. As shown in FIG. 6D, the bonding layer 240 may be formed over and/or on the dielectric layer 238, and over and/or on the top-most interconnect structures 242. A deposition tool may be used to deposit the bonding layer 240 using a PVD technique, an ALD technique, a CVD technique, an oxidation technique, another deposition technique. In some implementations, a planarization tool may be used to planarize the bonding layer 240 after the bonding layer 240 is deposited.

As shown in FIG. 6E, the bonding structures 244 may be formed in the bonding layer 240. For example, a deposition tool, an exposure tool, and a developer tool may be used to form a patterned masking layer on the bonding layer 240. An etch tool may be used to etch the bonding layer 240 (e.g., using a wet etch technique, a dry etch technique) to form recesses in the bonding layer 240. A deposition tool and/or a plating tool may be used to deposit the bonding structures 244 in the recess using a CVD technique, a PVD technique, an ALD technique, an electroplating technique, and/or another deposition technique. In some implementations, a planarization tool may perform a planarization operation to planarize the bonding structures 244 after the bonding structures 244 are deposited.

As indicated above, FIGS. 6A-6E are provided as an example. Other examples may differ from what is described with regard to FIGS. 6A-6E.

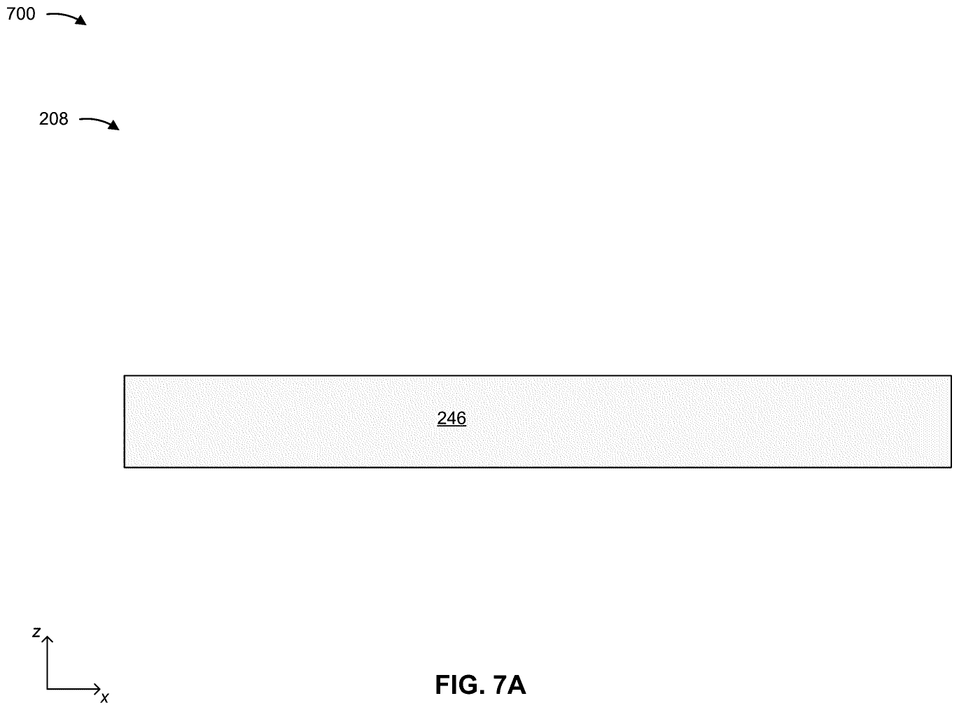

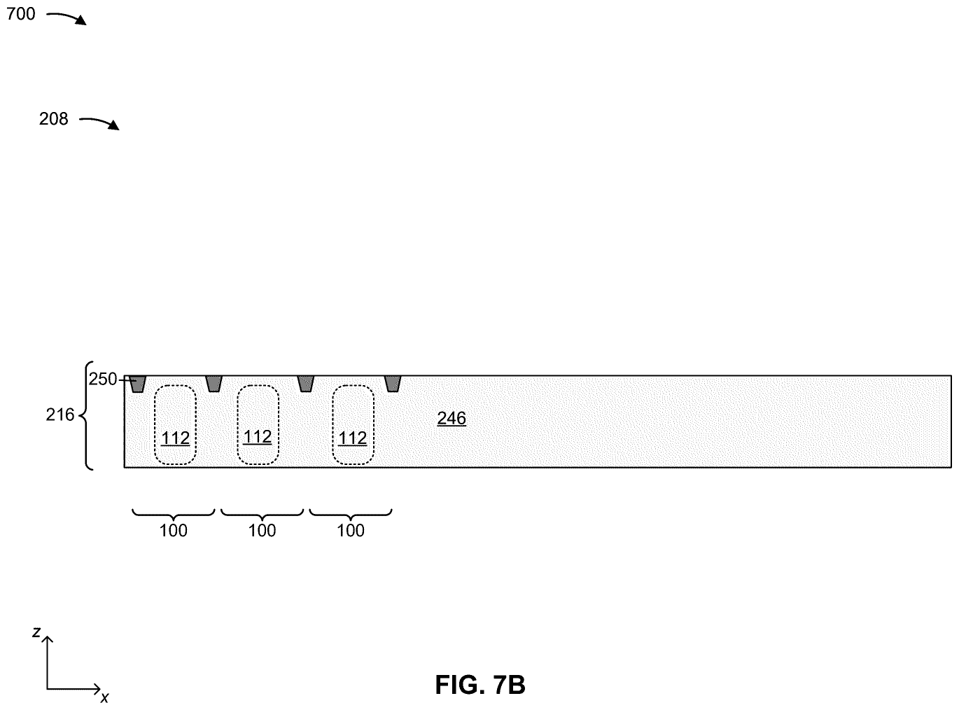

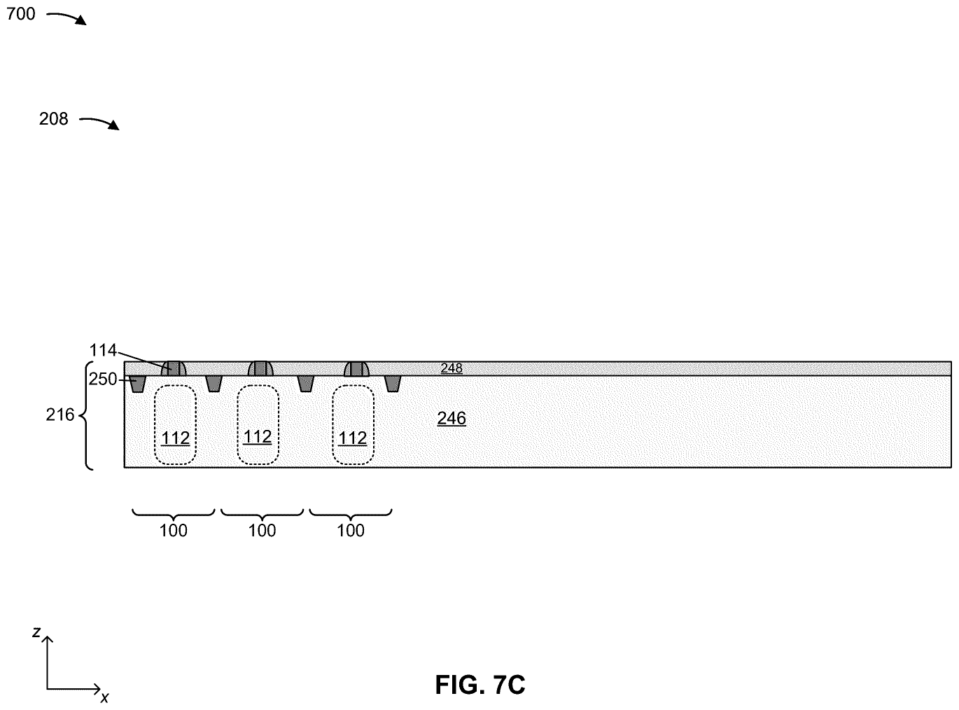

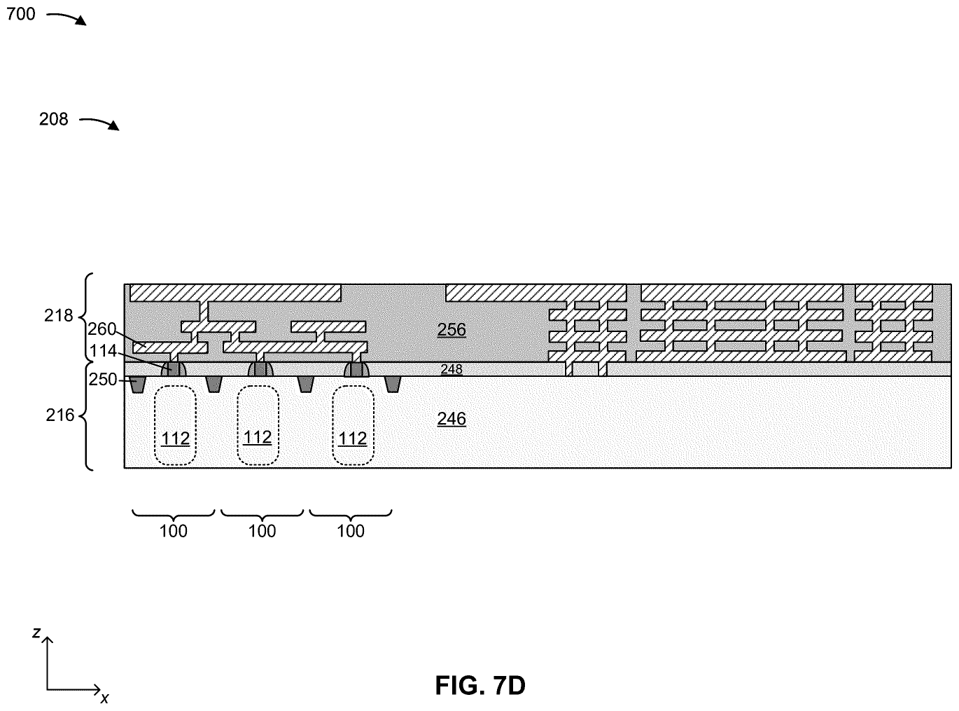

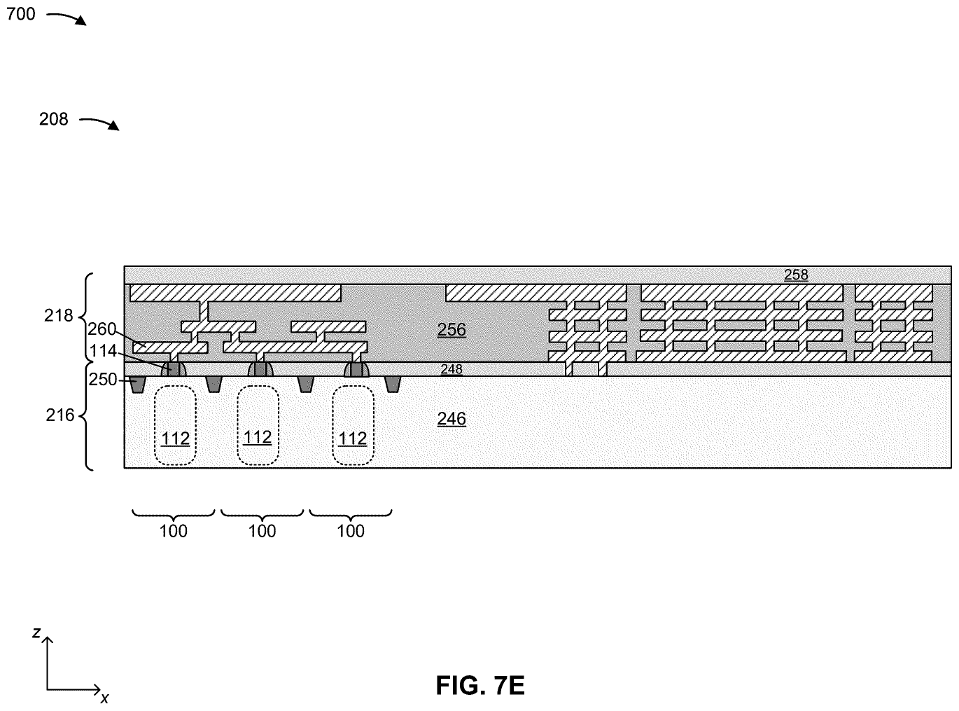

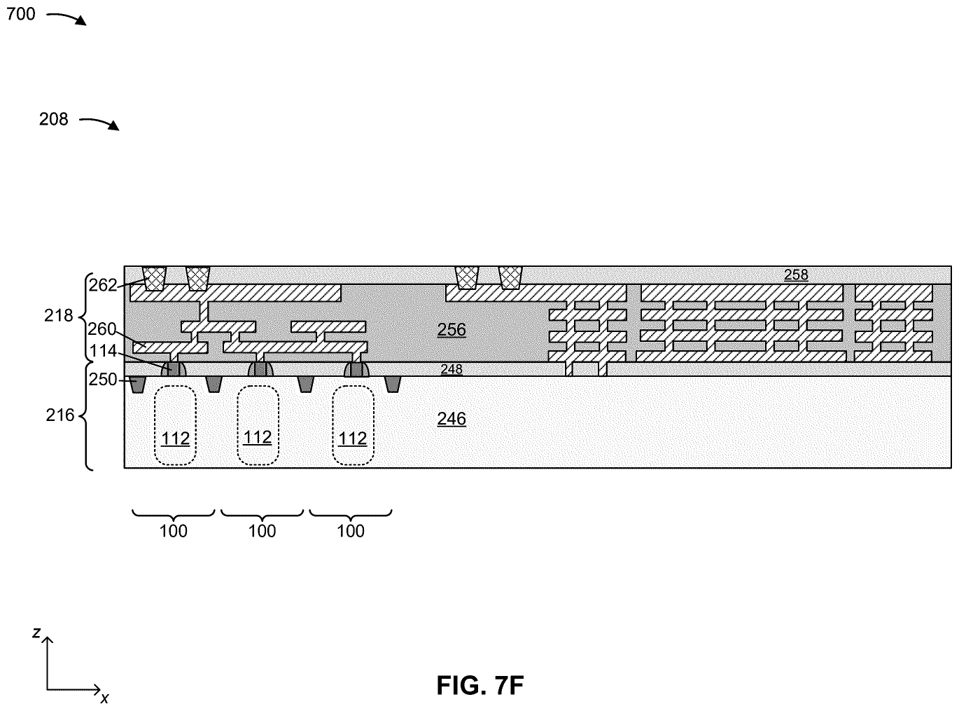

FIGS. 7A-7F are diagrams of an example implementation 700 of forming a sensor die 208 (or a portion thereof) described herein. In some implementations, one or more of the semiconductor processing operations described in connection with FIGS. 7A-7F may be performed using one or more semiconductor processing tools, such as a deposition tool, an exposure tool, a developer tool, an etch tool, a planarization tool, a plating tool, an ion implantation tool, and/or a wafer/die transport tool, among other examples.

Turning to FIG. 7A, the substrate 246 of the device layer 216 of the sensor die 208 is provided. The substrate 246 may be provided in the form of a semiconductor wafer such as a silicon (Si) wafer may be provided as an SOI wafer, and/or another type of semiconductor work piece.

As shown in FIG. 7B, photodiodes 112 of pixel sensors 100 of a pixel sensor array 222 of the sensor die 208 may be formed in the substrate 246 from the front side of the substrate 246. In some implementations, an ion implantation tool may be used to implant ions into the substrate 246 to form a P-N junction between a p-doped region of the substrate 246 and an n-doped region of the substrate 246, or to form a P-I-N junction between p-doped region of the substrate 246, an n-doped region of the substrate 246, and an intrinsic (e.g., undoped) semiconductor region for a photodiode 112.

As further shown in FIG. 7B, STI structures 250 may be formed in the substrate 246 (e.g., from the front side of the substrate 246) such that the STI structures 250 are located between the photodiodes 112. In some implementations, the STI structures 250 are formed after the photodiodes 112 are formed. In some implementations, the STI structures 250 are formed prior to formation of the photodiodes 112. A deposition tool, an exposure tool, and a developer tool may be used to form a patterned masking layer on the substrate 246. An etch tool may be used to etch into the substrate 246 from the front side of the substrate 246 (e.g., using a wet etch technique, a dry etch technique) to form the recesses in the front side of the substrate 246. A deposition tool may be used to deposit the STI structures 250 in the recesses using a CVD technique, a PVD technique, an ALD technique, an oxidation technique, and/or another deposition technique. In some implementations, a planarization tool may perform a planarization operation to planarize the STI structures 250 after the STI structures 250 are deposited.

As shown in FIG. 7C, transfer gates 114 of the pixel sensors 100 may be formed over and/or on the front side surface of the substrate 246. Forming a transfer gate 114 may include deposing a gate dielectric on the front side surface of the substrate 246, depositing a gate electrode on the gate dielectric layer, and/or forming sidewall spacers on sidewalls of the gate electrode, among other examples.

As further shown in FIG. 7C, a dielectric layer 248 may be formed over and/or on the front side of the substrate 246, and over and/or on the transfer gates 114. A deposition tool may be used to deposit the dielectric layer 248 using a CVD technique, a PVD technique, an ALD technique, an electroplating technique, and/or another deposition technique. In some implementations, a planarization tool may perform a planarization operation to planarize the dielectric layer 248 after the dielectric layer 248 is deposited.

As shown in FIG. 7D, a first portion of an interconnect layer 218 of the sensor die 208 is formed above the device layer 216. To form the first portion of the interconnect layer 218, a deposition tool may be used to deposit a dielectric layer 256 (which may include one or more ILD layers, one or more IMD layers, one or more ESLs, and/or one or more of another type of dielectric layer) using a PVD technique, an ALD technique, a CVD technique, an oxidation technique, another deposition technique. In some implementations, a planarization tool may be used to planarize the dielectric layer 256 after the dielectric layer 256 is deposited.

A deposition tool, an exposure tool, a developer tool, an etch tool, a planarization tool, a plating tool, and/or another semiconductor processing tool may be used to perform various operations to form interconnect structures 260 in the first portion of the interconnect layer 218. A deposition tool and/or a plating tool may be used to deposit the interconnect structures 260 using a PVD technique, an ALD technique, a CVD technique, an electroplating technique, and/or another deposition technique. In some implementations, a planarization tool may be used to planarize the interconnect structures 260 after the interconnect structures 260 are deposited.

In some implementations, first portion of the interconnect layer 218 is built up in the z-direction in a plurality of via layers (V-layers) and metallization layers (M-layers). For example, a first portion of the dielectric layer 256 may be formed, recesses may be formed in the first portion of the dielectric layer 256, and first interconnect structures 260 (e.g., a V0 via layer, an M0 metallization layer) may be formed in the recesses. A second portion of the dielectric layer 256 may be formed, recesses may be formed in the second portion of the dielectric layer 256, and second interconnect structures 260 (e.g., a V1 via layer, an M1 metallization layer) may be formed in the recesses. The remaining via layers and/or metallization layers of the first portion of the interconnect layer 218 may be formed in a similar manner.

As shown in FIGS. 7E and 7F, a second portion of the interconnect layer 218 may be formed, and the second portion of the interconnect layer 218 may include a bonding layer 258 and bonding structures 262. As shown in FIG. 7E, the bonding layer 258 may be formed over and/or on the dielectric layer 256, and over and/or on the top-most interconnect structures 260. A deposition tool may be used to deposit the bonding layer 258 using a PVD technique, an ALD technique, a CVD technique, an oxidation technique, another deposition technique. In some implementations, a planarization tool may be used to planarize the bonding layer 258 after the bonding layer 258 is deposited.

As shown in FIG. 7F, the bonding structures 262 may be formed in the bonding layer 258. For example, a deposition tool, an exposure tool, and a developer tool may be used to form a patterned masking layer on the bonding layer 258. An etch tool may be used to etch the bonding layer 258 (e.g., using a wet etch technique, a dry etch technique) to form recesses in the bonding layer 258. A deposition tool and/or a plating tool may be used to deposit the bonding structures 262 in the recess using a CVD technique, a PVD technique, an ALD technique, an electroplating technique, and/or another deposition technique. In some implementations, a planarization tool may perform a planarization operation to planarize the bonding structures 262 after the bonding structures 262 are deposited.

As indicated above, FIGS. 7A-7F are provided as an example. Other examples may differ from what is described with regard to FIGS. 7A-7F.

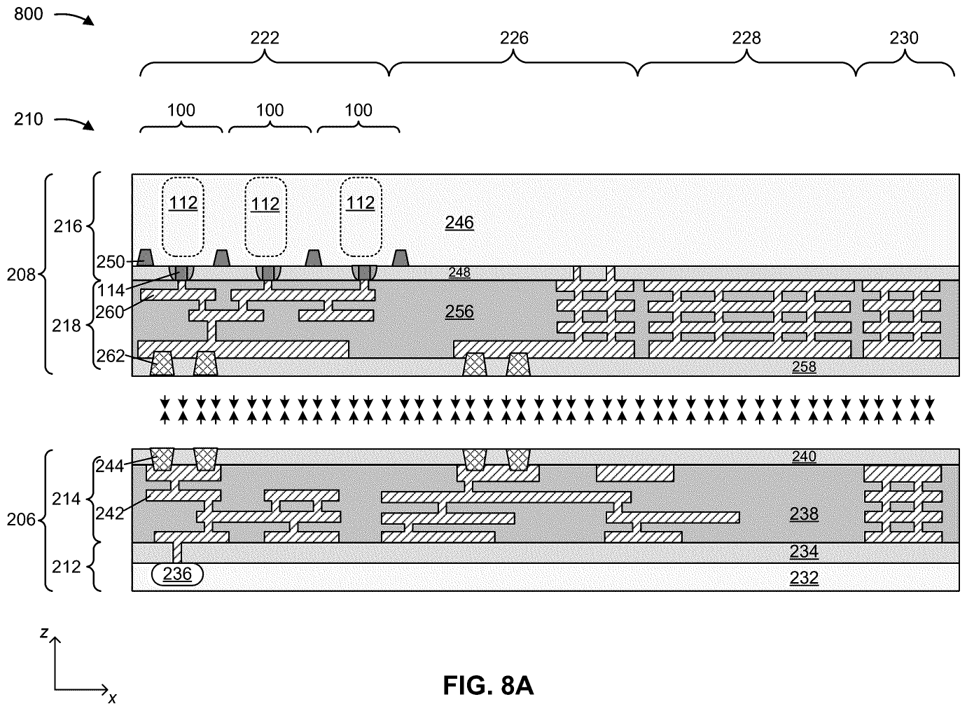

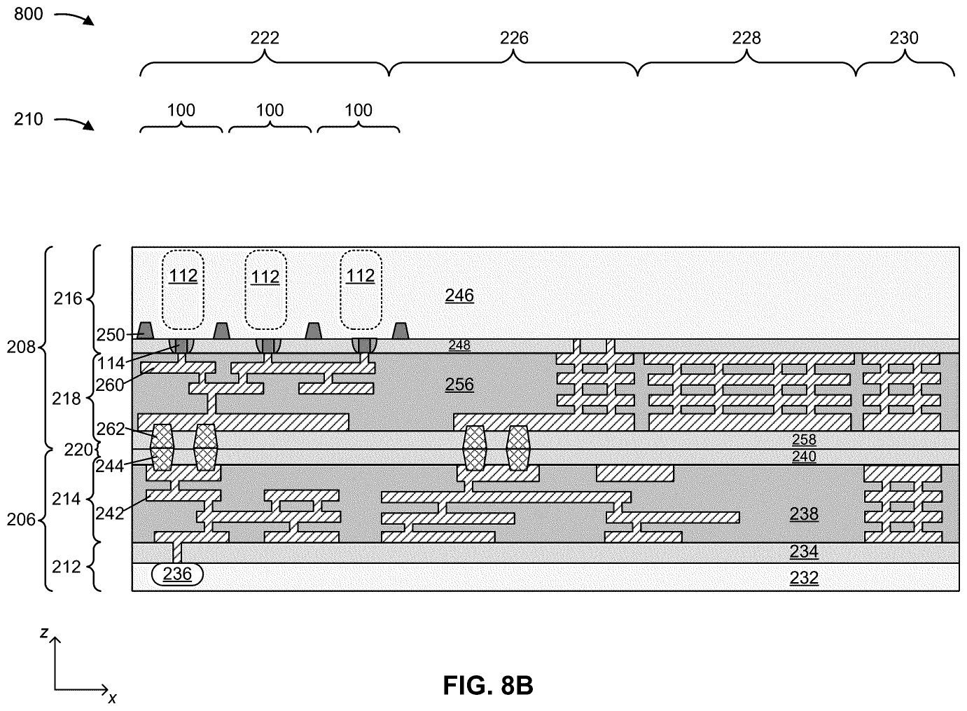

FIGS. 8A and 8B are diagrams of an example implementation 800 of forming an image sensor device 210 (or a portion thereof) described herein. In some implementations, one or more of the semiconductor processing operations described in connection with FIGS. 8A and 8B may be performed using one or more semiconductor processing tools, such as a deposition tool, an exposure tool, a developer tool, an etch tool, a planarization tool, a plating tool, an ion implantation tool, and/or a wafer/die transport tool, among other examples.

As shown in FIGS. 8A and 8B, a bonding operation is performed to bond a circuitry die 206 and a sensor die 208 to form the image sensor device 210. The circuitry die 206 and the sensor die 208 may be bonded at a bonding interface 220, which may include the bonding layers 240 and 258 (respectively of the circuitry die 206 and the sensor die 208), and the bonding structures 244 and 262 (respectively of the circuitry die 206 and the sensor die 208). A bonding tool may be used to form a dielectric-to-dielectric bond between the bonding layers 240 and 258 at the bonding interface 220, and to form a metal-to-metal bond between the bonding structures 244 and 262 at the bonding interface 220.

As shown in FIG. 8B, after bonding, the circuitry die 206 and the sensor die 208 are stacked or vertically arranged in the z-direction in the image sensor device 210. The interconnect layer 214 of the circuitry die 206 and the interconnect layer 218 of the sensor die 208 are facing toward each other in the image sensor device 210, and the device layer 212 of the circuitry die 206 and the device layer 216 of the sensor die 208 are facing away from each other.

As indicated above, FIGS. 8A and 8B are provided as an example. Other examples may differ from what is described with regard to FIGS. 8A and 8B.

FIGS. 9A-9I are diagrams of an example implementation 900 of forming a pixel sensor array 222 of a sensor die 208 (or a portion thereof) described herein. In particular, the example implementation 900 may include an example of forming a pixel sensor 100, of the pixel sensor array 222, to include a plurality of layers of diffusion structures, including the diffusion structures 266 and the diffusion structures 272. In some implementations, one or more of the semiconductor processing operations described in connection with FIGS. 9A-9I may be performed using one or more semiconductor processing tools, such as a deposition tool, an exposure tool, a developer tool, an etch tool, a planarization tool, a plating tool, an ion implantation tool, and/or a wafer/die transport tool, among other examples.

As shown in FIG. 9A, the operations described in connection with FIGS. 9A-9I may be performed as part of back side processing of the sensor die 208, after operations described in FIGS. 7C-7F, 8A, and/or 8B are performed. As shown in FIG. 9B, the recesses 302 for the diffusion structures 266 of the pixel sensor 100 may be formed in the back side of the substrate 246. The recesses 302 may extend into the back side of the substrate 246 above the photodiode 112.

In some implementations, a pattern in a photoresist layer is used to etch the substrate 246 to form the recesses 302. In these implementations, a deposition tool may be used to form the photoresist layer on the substrate 246. An exposure tool may be used to expose the photoresist layer to a radiation source to pattern the photoresist layer. A developer tool may be used to develop and remove portions of the photoresist layer to expose the pattern. An etch tool may be used to etch into the substrate 246 based on the pattern to form the recesses 302. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the substrate 246 based on a pattern.

As shown in FIG. 9C, recesses 902 for the DTI structure 224 may be formed around the photodiode 112 in the substrate 246. In some implementations, the recesses 902 are formed after the recesses 302 are formed. In some implementations, the recesses 902 are formed prior to formation of the recesses 302.

In some implementations, a pattern in a photoresist layer is used to etch the substrate 246 to form the recesses 902. In these implementations, a deposition tool may be used to form the photoresist layer on the back side of the substrate 246. An exposure tool may be used to expose the photoresist layer to a radiation source to pattern the photoresist layer. A developer tool may be used to develop and remove portions of the photoresist layer to expose the pattern. An etch tool may be used to etch into the substrate 246 based on the pattern to form the recesses 902. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the substrate 246 based on a pattern.

As shown in FIG. 9D, the dielectric liner 254 of the DTI structure 224 is conformally deposited on the sidewalls and bottom surface of the recesses 902. A deposition tool may be used to deposit the dielectric liner 254 using a conformal deposition technique such as ALD. Additionally and/or alternatively, another deposition technique such as CVD may be used. The dielectric liner 254 may continuously extend over the back side of the substrate 246 such that the dielectric liner 254 is deposited in the recesses 302.

As shown in FIG. 9E, dielectric material is deposited in the recesses 302 and in the recesses 902 to form the diffusion structures 266 in the recesses 302, to form the dielectric layer 252 of the DTI structure 224 in the recesses 902, and to form the buffer layer 264 above the DTI structure 224 and above the diffusion structures 266. The dielectric material may be deposited on the dielectric liner 254. A deposition tool may be used to deposit the dielectric layer 252 using a PVD technique, an ALD technique, a CVD technique, an oxidation technique, another deposition technique. In some implementations, a planarization operation, such as a chemical mechanical planarization (CMP) operation, is performed using a planarization tool to planarize the buffer layer 264.

As shown in FIG. 9F, the metal grid structure 270 may be formed over and/or on the buffer layer 264. A deposition tool may be used to deposit a metal layer on the buffer layer 264 using a CVD technique, a PVD technique, an ALD technique, an electroplating technique, and/or another suitable deposition technique. The metal layer may be patterned using lithography techniques and etched to form the metal grid structure 270.

As shown in FIG. 9G, the recesses 306 for the diffusion structures 272 of the pixel sensor 100 may be formed in the buffer layer 264. In some implementations, a pattern in a photoresist layer is used to etch the buffer layer 264 to form the recesses 306. In some implementations, the buffer layer 264 to form the recesses 306 using the metal grid structure 270 as a self-aligned pattern.

As shown in FIG. 9G, a combination of sputter etching and chemical etching may be used to form the recesses 306 such that the recesses 306 having an approximate V-shaped cross-sectional profile and an approximate conical three-dimensional shape. Neutral radicals 904 may be used to chemically etch the buffer layer 264, and ions 906 may be used to bombard the buffer layer 264 to sputter etch the buffer layer 264, resulting in removal of material 908 from the buffer layer 264. In some implementations, a low bias power for the ions 906 may be used to achieve a particular directionality for the sputter etch to achieve the approximate V-shaped cross-sectional profile and an approximate conical three-dimensional shape for the recesses 306.

As shown in FIG. 9H, dielectric material is deposited over and/or on the buffer layer 264 and in the recesses 306 to form the passivation layer 268 on the buffer layer 264 and to form the diffusion structures 272 in the recesses 306. A deposition tool may be used to deposit the dielectric material using a PVD technique, an ALD technique, a CVD technique, an oxidation technique, another deposition technique. In some implementations, a planarization tool is used to planarize the passivation layer 268 after the passivation layer 268 is deposited.

As further shown in FIG. 9I, the metal grid structure 274 may be formed over and/or on the passivation layer 268. A deposition tool may be used to deposit a metal layer on the passivation layer 268 using a CVD technique, a PVD technique, an ALD technique, an electroplating technique, and/or another suitable deposition technique. The metal layer may be patterned using lithography techniques and etched to form the metal grid structure 274. The color filter region 276 may be formed in the metal grid structure 274, and the micro-lens 280) may be formed on the color filter region 276.

As indicated above, FIGS. 9A-9I are provided as an example. Other examples may differ from what is described with regard to FIGS. 9A-9I.

FIGS. 10A-10E are diagrams of an example implementation 1000 of forming a pixel sensor array 222 of a sensor die 208 (or a portion thereof) described herein. In particular, the example implementation 1000 may include an example of forming a pixel sensor 100, of the pixel sensor array 222, to include a plurality of layers of diffusion structures, including the diffusion structures 266 and the diffusion structures 272. In some implementations, one or more of the semiconductor processing operations described in connection with FIGS. 10A-10E may be performed using one or more semiconductor processing tools, such as a deposition tool, an exposure tool, a developer tool, an etch tool, a planarization tool, a plating tool, an ion implantation tool, and/or a wafer/die transport tool, among other examples.

As shown in FIG. 10A, similar processing operations as illustrated and described in connection with FIGS. 9A-9F may be performed to form the DTI structure 224, the buffer layer 264, the diffusion structures 266, and the metal grid structure 270.

As shown in FIG. 10B, the recesses 306 for the diffusion structures 272 of the pixel sensor 100 may be formed in the buffer layer 264. In some implementations, a pattern in a photoresist layer is used to etch the buffer layer 264 to form the recesses 306. In some implementations, the buffer layer 264 is etched to form the recesses 306 using the metal grid structure 270 as a self-aligned pattern.

As shown in FIG. 10B, a different etch technique that the technique described in connection with FIG. 9G may be used to form the recesses 306 such that the recesses have an approximate U-shaped cross-sectional profile and an approximate semi-circular three-dimensional shape. In particular, a cyclic reactive ion etch technique (sometimes referred to as a BOSCH etch technique) may be used to achieve the approximate U-shaped cross-sectional profile and an approximate semi-circular three-dimensional shape for the recesses 306.

FIG. 10C illustrates an example process sequence for etching the buffer layer 264 to form the recesses 306 to have an approximate U-shaped cross-sectional profile and an approximate semi-circular three-dimensional shape. As shown in FIG. 10C, a cycle of a cyclic reactive ion etching process may include etching a recess 306 to a first depth in the buffer layer 264. A protective liner 1002 may be formed on the sidewalls and bottom surface of the recess 306. The portion of the protective liner 1002 on the bottom surface of the recess 306 may be removed by etching such that the protective liner 1002 remains on the sidewalls of the recess 306. The depth of the recess 306 may be subsequently increased from the first depth to a second depth by etching further into the buffer layer 264 while the protective liner 1002 protects the sidewalls of the recess 306 from lateral etching. Additional cycles may be performed to achieve a particular depth for the recesses 306. In some implementations, a similar technique may be used to etch the substrate 246 to form the recesses 302 such that the diffusion structures 266 have an approximate U-shaped cross-sectional profile and an approximate semi-circular three-dimensional shape.

As shown in FIG. 10D, dielectric material is deposited over and/or on the buffer layer 264 and in the recesses 306 to form the passivation layer 268 on the buffer layer 264 and to form the diffusion structures 272 in the recesses 306. A deposition tool may be used to deposit the dielectric material using a PVD technique, an ALD technique, a CVD technique, an oxidation technique, another deposition technique. In some implementations, a planarization tool is used to planarize the passivation layer 268 after the passivation layer 268 is deposited.

As further shown in FIG. 10E, the metal grid structure 274 may be formed over and/or on the passivation layer 268. A deposition tool may be used to deposit a metal layer on the passivation layer 268 using a CVD technique, a PVD technique, an ALD technique, an electroplating technique, and/or another suitable deposition technique. The metal layer may be patterned using lithography techniques and etched to form the metal grid structure 274. The color filter region 276 may be formed in the metal grid structure 274, and the micro-lens 280 may be formed on the color filter region 276.

As indicated above. FIGS. 10A-10E are provided as an example. Other examples may differ from what is described with regard to FIGS. 10A-10E.

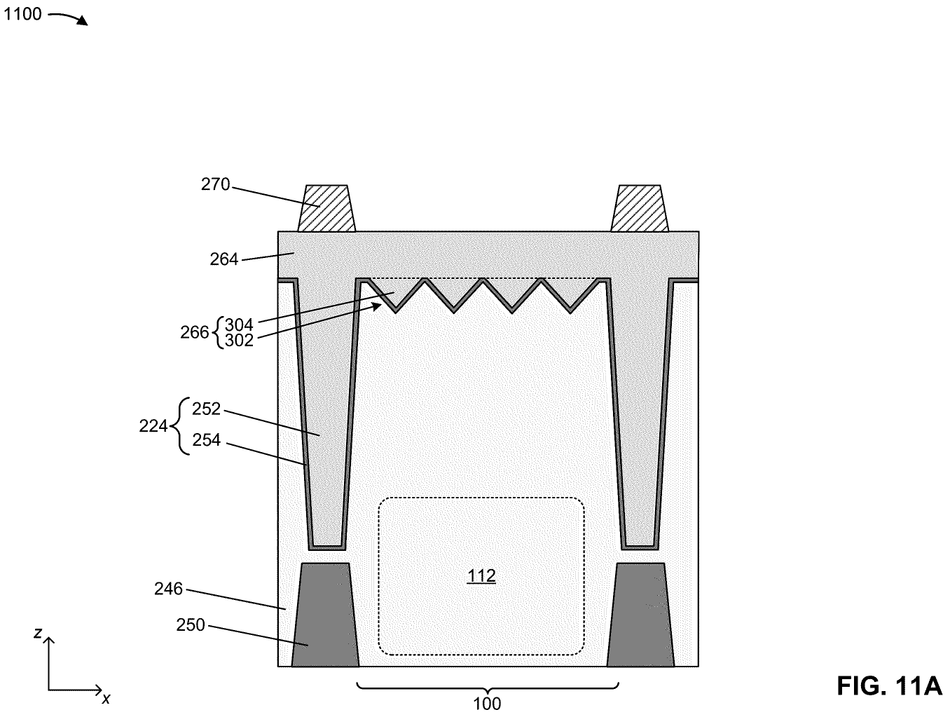

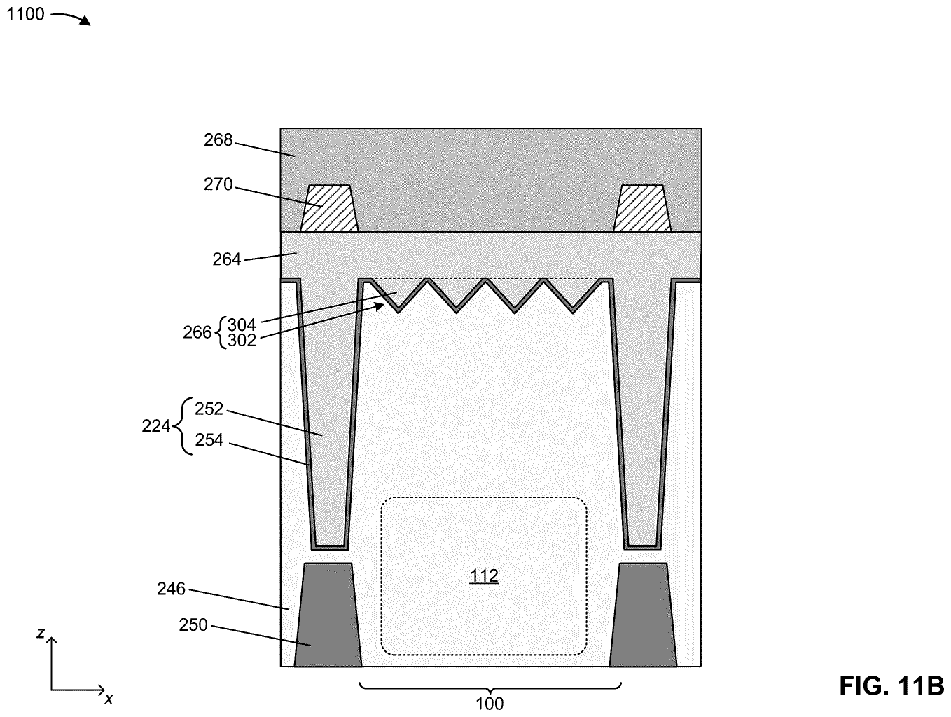

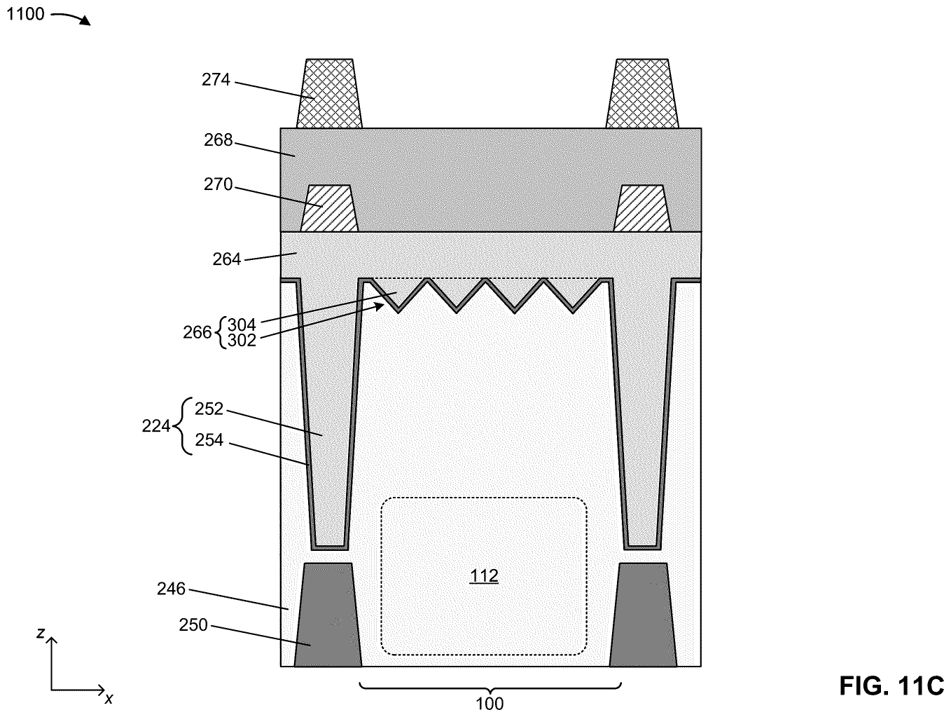

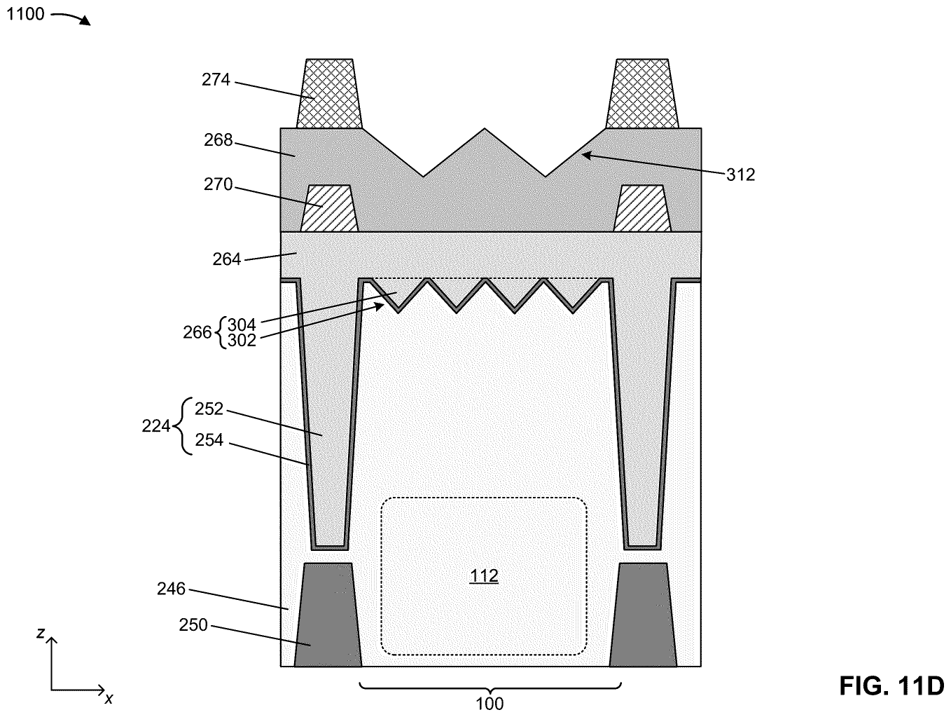

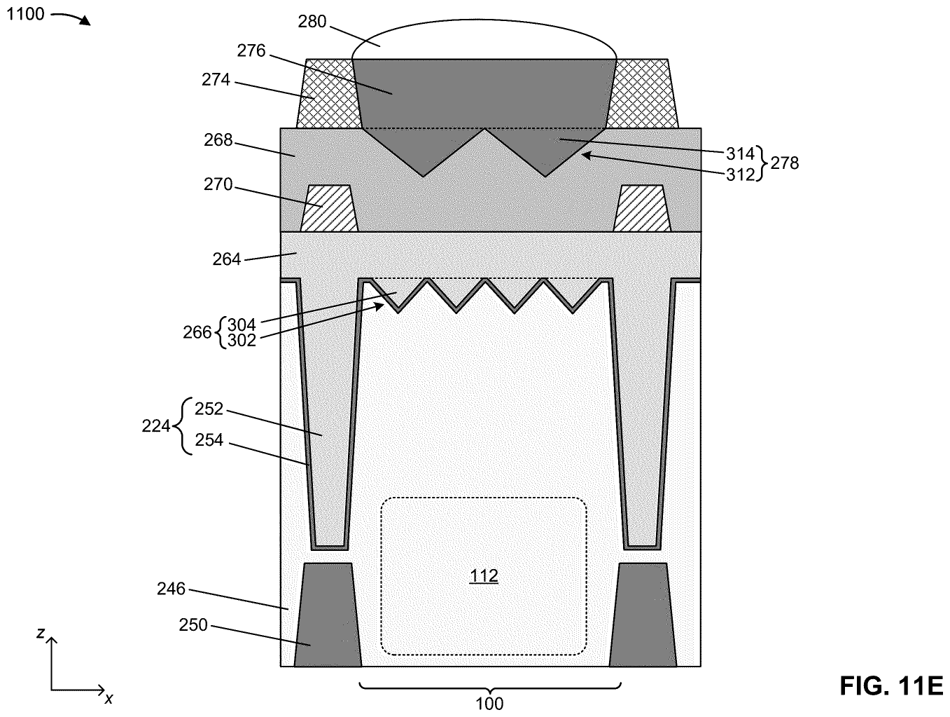

FIGS. 11A-11E are diagrams of an example implementation 1100 of forming a pixel sensor array 222 of a sensor die 208 (or a portion thereof) described herein. In particular, the example implementation 1100 may include an example of forming a pixel sensor 100, of the pixel sensor array 222, to include a plurality of layers of diffusion structures, including the diffusion structures 266 and the diffusion structures 278. In some implementations, one or more of the semiconductor processing operations described in connection with FIGS. 11A-11E may be performed using one or more semiconductor processing tools, such as a deposition tool, an exposure tool, a developer tool, an etch tool, a planarization tool, a plating tool, an ion implantation tool, and/or a wafer/die transport tool, among other examples.

As shown in FIG. 11A, similar processing operations as illustrated and described in connection with FIGS. 9A-9F may be performed to form the DTI structure 224, the buffer layer 264, the diffusion structures 266, and the metal grid structure 270.

As shown in FIG. 11B, the passivation layer 268 is formed over and/or on the buffer layer 264. A deposition tool may be used to deposit the passivation layer 268 using a PVD technique, an ALD technique, a CVD technique, an oxidation technique, another deposition technique. In some implementations, a planarization operation, such as a CMP operation, is performed using a planarization tool to planarize the passivation layer 268.

As shown in FIG. 11C, the metal grid structure 274 may be formed over and/or on the passivation layer 268. A deposition tool may be used to deposit a metal layer on the passivation layer 268 using a CVD technique, a PVD technique, an ALD technique, an electroplating technique, and/or another suitable deposition technique. The metal layer may be patterned using lithography techniques and etched to form the metal grid structure 274.

As shown in FIG. 11D, the recesses 312 for the diffusion structures 278 of the pixel sensor 100 may be formed in the passivation layer 268. In some implementations, a pattern in a photoresist layer is used to etch the passivation layer 268 to form the recesses 312. In some implementations, the passivation layer 268 is etched to form the recesses 312 using the metal grid structure 274 as a self-aligned pattern.

In some implementations, an etch technique, such as the combination of sputter etching and chemical etching described in connection with FIG. 9G, may be used to form the recesses 312 such that the recesses 312 have an approximate V-shaped cross-sectional profile and an approximate conical three-dimensional. In some implementations, an etch technique, such as the cyclic reactive ion technique described in connection with FIG. 10C, may be used to form the recesses 312 such that the recesses 312 have an approximate U-shaped cross-sectional profile and an approximate semi-circular three-dimensional shape.

As shown in FIG. 11E, the color filter region 276 may be formed in the metal grid structure 274 such that dielectric material of the color filter region 276 fills in the recesses 312 to form the diffusion structures 278. The micro-lens 280 may be formed on the color filter region 276.

As indicated above, FIGS. 11A-11E are provided as an example. Other examples may differ from what is described with regard to FIGS. 11A-11E.

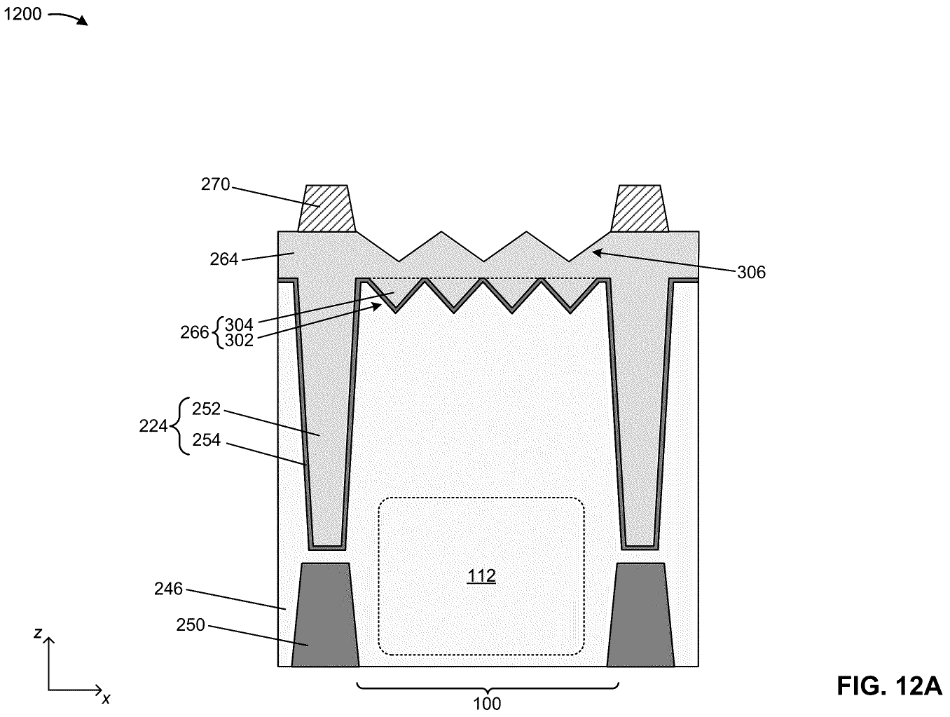

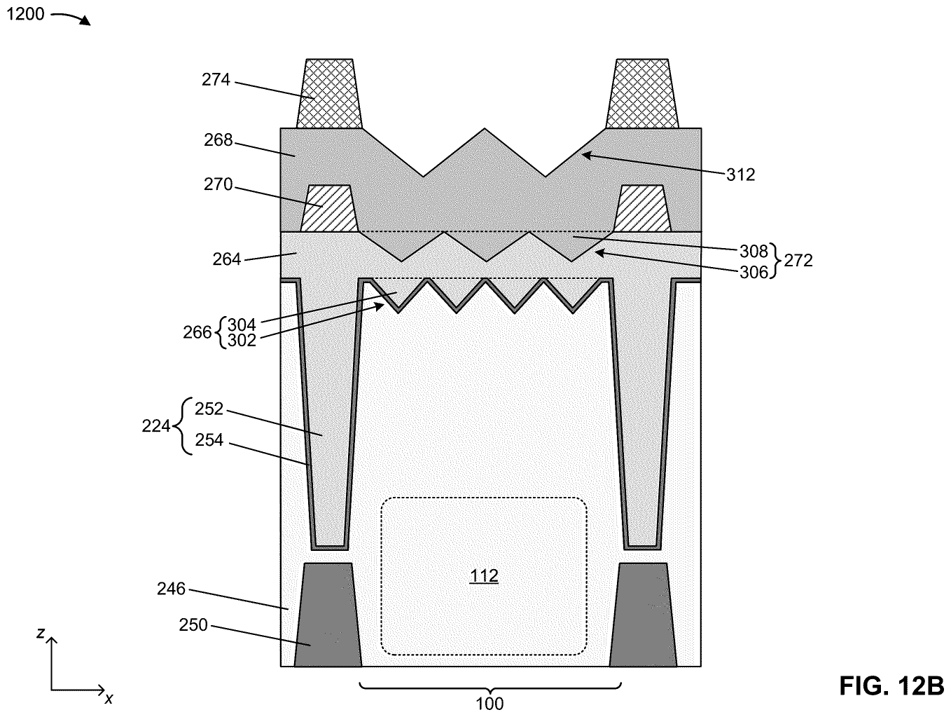

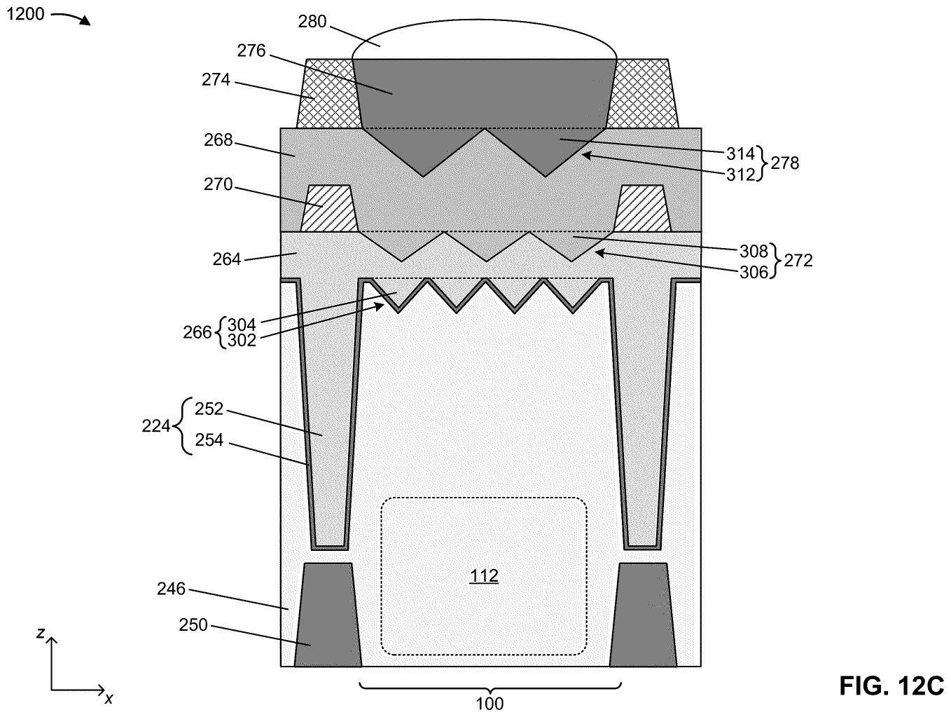

FIGS. 12A-12C are diagrams of an example implementation 1200 of forming a pixel sensor array 222 of a sensor die 208 (or a portion thereof) described herein. In particular, the example implementation 1200 may include an example of forming a pixel sensor 100, of the pixel sensor array 222, to include a plurality of layers of diffusion structures, including the diffusion structures 266, the diffusion structures 272, and the diffusion structures 278. In some implementations, one or more of the semiconductor processing operations described in connection with FIGS. 12A-12C may be performed using one or more semiconductor processing tools, such as a deposition tool, an exposure tool, a developer tool, an etch tool, a planarization tool, a plating tool, an ion implantation tool, and/or a wafer/die transport tool, among other examples.

As shown in FIG. 12A, similar processing operations as illustrated and described in connection with FIGS. 9A-9F may be performed to form the DTI structure 224, the buffer layer 264, the diffusion structures 266, and the metal grid structure 270. As further shown in FIG. 12A, the recesses 306 for the diffusion structures 272 may be formed in the buffer layer 264. In some implementations, an etch technique, such as the combination of sputter etching and chemical etching described in connection with FIG. 9G, may be used to form the recesses 306 such that the recesses 306 have an approximate V-shaped cross-sectional profile and an approximate conical three-dimensional. In some implementations, an etch technique, such as the cyclic reactive ion technique described in connection with FIG. 10C, may be used to form the recesses 306 such that the recesses 306 have an approximate U-shaped cross-sectional profile and an approximate semi-circular three-dimensional shape.

As shown in FIG. 12B, the passivation layer 268 is formed over and/or on the buffer layer 264 such that passivation layer 268 fills in the recesses 306 to form the diffusion structures 266. A deposition tool may be used to deposit the passivation layer 268 using a PVD technique, an ALD technique, a CVD technique, an oxidation technique, another deposition technique. In some implementations, a planarization operation, such as a CMP operation, is performed using a planarization tool to planarize the passivation layer 268.

As further shown in FIG. 12B, the metal grid structure 274 may be formed over and/or on the passivation layer 268. A deposition tool may be used to deposit a metal layer on the passivation layer 268 using a CVD technique, a PVD technique, an ALD technique, an electroplating technique, and/or another suitable deposition technique. The metal layer may be patterned using lithography techniques and etched to form the metal grid structure 274.

The recesses 312 for the diffusion structures 278 of the pixel sensor 100 may be formed in the passivation layer 268. In some implementations, a pattern in a photoresist layer is used to etch the passivation layer 268 to form the recesses 312. In some implementations, the passivation layer 268 is etched to form the recesses 312 using the metal grid structure 274 as a self-aligned pattern.

In some implementations, an etch technique, such as the combination of sputter etching and chemical etching described in connection with FIG. 9G, may be used to form the recesses 312 such that the recesses 312 have an approximate V-shaped cross-sectional profile and an approximate conical three-dimensional. In some implementations, an etch technique, such as the cyclic reactive ion technique described in connection with FIG. 10C, may be used to form the recesses 312 such that the recesses 312 have an approximate U-shaped cross-sectional profile and an approximate semi-circular three-dimensional shape.

As shown in FIG. 12C, the color filter region 276 may be formed in the metal grid structure 274 such that dielectric material of the color filter region 276 fills in the recesses 312 to form the diffusion structures 278. The micro-lens 280 may be formed on the color filter region 276.

As indicated above, FIGS. 12A-12C are provided as an example. Other examples may differ from what is described with regard to FIGS. 12A-12C.

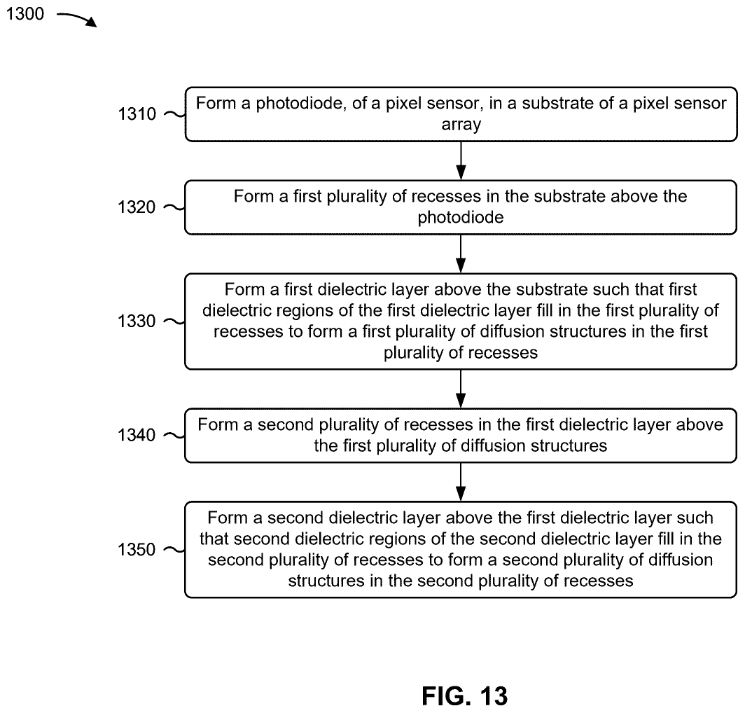

FIG. 13 is a flowchart of an example process 1300 associated with forming a pixel sensor array described herein. In some implementations, one or more process blocks of FIG. 13 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 13, process 1300 may include forming a photodiode, of a pixel sensor, in a substrate of a pixel sensor array (block 1310). For example, one or more semiconductor processing tools may be used to form a photodiode 112, of a pixel sensor 100, in a substrate 246 of a pixel sensor array 222, as described herein.

As further shown in FIG. 13, process 1300 may include forming a first plurality of recesses in the substrate above the photodiode (block 1320). For example, one or more semiconductor processing tools may be used to form a first plurality of recesses 302 in the substrate 246 above the photodiode 112, as described herein.

As further shown in FIG. 13, process 1300 may include forming a first dielectric layer above the substrate such that first dielectric regions of the first dielectric layer fill in the first plurality of recesses to form a first plurality of diffusion structures in the first plurality of recesses (block 1330). For example, one or more semiconductor processing tools may be used to form a first dielectric layer (e.g., the buffer layer 264) above the substrate 246 such that first dielectric regions (e.g., portions 304) of the first dielectric layer fill in the first plurality of recesses 302 to form a first plurality of diffusion structures 26) in the first plurality of recesses 302, as described herein.

As further shown in FIG. 13, process 1300 may include forming a second plurality of recesses in the first dielectric layer above the first plurality of diffusion structures (block 1340). For example, one or more semiconductor processing tools may be used to form a second plurality of recesses 306 in the first dielectric layer above the first plurality of diffusion structures 266, as described herein. Alternatively, the one or more semiconductor processing tools may be used to form a second plurality of recesses 312 in another dielectric layer above the first dielectric layer, as described herein.

As further shown in FIG. 13, process 1300 may include forming a second dielectric layer above the first dielectric layer such that second dielectric regions of the second dielectric layer fill in the second plurality of recesses to form a second plurality of diffusion structures in the second plurality of recesses (block 1350). For example, one or more semiconductor processing tools may be used to form a second dielectric layer (e.g., a passivation layer 268) above the first dielectric layer such that second dielectric regions (e.g., portions 308) of the second dielectric layer fill in the second plurality of recesses 306 to form a second plurality of diffusion structures 272 in the second plurality of recesses 306, as described herein.

Process 1300 may include additional implementations, such as any single implementation or any combination of implementations described below and/or in connection with one or more other processes described elsewhere herein. Alternatively, one or more semiconductor processing tools may be used to form a color filter region 276 above the second dielectric layer such that second dielectric regions (e.g., portions 314) of the color filter region 276 fill in the second plurality of recesses 312 to form a second plurality of diffusion structures 278 in the second plurality of recesses 312, as described herein.

Process 1300 may include additional implementations, such as any single implementation or any combination of implementations described below and/or in connection with one or more other processes described elsewhere herein.

In a first implementation, process 1300 includes forming a third plurality of recesses 312 in the second dielectric layer above the second plurality of diffusion structures 272, and forming a color filter region 276, of the pixel sensor 100, above the second dielectric layer such that third dielectric regions (e.g., portions 314) of the color filter region 276 fill in the third plurality of recesses 312 to form a third plurality of diffusion structures 278 in the third plurality of recesses 312.

In a second implementation, alone or in combination with the first implementation, the first plurality of recesses 302 each have an approximately pyramidal shape, and the second plurality of recesses 306 or 312 each have an approximately conical shape.

In a third implementation, alone or in combination with one or more of the first and second implementations, forming the second plurality of recesses 306 or 312 includes performing a combination of chemical etching and sputter etching to form the second plurality of recesses 306 or 312.

In a fourth implementation, alone or in combination with one or more of the first through third implementations, forming the second plurality of recesses 306 or 312 includes forming the second plurality of recesses 306 or 312 to a first depth in the first dielectric layer, forming a protective liner 1002 in the second plurality of recesses 306 or 312, and etching through a bottom portion of the protective liner 1002 and into the first dielectric layer to increase the second plurality of recesses 306 or 312 from the first depth to a second depth in the first dielectric layer, where the protective liner 1002 protects sidewalls of the second plurality of recesses 306 or 312 from being etched.

Although FIG. 13 shows example blocks of process 1300, in some implementations, process 1300 includes additional blocks, fewer blocks, different blocks, or differently arranged blocks than those depicted in FIG. 13. Additionally, or alternatively, two or more of the blocks of process 1300 may be performed in parallel.

In this way, a plurality of vertically arranged layers of diffusion structures are included above a photodiode of a pixel sensor. Each layer of diffusion structures distributes incident light by refraction to provide a greater amount of distribution of the incident light than a single layer of diffusion structures. For example, a top layer of diffusion structures may distribute incident light by refraction, and a bottom layer of diffusion structures may further distribute the distributed incident light from the top layer of diffusion structures before the incident light enters the photodiode of the pixel sensor. This ensures that the incident light is spread out across the photodiode and increases the length of the path of travel of photons of the incident light, thereby increasing the likelihood that the photons will be absorbed in the photodiode. Thus, the plurality of vertically arranged layers of diffusion structures may further increase the QE of the pixel sensor. Moreover, each layer of diffusion structures may be sized and/or shaped to distribute particular wavelengths of the incident light, thereby enabling a broader range of wavelengths of the incident light to be distributed for further QE enhancement.

As described in greater detail above, some implementations described herein provide a pixel sensor. The pixel sensor includes a photodiode in a substrate. The pixel sensor includes a first plurality of diffusion structures extending into a portion of the substrate above the photodiode. The pixel sensor includes a second plurality of diffusion structures above the first plurality of diffusion structures, where the second plurality of diffusion structures extend into a dielectric layer above the substrate.

As described in greater detail above, some implementations described herein provide a pixel sensor array. The pixel sensor array includes a pixel sensor that includes a photodiode in a substrate. The pixel sensor array includes a first plurality of diffusion structures extending into a portion of the substrate above the photodiode. The pixel sensor array includes a DTI structure extending into the substrate and laterally surrounding the first plurality of diffusion structures and at least a portion of the photodiode. The pixel sensor array includes a second plurality of diffusion structures above the first plurality of diffusion structures, where the second plurality of diffusion structures extend into a dielectric layer above the substrate. The pixel sensor array includes a grid structure above the DTI structure and laterally surrounding the second plurality of diffusion structures.

As described in greater detail above, some implementations described herein provide a method. The method includes forming a photodiode, of a pixel sensor, in a substrate of a pixel sensor array. The method includes forming a first plurality of recesses in the substrate above the photodiode. The method includes forming a first dielectric layer above the substrate such that first dielectric regions of the first dielectric layer fill in the first plurality of recesses to form a first plurality of diffusion structures in the first plurality of recesses. The method includes forming a second plurality of recesses in the first dielectric layer above the first plurality of diffusion structures. The method includes forming a second dielectric layer above the first dielectric layer such that second dielectric regions of the second dielectric layer fill in the second plurality of recesses to form a second plurality of diffusion structures in the second plurality of recesses.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A pixel sensor, comprising:
a photodiode in a substrate;
a first plurality of diffusion structures extending into a portion of the substrate above the photodiode; and
a second plurality of diffusion structures above the first plurality of diffusion structures,
wherein the second plurality of diffusion structures extend into a dielectric layer above the substrate.

2. The pixel sensor of claim 1, wherein a first quantity of diffusion structures in the first plurality of diffusion structures and a second quantity of diffusion structures in the second plurality of diffusion structures are different quantities of diffusion structures.

3. The pixel sensor of claim 1, wherein a first material composition of the first plurality of diffusion structures and a second material composition of the second plurality of diffusion structures are different material compositions.

4. The pixel sensor of claim 1, wherein a first refractive index of a material composition of the first plurality of diffusion structures and a second refractive index of a material composition of the second plurality of diffusion structures are different refractive indexes.

5. The pixel sensor of claim 1, wherein a first vertical thickness of a diffusion structure of the first plurality of diffusion structures and a second vertical thickness of a diffusion structure of the second plurality of diffusion structures, are different vertical thicknesses.

6. The pixel sensor of claim 1, wherein a first lateral width of a diffusion structure of the first plurality of diffusion structures, and a second lateral width of a diffusion structure of the second plurality of diffusion structures, are different lateral widths.

7. The pixel sensor of claim 1, further comprising:
a third plurality of diffusion structures above the second plurality of diffusion structures,
wherein the third plurality of diffusion structures extend into another dielectric layer above the dielectric layer.

8. A pixel sensor array, comprising:
a pixel sensor comprising a photodiode in a substrate;
a first plurality of diffusion structures extending into a portion of the substrate above the photodiode,
a deep trench isolation (DTI) structure extending into the substrate and laterally surrounding the first plurality of diffusion structures and at least a portion of the photodiode;
a second plurality of diffusion structures above the first plurality of diffusion structures,
wherein the second plurality of diffusion structures extend into a dielectric layer above the substrate; and
a grid structure above the DTI structure and laterally surrounding the second plurality of diffusion structures.

9. The pixel sensor array of claim 8, wherein the first plurality of diffusion structures have an approximately V-shaped cross-sectional profile; and
wherein the second plurality of diffusion structures have an approximately U-shaped cross-sectional profile.

10. The pixel sensor array of claim 8, wherein a refractive index of the dielectric layer is different at a bottom of the dielectric layer than at a top of the dielectric layer.

11. The pixel sensor array of claim 10, further comprising another dielectric layer above the dielectric layer,
wherein the refractive index of the dielectric layer is greater than a refractive index of the other dielectric layer.

12. The pixel sensor array of claim 11, wherein the refractive index of the other dielectric layer is greater at a bottom of the other dielectric layer than at a top of the other dielectric layer.

13. The pixel sensor array of claim 8, further comprising:
a third plurality of diffusion structures above the second plurality of diffusion structures,
wherein the third plurality of diffusion structures extend into another dielectric layer above the dielectric layer.

14. The pixel sensor array of claim 13, wherein a first quantity of diffusion structures in the second plurality of diffusion structures is greater than a second quantity of diffusion structures in the third plurality of diffusion structures.

15. The pixel sensor array of claim 14, wherein a third quantity of diffusion structures in the first plurality of diffusion structures is greater than the first quantity of diffusion structures in the second plurality of diffusion structures.

16. A method, comprising:
forming a photodiode, of a pixel sensor, in a substrate of a pixel sensor array;
forming a first plurality of recesses in the substrate above the photodiode;
forming a first dielectric layer above the substrate such that first dielectric regions of the first dielectric layer fill in the first plurality of recesses to form a first plurality of diffusion structures in the first plurality of recesses;
forming a second plurality of recesses in the first dielectric layer above the first plurality of diffusion structures; and
forming a second dielectric layer above the first dielectric layer such that second dielectric regions of the second dielectric layer fill in the second plurality of recesses to form a second plurality of diffusion structures in the second plurality of recesses.

17. The method of claim 16, further comprising:
forming a third plurality of recesses in the second dielectric layer above the second plurality of diffusion structures; and
forming a color filter region, of the pixel sensor, above the second dielectric layer such that third dielectric regions of the color filter region fill in the third plurality of recesses to form a third plurality of diffusion structures in the third plurality of recesses.

18. The method of claim 16, wherein the first plurality of recesses each have an approximately pyramidal shape; and
wherein the second plurality of recesses each have an approximately conical shape.

19. The method of claim 16, wherein forming the second plurality of recesses comprises:
performing a combination of chemical etching and sputter etching to form the second plurality of recesses.

20. The method of claim 16, wherein forming the second plurality of recesses comprises:
forming the second plurality of recesses to a first depth in the first dielectric layer;
forming a protective liner in the second plurality of recesses; and
etching through a bottom portion of the protective liner and into the first dielectric layer to increase the second plurality of recesses from the first depth to a second depth in the first dielectric layer,
wherein the protective liner protects sidewalls of the second plurality of recesses from being etched.
